(19) United States
(12) Patent Application Publication
(10) Pub. No.: US 2023/0044675 A1
(43) Pub. Date: Feb. 9, 2023

(54) LIGHT EMITTING ELEMENT, METHOD FOR MANUFACTURING SAME, AND LIGHT EMITTING ELEMENT ARRAY

(71) Applicant: SONY GROUP CORPORATION, TOKYO (JP)

(72) Inventors: KENTARO HAYASHI, TOKYO (JP); TATSUSHI HAMAGUCHI, KANAGAWA (JP); MASAMICHI ITO, Tokyo (JP)

(21) Appl. No.: 17/758,145

(22) PCT Filed: Dec. 10, 2020
(86) PCT No.: PCT/JP2020/045968

§ 371 Date: Jun. 29, 2022

(30) Foreign Application Priority Data
Jan. 8, 2020 (JP) 2020-001292

(51) Int. Cl. H01S 5/183; H01S 5/042

(52) U.S. Cl. CPC H01S 5/18327; H01S 5/04256; H01S 5/18361

(57) ABSTRACT

A method for manufacturing a light emitting element according to the present disclosure is a method for manufacturing a light emitting element which includes a stacked structure 20 in which a first compound semiconductor layer 21, an active layer 23, and a second compound semiconductor layer 22 are stacked, a first light reflecting layer 41, and a second light reflecting layer 42 having a flat shape, and in which a base surface 90 positioned on a first surface side of the first compound semiconductor layer 21 has a protrusion 91 protruding in a direction away from the active layer 23, and a cross-sectional shape of the protrusion 91 includes a smooth curve, the method including: forming a first sacrificial layer 81 on the base surface on which the protrusion 91 is to be formed; forming a second sacrificial layer 82 on the entire surface; and performing etching back from the base surface 91 inward by using the second sacrificial layer 82 and the first sacrificial layer 81 as etching masks.

### TECHNICAL FIELD

The present disclosure relates to a light emitting element, a method for manufacturing the same, and a light emitting element array, and more specifically, to a light emitting element including a surface emitting laser element (vertical-cavity surface-emitting laser (VCSEL)), a method for manufacturing the same, and a light emitting element array.

### BACKGROUND ART

In a light emitting element including a surface emitting laser element, laser oscillation generally occurs by causing laser light to resonate between two light reflecting layers (distributed Bragg reflector (DBR) layers). Then, in a surface emitting laser element having a stacked structure in which an n-type compound semiconductor layer (first compound semiconductor layer), an active layer (light emitting layer) formed using a compound semiconductor, and a p-type compound semiconductor layer (second compound semiconductor layer) are stacked, generally, a second electrode formed using a transparent conductive material is formed on the p-type compound semiconductor layer, and a second light reflecting layer is formed on the second electrode. In addition, a first light reflecting layer and a first electrode are formed on the n-type compound semiconductor layer (on an exposed surface of a conductive substrate in a case where the n-type compound semiconductor layer is formed on the substrate). Note that, in the present specification, the concept “on” may refer to a direction away from the active layer with respect to the active layer, the concept “under” may refer to a direction toward the active layer with respect to the active layer, and the concepts “convex” and “concave” may be based on the active layer.

In order to suppress a diffraction loss due to light field confinement in a lateral direction, a structure in which the first light reflecting layer also functions as a concave mirror is well known from, for example, WO 2018/083877 A1. Here, in the technology disclosed in this International Publication, for example, a convex portion is formed in the n-type compound semiconductor layer with respect to the active layer, and the first light reflecting layer is formed on the convex portion.

### CITATION LIST

### Patent Document

### Patent Document 1: WO 2018/083877 A1

### SUMMARY OF THE INVENTION

### Problems to be Solved by the Invention

In order to form the convex portion in the n-type compound semiconductor layer, a resist material layer is formed on the n-type compound semiconductor layer, the resist material layer is left on a region where the convex portion is to be formed, and then the resist material layer is subjected to heating treatment to make a cross-sectional shape of the resist material layer be, for example, an arc. However, due to an influence of wettability, surface tension, gravity, or the like between the n-type compound semiconductor layer and the resist material layer, or due to specifications required for the first light reflecting layer, the resist material layer does not have a desired cross-sectional shape, and as a result, the first light reflecting layer having a desired cross-sectional shape is not obtained in some cases.

Therefore, an object of the present disclosure is to provide a method for manufacturing a light emitting element capable of obtaining a first light reflecting layer having a desired cross-sectional shape, a light emitting element obtained by the method for manufacturing a light emitting element, and a light emitting element array.

### Solutions to Problems

A method for manufacturing a light emitting element according to a first or second aspect of the present disclosure for achieving the above-described object includes:

a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked;

a first light reflecting layer; and

a second light reflecting layer formed on a second surface side of the second compound semiconductor layer and having a flat shape,

in which a base surface positioned on a first surface side of the first compound semiconductor layer has a protrusion protruding in a direction away from the active layer, and

a cross-sectional shape of the protrusion in a case where the base surface is cut along a virtual plane including a stacking direction of the stacked structure includes a smooth curve.

Then, the method for manufacturing the light emitting element according to the first aspect of the present disclosure includes:

forming the second light reflecting layer on the second surface side of the second compound semiconductor layer after forming the stacked structure;

forming a first sacrificial layer on the base surface on which the protrusion is to be formed;

forming a second sacrificial layer on the entire surface and then performing etching back from the base surface inward by using the second sacrificial layer and the first sacrificial layer as etching masks to form the protrusion on the base surface; and

forming the first light reflecting layer on at least the protrusion.

Furthermore, the method for manufacturing the light emitting element according to the second aspect of the present disclosure includes:

forming the second light reflecting layer on the second surface side of the second compound semiconductor layer after forming the stacked structure;

forming a first layer on a portion of the base surface on which the protrusion is to be formed;

forming a second layer covering the first layer to form the protrusion constituted by the first layer and the second layer covering the first layer on the base surface; and

forming the first light reflecting layer on at least the protrusion.

A light emitting element according to the first or second aspect of the present disclosure for achieving the above-described object includes:

a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked;

a first light reflecting layer; and

a second light reflecting layer formed on a second surface side of the second compound semiconductor layer and having a flat shape,

in which a base surface positioned on a first surface side of the first compound semiconductor layer has a protrusion protruding in a direction away from the active layer,

a cross-sectional shape of the protrusion in a case where the base surface is cut along a virtual plane including a stacking direction of the stacked structure includes a smooth curve,

the first light reflecting layer is formed on at least the protrusion, and

a diameter of the protrusion is D₁, a height of the protrusion is H₁, a radius of curvature of a top portion of the protrusion is R₁, and a surface roughness of the protrusion is Ra_{Pj}.

Then, in the light emitting element according to the first aspect of the present disclosure,

2×10⁻⁶ m≤D₁≤2.5×10⁻⁵ m,

preferably, 1×10⁻⁵ m≤D₁≤2.4×10⁻⁵ m, and

more preferably, 1.6×10⁻⁵ m≤D₁≤2.0×10⁻⁵ m,

1×10⁻⁸ m≤H₁≤5×10⁻⁷ m,

preferably, 1×10⁻⁸ m≤H₁≤2×10⁻⁷ m, and

more preferably, 1×10⁻⁸ m≤H₁≤1×10⁻⁷ m,

1×10⁻⁴ m≤R₁,

preferably, 5×10⁻⁴ m≤R₁, and

more preferably, 9×10⁻⁴ m≤R₁, and

Ra_{Pj}≤1.0 nm,

preferably, Ra_{Pj}≤0.7 nm, and

more preferably, Ra_{Pj}≤0.3 nm.

Furthermore, in the light emitting element according to the second aspect of the present disclosure,

2×10⁻³ m≤D₁,

preferably, 5×10⁻³ m≤D₁, and

more preferably, 1×10⁻² m≤D₁,

1×10⁻³ m≤R₁,

preferably, 5×10⁻³ m≤R₁, and

more preferably, 1×10⁻² m≤R₁, and

Ra_{Pj}≤1.0 nm,

preferably, Ra_{Pj}≤0.7 nm, and

more preferably, Ra_{Pj}≤0.3 nm.

A light emitting element according to a third aspect of the present disclosure for achieving the above-described object includes:

a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked;

a first light reflecting layer; and

a second light reflecting layer formed on a second surface side of the second compound semiconductor layer and having a flat shape,

in which a base surface positioned on a first surface side of the first compound semiconductor layer has a protrusion protruding in a direction away from the active layer,

the protrusion is constituted by a first layer and a second layer covering the first layer,

a cross-sectional shape of the protrusion in a case where the base surface is cut along a virtual plane including a stacking direction of the stacked structure includes a smooth curve, and

the first light reflecting layer is formed on at least the protrusion.

A light emitting element array of the present disclosure for achieving the above-described object includes:

a plurality of light emitting elements,

in which each of the light emitting elements includes the light emitting element according to the first aspect of the present disclosure, and

a formation pitch P₀ (a distance from an axial line of the first light reflecting layer included in the light emitting element to an axial line of a first light reflecting layer included in an adjacent light emitting element) of the light emitting elements is 3×10⁻⁵ m or less, preferably, 2×10⁻⁶ m≤P₀≤2.8×10⁻⁵ m, and more preferably, 1×10⁻⁵ m≤P₀≤2×10⁻⁵ m.

### BRIEF DESCRIPTION OF DRAWINGS

FIG. 1 is a schematic partial cross-sectional view of a light emitting element of Embodiment 1.

FIG. 2 is a schematic partial cross-sectional view of a light emitting element array including a plurality of the light emitting elements of Embodiment 1.

FIG. 3 is a schematic partial cross-sectional view of Modified Example-1 of the light emitting element of Embodiment 1.

FIG. 4 is a schematic partial cross-sectional view of Modified Example-2 of the light emitting element of Embodiment 1.

FIG. 5 is a schematic plan view illustrating disposition of a first light reflecting layer and a first electrode in the light emitting element array including the plurality of light emitting elements of Embodiment 1.

FIG. 6 is a schematic plan view illustrating disposition of the first light reflecting layer and the first electrode in the light emitting element array including the plurality of light emitting elements of Embodiment 1.

FIGS. 7A and 7B are schematic partial end views of a stacked structure and the like for explaining a method for manufacturing the light emitting element of Embodiment 1.

FIG. 8 is a schematic partial end view of the stacked structure and the like for explaining the method for manufacturing the light emitting element of Embodiment 1, continued from FIG. 7B.

FIG. 9 is a schematic partial end view of the stacked structure and the like for explaining the method for manufacturing the light emitting element of Embodiment 1, continued from FIG. 8.

FIGS. 10A, 10B, and 10C are schematic partial end views of a first compound semiconductor layer and the like for explaining the method for manufacturing the light emitting element of Embodiment 1, continued from FIG. 9.

FIG. 11 is a graph showing a relationship between a resist material constituting a second sacrificial layer, a diameter D₁ of a protrusion, and a radius R₁ of curvature of a top portion of the protrusion.

FIG. 12 is a schematic partial cross-sectional view of a light emitting element of Embodiment 3.

FIGS. 13A and 13B are schematic partial end views of a stacked structure and the like for explaining a method for manufacturing the light emitting element of Embodiment 3.

FIG. 14 is a schematic partial cross-sectional view of a light emitting element of Embodiment 4.

FIG. 15 is a schematic partial cross-sectional view of a modified example of the light emitting element of Embodiment 4.

FIG. 16 is a schematic partial cross-sectional view of a light emitting element of Embodiment 5.

FIG. 17 is a schematic partial cross-sectional view of a light emitting element array including a plurality of the light emitting elements of Embodiment 5.

FIG. 18 is a schematic partial cross-sectional view of Modified Example-1 of the light emitting element of Embodiment 5.

FIG. 19 is a schematic partial cross-sectional view of Modified Example-2 of the light emitting element of Embodiment 5.

FIG. 20 is a schematic partial cross-sectional view of Modified Example-3 of the light emitting element of Embodiment 5.

FIG. 21 is a schematic partial end view of a light emitting element of Embodiment 6.

FIG. 22 is a schematic partial end view of a light emitting element of Embodiment 7.

FIG. 23 is a schematic partial end view of a modified example of the light emitting element of Embodiment 7.

FIGS. 24A, 24B, and 24C are schematic partial end views of a stacked structure and the like for explaining a method for manufacturing a light emitting element of Embodiment 8.

FIG. 25 is a schematic partial end view of a light emitting element of Embodiment 11.

FIGS. 26A and 26B are schematic partial end views of a stacked structure and the like for explaining a method for manufacturing the light emitting element of Embodiment 11.

(A), (B), and (C) of FIG. 27 are conceptual diagrams illustrating light field intensities in a conventional light emitting element, the light emitting element of Embodiment 11, and a light emitting element of Embodiment 16, respectively.

FIG. 28 is a schematic partial end view of a light emitting element of Embodiment 12.

FIG. 29 is a schematic partial end view of a light emitting element of Embodiment 13.

FIGS. 30A and 30B are a schematic partial end view of a light emitting element of Embodiment 14 and a schematic partial cross-sectional view obtained by cutting a main part of the light emitting element of Embodiment 14, respectively.

FIG. 31 is a schematic partial end view of a light emitting element of Embodiment 15.

FIG. 32 is a schematic partial end view of the light emitting element of Embodiment 16.

FIG. 33 is a schematic partial cross-sectional view of a light emitting element of Embodiment 17.

FIG. 34 is a schematic partial cross-sectional view of the light emitting element of Embodiment 17, and a view in which two longitudinal modes, a longitudinal mode A and a longitudinal mode B, are superimposed.

FIG. 35 is a schematic partial cross-sectional view of a light emitting element of Embodiment 20.

FIG. 36 is a schematic partial cross-sectional view of a light emitting element of Embodiment 21.

FIG. 37 is a schematic partial cross-sectional view of Modified Example-1 of the light emitting element of Embodiment 21.

FIG. 38 is a schematic partial cross-sectional view of a light emitting element array including Modified Example-1 of the light emitting element of Embodiment 21.

FIG. 39 is a schematic partial cross-sectional view of Modified Example-2 of the light emitting element of Embodiment 21.

FIG. 40 is a schematic partial cross-sectional view of a light emitting element array including Modified Example-2 of the light emitting element of Embodiment 21.

FIG. 41 is a schematic partial cross-sectional view of Modified Example-3 of the light emitting element of Embodiment 21.

FIG. 42 is a schematic partial cross-sectional view of Modified Example-4 of the light emitting element of Embodiment 21.

FIG. 43 is a schematic partial cross-sectional view of Modified Example-5 of the light emitting element of Embodiment 21.

FIG. 44 is a schematic plan view illustrating disposition of a first light reflecting layer and a partition wall in a light emitting element array including the light emitting element of Embodiment 21.

FIG. 45 is a schematic plan view illustrating disposition of a first light reflecting layer and a first electrode in the light emitting element array including Modified Example-1 of the light emitting element of Embodiment 21 illustrated in FIG. 44.

FIG. 46 is a schematic plan view illustrating disposition of the first light reflecting layer and the partition wall in the light emitting element array including the light emitting element of Embodiment 21.

FIG. 47 is a schematic plan view illustrating disposition of the first light reflecting layer and the first electrode in the light emitting element array including Modified Example-1 of the light emitting element of Embodiment 21 illustrated in FIG. 46.

FIG. 48 is a schematic plan view illustrating disposition of the first light reflecting layer and the partition wall in the light emitting element array including the light emitting element of Embodiment 21.

FIG. 49 is a schematic plan view illustrating disposition of the first light reflecting layer and the first electrode in the light emitting element array including Modified Example-1 of the light emitting element of Embodiment 21 illustrated in FIG. 48.

FIG. 50 is a schematic plan view illustrating disposition of the first light reflecting layer and the partition wall in the light emitting element array including the light emitting element of Embodiment 21.

FIG. 51 is a schematic plan view illustrating disposition of the first light reflecting layer and the first electrode in the light emitting element array including Modified Example-1 of the light emitting element of Embodiment 21 illustrated in FIG. 50.

FIG. 52 is a schematic partial end view of a light emitting element of Embodiment 22.

FIG. 53 is a schematic partial end view of a light emitting element array of Embodiment 22.

FIG. 54 is a schematic partial end view of a light emitting element of Embodiment 23.

FIG. 55 is a schematic partial end view of a light emitting element array of Embodiment 23.

FIG. 56 is a schematic plan view illustrating disposition of a first portion and a second portion of a base surface in the light emitting element array of Embodiment 23.

FIG. 57 is a schematic plan view illustrating disposition of a first light reflecting layer 41 and a first electrode in the light emitting element array of Embodiment 23.

FIG. 58 is a schematic plan view illustrating disposition of the first portion and the second portion of the base surface in the light emitting element array of Embodiment 23.

FIG. 59 is a schematic plan view illustrating disposition of the first light reflecting layer 41 and the first electrode in the light emitting element array of Embodiment 23.

FIG. 60 is a schematic partial end view of a light emitting element array of Embodiment 24.

FIG. 61 is a schematic partial end view of the light emitting element array of Embodiment 24.

FIG. 62 is a schematic plan view illustrating disposition of a first portion and a second portion of a base surface in the light emitting element array of Embodiment 24.

FIG. 63 is a conceptual diagram assuming a Fabry-Perot resonator sandwiched between two concave mirror portions having the same radius of curvature.

FIG. 64 is a graph illustrating a relationship between a value of ω₀, a value of a resonator length L_{OR}, and a value of a radius R₁ of curvature (R_{DBR}) of a concave mirror portion of a first light reflecting layer.

FIG. 65 is a graph illustrating a relationship between a value of ω₀, a value of a resonator length L_{OR}, and a value of a radius R₁ of curvature (R_{DBR}) of the concave mirror portion of the first light reflecting layer.

FIGS. 66A and 66B are a diagram schematically illustrating a laser light collecting state in a case where the value of ω₀ is “positive”, and a diagram schematically illustrating a laser light collecting state in a case where the value of ω₀ is “negative”, respectively.

FIGS. 67A and 67B are conceptual diagrams schematically illustrating a longitudinal mode existing in a gain spectrum determined by an active layer.

FIG. 68 is a schematic partial end view of a conventional light emitting element.

FIGS. 69A and 69B are views each illustrating a schematic cross-sectional shape of a resist material layer obtained in a conventional technology.

### MODE FOR CARRYING OUT THE INVENTION

Hereinafter, the present disclosure will be described on the basis of embodiments with reference to the drawings, but the present disclosure is not limited to the embodiments, and various numerical values and materials in the embodiments are examples. Note that descriptions will be provided in the following order.

1. General Description of Methods for Manufacturing Light Emitting Element According to First and Second Aspects of Present Disclosure, Light Emitting Elements According to First to Third Aspects of Present Disclosure, and Light Emitting Element Array of Present Disclosure

2. Embodiment 1 (Method for Manufacturing Light Emitting Element According to First Aspect of Present Disclosure, Light Emitting Element According to First Aspect of Present Disclosure, and Light Emitting Element Array of Present Disclosure)

3. Embodiment 2 (Light Emitting Element According to Second Aspect of Present Disclosure)

4. Embodiment 3 (Method for Manufacturing Light Emitting Element According to Second Aspect of Present Disclosure and Light Emitting Element According to Third Aspect of Present Disclosure)

5. Embodiment 4 (Modification of Embodiments 1 to 3)

6. Embodiment 5 (Modification of Embodiments 1 to 4)

7. Embodiment 6 (Modification of Embodiments 1 to 5 and Light Emitting Element of Second Configuration)

8. Embodiment 7 (Another Modification of Embodiments 1 to 5 and Light Emitting Element of Third Configuration)

9. Embodiment 8 (Modification of Embodiment 7)

10. Embodiment 9 (Modification of Embodiments 1 to 8)

11. Embodiment 10 (Modification of Embodiments 1 to 9 and Light Emitting Element of Fourth Configuration)

12. Embodiment 11 (Modification of Embodiments 1 to 10 and Light Emitting Element of 5-A-th Configuration)

13. Embodiment 12 (Modification of Embodiment 11 and Light Emitting Element of 5-B-th Configuration)

14. Embodiment 13 (Modification of Embodiments 11 to 12 and Light Emitting Element of 5-C-th Configuration)

15. Embodiment 14 (Modification of Embodiments 11 to 13 and Light Emitting Element of 5-D-th Configuration)

16. Embodiment 15 (Modification of Embodiments 11 to 14)

17. Embodiment 16 (Modification of Embodiments 1 to 15, Light Emitting Element of 6-A-th Configuration, Light Emitting Element of 6-B-th Configuration, Light Emitting Element of 6-C-th Configuration, and Light Emitting Element of 6-D-th Configuration)

18. Embodiment 17 (Modification of Embodiment 1 to Embodiment 16 and Light Emitting Element of Seventh Configuration)

19. Embodiment 18 (Modification of Embodiment 17)

20. Embodiment 19 (Another Modification of Embodiment 17)

21. Embodiment 20 (Modification of Embodiments 17 to 19)

22. Embodiment 21 (Modification of Embodiments 1 to 20)

23. Embodiment 22 (Modification of Embodiments 1 to 4)

24. Embodiment 23 (Modification of Embodiment 22)

25. Embodiment 24 (Modification of Embodiments 22 to 24)

26. Others

<General Description of Methods for Manufacturing Light Emitting Element According to First and Second Aspects of Present Disclosure, Light Emitting Elements According to First to Third Aspects of Present Disclosure, and Light Emitting Element Array of Present Disclosure>

In the method for manufacturing the light emitting element according to the first aspect of the present disclosure, in the forming of the second sacrificial layer on the entire surface, the formation of the second sacrificial layer can be performed a plurality of times. Alternatively, after the second sacrificial layer is formed on the entire surface, and then etching back is performed from the base surface inward by using the second sacrificial layer and the first sacrificial layer as the etching mask to form the protrusion on the base surface, the second sacrificial layer may be formed on the entire surface, and then etching back may be performed from the base surface inward by using the second sacrificial layer as the etching mask to form the protrusion on the base surface. In this case, the formation of the second sacrificial layer may be performed a plurality of times. Furthermore, in the method for manufacturing the light emitting element according to the second aspect of the present disclosure, in the forming of the second layer on the entire surface, the formation of the second layer can be performed a plurality of times.

In the method for manufacturing the light emitting element according to the first aspect of the present disclosure, the first sacrificial layer and the second sacrificial layer can be formed using an organic material such as a resist material, a ceramic material such as SOG, a semiconductor/metal material, or the like.

Further, in the method for manufacturing the light emitting element according to the second aspect of the present disclosure, examples of a material of the first layer can include an organic material such as a resist material, a ceramic material such as SOG, a transparent resin that does not absorb (or hardly absorbs) light having an oscillation wavelength such as an epoxy-based resin or a silicone-based resin, and a synthetic resin such as an acryl-based resin, an ABS resin, a PET resin, or a polystyrene resin. Examples of a material of the second layer can include an organic material such as a resist material and a ceramic material such as SOG. Examples of a method for forming the first layer can include a method in which a first layer/forming layer is formed on the base surface by a method appropriate for the material of the first layer, and then the first layer/forming layer is patterned, and the first layer can be obtained on the basis of a nanoimprint method. Examples of a cross-sectional shape of the first layer in a case where the first layer is cut along a virtual plane (XZ plane) including the stacking direction of the stacked structure can include a rectangle and an isosceles trapezoid. In some cases, the cross-sectional shape of the first layer can be similar to the cross-sectional shape (described later) of the protrusion in a case where the base surface is cut along the virtual plane (XZ plane) including the stacking direction of the stacked structure.

In the light emitting elements according to the first to third aspects of the present disclosure, a wavelength conversion material layer (color conversion material layer) can be provided in a region of the light emitting element where light is emitted. Then, in this case, white light can be emitted via the wavelength conversion material layer (color conversion material layer). Specifically, in a case where light emitted from the active layer is emitted to the outside via the first light reflecting layer, it is sufficient if the wavelength conversion material layer (color conversion material layer) is formed on a light emitting side of the first light reflecting layer, and in a case where light emitted from the active layer is emitted to the outside via the second light reflecting layer, it is sufficient if the wavelength conversion material layer (color conversion material layer) is formed on a light emitting side of the second light reflecting layer.

In a case where blue light is emitted from the light emitting layer, white light can be emitted via the wavelength conversion material layer by employing the following form.

[A] By using a wavelength conversion material layer that converts blue light emitted from the light emitting layer into yellow light, white light in which blue and yellow are mixed is obtained as light emitted from the wavelength conversion material layer.
[B] By using a wavelength conversion material layer that converts blue light emitted from the light emitting layer into orange light, white light in which blue and orange are mixed is obtained as light emitted from the wavelength conversion material layer.
[C] By using a wavelength conversion material layer that converts blue light emitted from the light emitting layer into green light and a wavelength conversion material layer that converts blue light into red light, white light in which blue, green, and red are mixed is obtained as light emitted from the wavelength conversion material layer.

Alternatively, in a case where an ultraviolet ray is emitted from the light emitting layer, white light can be emitted via the wavelength conversion material layer by employing the following form.

[D] By using a wavelength conversion material layer that converts ultraviolet light emitted from the light emitting layer into blue light and a wavelength conversion material layer that converts ultraviolet light into yellow light, white light in which blue and yellow are mixed is obtained as light emitted from the wavelength conversion material layer.
[E] By using a wavelength conversion material layer that converts ultraviolet light emitted from the light emitting layer into blue light and a wavelength conversion material layer that converts ultraviolet light into orange light, white light in which blue and orange are mixed is obtained as light emitted from the wavelength conversion material layer.
[F] By using a wavelength conversion material layer that converts ultraviolet light emitted from the light emitting layer into blue light, a wavelength conversion material layer that converts ultraviolet light into green light, and a wavelength conversion material layer that converts ultraviolet light into red light, white light in which blue, green, and red are mixed is obtained as light emitted from the wavelength conversion material layer.

Here, examples of a wavelength conversion material which is excited by blue light and emits red light can include, specifically, red light emitting phosphor particles, and more specifically, (ME:Eu)S [however, “ME” means at least one atom selected from the group consisting of Ca, Sr, and Ba, and a similar configuration applies to the following], (M:Sm)ₓ(Si,Al)₁₂(O,N)₁₆ [however, “M” means at least one atom selected from the group consisting of Li, Mg, and Ca, and a similar configuration applies to the following], ME₂Si₅N₈:Eu, (Ca:Eu)SiN₂, and (Ca:Eu)AlSiN₃. Furthermore, examples of a wavelength conversion material which is excited by blue light and emits green light can include, specifically, green light emitting phosphor particles, and more specifically, (ME:Eu)Ga₂S₄, (M:RE)ₓ(Si,Al)₁₂(O,N)₁₆ [however, “RE” means Tb and Yb], (M:Tb)ₓ(Si,Al)₁₂(O,N)₁₆, (M:Yb)ₓ(Si,Al)₁₂(O,N)₁₆, and Si_{6-Z}Al_{Z}O_{Z}N_{8-Z}:Eu. Furthermore, examples of a wavelength conversion material that is excited by blue light and emits yellow light can include, specifically, yellow light emitting phosphor particles, and more specifically, yttrium-aluminum-garnet (YAG)-based phosphor particles. Note that the wavelength conversion material may be used singly or in combination of two or more thereof. Furthermore, by using a mixture of two or more kinds of wavelength conversion materials, emission light of a color other than yellow, green, and red can be emitted from the wavelength conversion material mixture. Specifically, for example, cyan light may be emitted, and in this case, it is sufficient if a mixture of the green light emitting phosphor particles (for example, LaPO₄:Ce,Tb, BaMgAl₁₀O₁₇:Eu,Mn, Zn₂SiO₄:Mn, MgAl₁₁O₁₉:Ce,Tb, Y₂SiO₅:Ce,Tb, and MgAl₁₁O₁₉:CE,Tb,Mn) and the blue light emitting phosphor particles (for example, BaMgAl₁₀O₁₇:Eu, BaMg₂Al₁₆O₂₇:Eu, Sr₂P₂O₇:Eu, Sr₅(PO₄)₃Cl:Eu, (Sr,Ca,Ba,Mg)₅(PO₄)₃Cl:Eu, CaWO₄, and CaWO₄:Pb) is used.

Furthermore, examples of a wavelength conversion material that is excited by an ultraviolet ray and emits red light can include, specifically, red light emitting phosphor particles, and more specifically, Y₂O₃:Eu, YVO₄:Eu, Y(P,V)O₄:Eu, 3.5MgO.0.5MgF₂.Ge₂:Mn, CaSiO₃:Pb,Mn, Mg₆AsO₁₁:Mn, (Sr,Mg)₃(PO₄)₃:Sn, La₂O₂S:Eu, and Y₂O₂S:Eu. Furthermore, examples of a wavelength conversion material that is excited by an ultraviolet ray and emits green light can include, specifically, green light emitting phosphor particles, and more specifically, LaPO₄:Ce,Tb, BaMgAl₁₀O₁₇:Eu,Mn, Zn₂SiO₄:Mn, MgAl₁₁O₁₉:Ce,Tb, Y₂SiO₅:Ce,Tb, MgAl₁₁O₁₉:CE,Tb,Mn, and Si_{6-Z}Al_{Z}O_{Z}N_{8-Z}:Eu. Furthermore, examples of a wavelength conversion material that is excited by an ultraviolet ray and emits blue light can include, specifically, blue light emitting phosphor particles, and more specifically, BaMgAl₁₀O₁₇:Eu, BaMg₂Al₁₆O₂₇:Eu, Sr₂P₂O₇:Eu, Sr₅(PO₄)₃Cl:Eu, (Sr,Ca,Ba,Mg)₅(PO₄)₃Cl:Eu, CaWO₄, and CaWO₄:Pb. Furthermore, examples of a wavelength conversion material that is excited by an ultraviolet ray and emits yellow light can include, specifically, yellow light emitting phosphor particles, and more specifically, YAG-based phosphor particles. Note that the wavelength conversion material may be used singly or in combination of two or more thereof. Furthermore, by using a mixture of two or more kinds of wavelength conversion materials, emission light of a color other than yellow, green, and red can be emitted from the wavelength conversion material mixture. Specifically, cyan light may be emitted, and in this case, it is sufficient if a mixture of the green light emitting phosphor particles and the blue light emitting phosphor particles is used.

However, the wavelength conversion material (color conversion material) is not limited to phosphor particles. For example, with an indirect transition type silicon-based material, light emitting particles to which a quantum well structure localizing a carrier wave function and using a quantum effect to efficiently convert a carrier into light like a direct transition type, such as a two-dimensional quantum well structure, a one-dimensional quantum well structure (quantum wire), or a zero-dimensional quantum well structure (quantum dot), is applied can be used. Alternatively, it is known that a rare earth atom added to a semiconductor material emits light keenly by interior transition, and light emitting particles to which such a technology is applied can be used.

Examples of the wavelength conversion material (color conversion material) can include the quantum dot as described above. As a size (diameter) of the quantum dot decreases, a band gap energy increases, and a wavelength of light emitted from the quantum dot decreases. That is, as the size of the quantum dot decreases, light having a shorter wavelength (light on a blue light side) is emitted, and as the size of the quantum dot increases, light having a longer wavelength (light on a red light side) is emitted. Therefore, it is possible to obtain a quantum dot that emits light having a desired wavelength (performs color conversion to a desired color) by using the same material constituting the quantum dot and adjusting the size of the quantum dot. Specifically, the quantum dot preferably has a core-shell structure. Examples of a material constituting the quantum dot can include Si, Se, a chalcopyrite-based compound such as CuInGaSe (CIGS), CuInSe₂ (CIS), CuInS₂, CuAlS₂, CuAlSe₂, CuGaS₂, CuGaSe₂, AgAlS₂, AgAlSe₂, AgInS₂, or AgInSe₂, a perovskite-based material, a Group III-V compound such as GaAs, GaP, InP, InAs, InGaAs, AlGaAs, InGaP, AlGaInP, InGaAsP, or GaN; CdSe, CdSeS, CdS, CdTe, In₂Se₃, In₂S₃, Bi₂Se₃, Bi₂S₃, ZnSe, ZnTe, ZnS, HgTe, HgS, PbSe, PbS, and TiO₂, but are not limited thereto.

In the methods for manufacturing a light emitting element according to the first and second aspect of the present disclosure, the light emitting elements according to the first to third aspects of the present disclosure, or the light emitting element array of the present disclosure (which may hereinafter be collectively referred to simply as “the present disclosure”), the term “smooth” is an analytical term. For example, in a case where a real variable function f(x) is differentiable for a<x<b, and f′(x) is continuous, it can be said that it is continuously differentiable in terms of words, and it is also expressed as being smooth.

Further, in the present disclosure, the cross-sectional shape of the protrusion in a case where the base surface is cut along the virtual plane (XZ plane) including the stacking direction of the stacked structure includes a smooth curve. Specifically, a figure drawn by the protrusion in a case where the protrusion is cut along the virtual plane including the stacking direction of the stacked structure can be a part of a circle, a part of a parabola, a part of a sine curve, a part of an ellipse, or a part of a catenary curve. In some cases, the figure is not strictly a part of a circle, is not strictly a part of a parabola, is not strictly a part of a sine curve, is not strictly a part of an ellipse, or is not strictly a part of a catenary curve. That is, a case where the figure is substantially a part of a circle, a case where the figure is substantially a part of a parabola, a case where the figure is substantially a part of a sine curve, a case where the figure is substantially a part of an ellipse, and a case where the figure is substantially a part of a catenary curve are also included in a case where “the figure is a part of a circle, is a part of a parabola, is a part of a sine curve, is substantially a part of an ellipse, or is substantially a part of a catenary curve”. The figure drawn by the protrusion can be obtained by measuring the shape of the protrusion with a measuring instrument and analyzing the obtained data on the basis of the least square method.

In a case where a planar shape of the protrusion is other than a circle, D₁ in S=π(D₁/2)² where an area of the protrusion is “S” is a diameter of the protrusion.

In a light emitting element obtained by the method for manufacturing the light emitting element according to the first or second aspect of the present disclosure having the above-described preferable form, or the light emitting elements according to the first to third aspects of the present disclosure having the above-described preferable form, or the light emitting element included in the light emitting element array of the present disclosure having the above-described preferable form (hereinafter, these light emitting elements may be collectively and simply referred to as the “light emitting element of the present disclosure and the like”), it is preferable that 1×10⁻⁵ m≤L_{OR}, where a resonator length is L_{OR}. Further, in the light emitting elements according to the first and second aspects of the present disclosure, a relationship between the resonator length L_{OR} and a radius R₁ of curvature of a top portion of the protrusion can be expressed as 1≤R₁/L_{OR}≤4×10².

In the light emitting element of the present disclosure and the like, the first light reflecting layer is formed on at least the protrusion, but in some cases, an extension portion of the first light reflecting layer is formed on a portion of the base surface other than the protrusion or is formed only on the protrusion.

Moreover, in the light emitting element of the present disclosure and the like having the above-described preferable form can have a form in which the first surface of the first compound semiconductor layer constitutes the base surface. The light emitting element having such a configuration is referred to as a “first configuration” for convenience. Alternatively, a configuration, in which a compound semiconductor substrate is disposed between the first surface of the first compound semiconductor layer and the first light reflecting layer, and the base surface is constituted by a surface of the compound semiconductor substrate, is possible. The light emitting element having such a configuration is referred to as the “light emitting element of the second configuration” for convenience. In this case, for example, the compound semiconductor substrate can be formed using a GaN substrate. As the GaN substrate, any of a polar substrate, a semipolar substrate, and a nonpolar substrate may be used. As a thickness of the compound semiconductor substrate, 5×10⁻⁵ m to 1×10⁻⁴ m can be exemplified, but the thickness is not limited to such a value. Alternatively, a configuration, in which a base material is disposed between the first surface of the first compound semiconductor layer and the first light reflecting layer, or the compound semiconductor substrate and the base material are disposed between the first surface of the first compound semiconductor layer and the first light reflecting layer, and the base surface is constituted by a surface of the base material, is possible. The light emitting element having such a configuration is referred to as a “light emitting element of a third configuration” for convenience. Examples of a material of the base material can include a transparent dielectric material such as TiO₂, Ta₂O₅, or SiO₂, a silicone-based resin, and an epoxy-based resin.

In the light emitting element of the present disclosure and the like, materials of various compound semiconductor layers (including the compound semiconductor substrate) positioned between the active layer and the first light reflecting layer are preferably not modulated in refractive index by 10% or more (there is no refractive index difference of 10% or more from an average refractive index of the stacked structure), and as a result, it is possible to suppress occurrence of disturbance of a light field in a resonator.

Furthermore, in the light emitting element of the present disclosure and the like having the above-described preferable form can have a form in which a value of a thermal conductivity of the stacked structure is higher than a value of a thermal conductivity of the first light reflecting layer. A value of a thermal conductivity of a dielectric material of the first light reflecting layer is generally about 10 watts/(m·K) or less. On the other hand, a value of a thermal conductivity of the GaN-based compound semiconductor of the stacked structure is about 50 to 100 watts/(m·K).

The light emitting element of the present disclosure and the like having the above-described preferable form can be implemented as a surface emitting laser element (vertical-cavity surface-emitting laser (VCSEL)) that emits laser light via the first light reflecting layer, or can be implemented as a surface emitting laser element that emits laser light via the second light reflecting layer. In some cases, a light emitting element manufacturing substrate (as described later) may be removed.

In the light emitting element array, a central portion (top portion) of the first light reflecting layer of each light emitting element can be positioned at, although not limited to, a vertex (intersection portion) of a square lattice, or can be positioned at a vertex (intersection portion) of a regular triangle lattice.

Furthermore, in the light emitting element of the present disclosure and the like having the above-described preferable form, the stacked structure can be formed using at least one material selected from the group consisting of a GaN-based compound semiconductor, an InP-based compound semiconductor, and a GaAs-based compound semiconductor. Specifically, the stacked structure can be formed using:

(a) a GaN-based compound semiconductor;

(b) an InP-based compound semiconductor;

(c) a GaAs-based compound semiconductor;

(d) a GaN-based compound semiconductor and an InP-based compound semiconductor;

(e) a GaN-based compound semiconductor and a GaAs-based compound semiconductor;

(f) an InP-based compound semiconductor and a GaAs-based compound semiconductor; or

(g) a GaN-based compound semiconductor, an InP-based compound semiconductor, and a GaAs-based compound semiconductor.

In the light emitting element of the present disclosure and the like, more specifically, the stacked structure can be formed using, for example, an AlInGaN-based compound semiconductor. Here, more specifically, examples of the AlInGaN-based compound semiconductor can include GaN, AlGaN, InGaN, and AlInGaN. Furthermore, these compound semiconductors may contain a boron (B) atom, a thallium (Tl) atom, an arsenic (As) atom, a phosphorus (P) atom, or an antimony (Sb) atom as desired. It is desirable that the active layer has a quantum well structure. Specifically, the active layer may have a single quantum well structure (SQW structure) or a multiple quantum well structure (MQW structure). The active layer having the quantum well structure has a structure in which at least one well layer and at least one barrier layer are stacked, and examples of a combination of (a compound semiconductor constituting the well layer and a compound semiconductor constituting the barrier layer) can include (In_{y}Ga_{(1-y)}N and GaN), (In_{y}Ga_{(1-y)}N and In_{z}Ga_{(1-z)}N) [where y>z], and (In_{y}Ga_{(1-y)}N and AlGaN). The first compound semiconductor layer can be formed using a compound semiconductor of a first conductivity type (for example, n-type), and the second compound semiconductor layer can be formed using a compound semiconductor of a second conductivity type (for example, p-type) different from the first conductivity type. The first compound semiconductor layer and the second compound semiconductor layer are also referred to as a first cladding layer and a second cladding layer. The first compound semiconductor layer and the second compound semiconductor layer may each be a single structure layer, a multilayer structure layer, or a superlattice structure layer. Furthermore, The first compound semiconductor layer and the second compound semiconductor layer can each be a layer including a composition gradient layer and a concentration gradient layer.

Alternatively, examples of a Group III atom constituting the stacked structure can include gallium (Ga), indium (In), and aluminum (Al), and examples of a Group V atom constituting the stacked structure can include arsenic (As), phosphorus (P), antimony (Sb), and nitrogen (N). Specifically, AlAs, GaAs, AlGaAs, AlP, GaP, GaInP, AlInP, AlGaInP, AlAsP, GaAsP, AlGaAsP, AlInAsP, GaInAsP, AlInAs, GaInAs, AlGaInAs, AlAsSb, GaAsSb, AlGaAsSb, AlN, GaN, InN, AlGaN, GaNAs, and GaInNAs can be used, and examples of a compound semiconductor constituting the active layer can include GaAs, AlGaAs, GaInAs, GaInAsP, GaInP, GaSb, GaAsSb, GaN, InN, GaInN, GaInN, GaInNAs, and GaInNAsSb.

Examples of the quantum well structure can include a two-dimensional quantum well structure, a one-dimensional quantum well structure (quantum wire), and a zero-dimensional quantum well structure (quantum dot). Examples of a material constituting the quantum well can include: Si, Se, a chalcopyrite-based compound such as CuInGaSe (CIGS), CuInSe₂ (CIS), CuInS₂, CuAlS₂, CuAlSe₂, CuGaS₂, CuGaSe₂, AgAlS₂, AgAlSe₂, AgInS₂, or AgInSe₂, a perovskite-based material, a Group III-V compound such as GaAs, GaP, InP, AlGaAs, InGaP, AlGaInP, InGaAsP, GaN, InAs, InGaAs, GaInNAs, GaSb, or GaAsSb, CdSe, CdSeS, CdS, CdTe, In₂Se₃, In₂S₃, Bi₂Se₃, Bi₂S₃, ZnSe, ZnTe, ZnS, HgTe, HgS, PbSe, PbS, and TiO₂, but are not limited thereto.

Both of the GaAs material and the InP material have a zinc blende structure. Examples of the main surface of the compound semiconductor substrate formed using these materials can include planes obtained by offsetting in a specific direction in addition to planes such as (100), (111)AB, (211)AB, and (311)AB. Note that “AB” means that a 90° offset direction is different, and whether a main material of the plane is Group III or Group V is determined by the offset direction. By controlling these crystal plane orientation and film formation conditions, composition unevenness and a dot shape can be controlled. As a film forming method, a film forming method such as the MBE method, the MOCVD method, the MEE method, or the ALD method is generally used as with the GaN-based compound semiconductor, but the film forming method is not limited to these methods.

In formation of the GaN-based compound semiconductor layer, examples of an organic gallium source gas in the MOCVD method can include a trimethylgallium (TMG) gas and a triethylgallium (TEG) gas, and examples of a nitrogen source gas can include an ammonia gas and a hydrazine gas. In formation of the GaN-based compound semiconductor layer of which the conductivity type is the n type, for example, it is only required to add silicon (Si) as an n-type impurity (n-type dopant), and in formation of the GaN-based compound semiconductor layer of which the conductivity type is the p type, for example, it is only required to add magnesium (Mg) as a p-type impurity (p-type dopant). In a case where aluminum (Al) or indium (In) is contained as a constituent atom of the GaN-based compound semiconductor layer, a trimethylaluminum (TMA) gas may be used as an Al source, and a trimethylindium (TMI) gas may be used as an In source. Moreover, a monosilane gas (SiH₄ gas) may be used as a Si source, and a biscyclopentadienyl magnesium gas, methylcyclopentadienyl magnesium, or biscyclopentadienyl magnesium (Cp₂Mg) may be used as a Mg source. Note that examples of the n-type impurity (n-type dopant) can include Ge, Se, Sn, C, Te, S, O, Pd, and Po in addition to Si, and examples of the p-type impurity (p-type dopant) can include Zn, Cd, Be, Ca, Ba, C, Hg, and Sr in addition to Mg.

In a case where the stacked structure is formed using the InP-based compound semiconductor or the GaAs-based compound semiconductor, TMGa, TEGa, TMIn, TMAl, and the like, which are organometallic raw materials, are generally used as Group III raw materials. Furthermore, as a Group V raw material, an arsine gas (AsH₃ gas), a phosphine gas (PH₃ gas), ammonia (NH₃), or the like is used. Note that an organometallic raw material is used as the Group V raw material in some cases, and examples of the organometallic raw material can include tertiary-butylarsine (TBAs), tertiary-butylphosphine (TBP), dimethylhydrazine (DMHy), and trimethylantimony (TMSb). These materials are effective in low-temperature growth because they decompose at a low temperature. As the n-type dopant, monosilane (SiH₄) is used as a Si source, hydrogen selenide (H₂Se) or the like is used as a Se source. Furthermore, dimethyl zinc (DMZn), biscyclopentadienyl magnesium (Cp₂Mg), or the like is used as the p-type dopant. A material similar to that of the GaN-based compound semiconductor is a candidate of a dopant material.

The stacked structure is formed on a second surface of the light emitting element manufacturing substrate or formed on a second surface of the compound semiconductor substrate. The second surface of the light emitting element manufacturing substrate or the compound semiconductor substrate faces the first surface of the first compound semiconductor layer, and a first surface of the light emitting element manufacturing substrate or the compound semiconductor substrate opposes the second surface of the light emitting element manufacturing substrate. Examples of the light emitting element manufacturing substrate can include a GaN substrate, a sapphire substrate, a GaAs substrate, a SiC substrate, an alumina substrate, a ZnS substrate, a ZnO substrate, an AlN substrate, a LiMgO substrate, a LiGaO₂ substrate, a MgAl₂O₄ substrate, an InP substrate, a Si substrate, and a substrate obtained by forming an underlying layer or a buffer layer on a surface (main surface) of each of these substrates, and it is preferable that a GaN substrate is used because of a low defect density. Furthermore, examples of the compound semiconductor substrate can include a GaN substrate, an InP substrate, and a GaAs substrate. Although it is known that a characteristic of the GaN substrate is changed to being polar/nonpolar/semipolar depending on a growth surface, any main surface (second surface) of the GaN substrate can be used for formation of the compound semiconductor layer. Furthermore, regarding the main surface of the GaN substrate, depending on a crystal structure (for example, a cubic crystal type or a hexagonal crystal type), a crystal plane orientation called a so-called A plane, B plane, C plane, R plane, M plane, N plane, S plane, or the like, or a plane obtained by offsetting them in a specific direction can be used. Examples of a method for forming various compound semiconductor layers included in the light emitting element can include, but are not limited to, an organic metal chemical vapor deposition (a metal organic-chemical vapor deposition (MOCVD) method or a metal organic-vapor phase epitaxy (MOVPE) method), a molecular beam epitaxy (MBE) method, a hydride vapor phase epitaxy (HVPE) method in which halogen contributes to transport or reaction, an atomic layer deposition (ALD) method, a migration-enhanced epitaxy (MEE) method, and a plasma-assisted physical vapor deposition (PPD) method.

In manufacturing of the light emitting element of the present disclosure and the like, the light emitting element manufacturing substrate may be left, or the light emitting element manufacturing substrate may be removed after sequentially forming the active layer, the second compound semiconductor layer, the second electrode, and the second light reflecting layer on the first compound semiconductor layer. Specifically, the light emitting element manufacturing substrate may be removed after sequentially forming the active layer, the second compound semiconductor layer, the second electrode, and the second light reflecting layer on the first compound semiconductor layer, and then fixing the second light reflecting layer to a support substrate, thereby exposing the first compound semiconductor layer (the first surface of the first compound semiconductor layer). The light emitting element manufacturing substrate can be removed by a wet etching method using an alkali aqueous solution such as a sodium hydroxide aqueous solution or a potassium hydroxide aqueous solution, an ammonia solution+a hydrogen peroxide solution, a sulfuric acid solution+a hydrogen peroxide solution, a hydrochloric acid solution+a hydrogen peroxide solution, or a phosphoric acid solution+a hydrogen peroxide solution, a dry etching method such as a chemical mechanical polishing (CMP) method, a mechanical polishing method, or a reactive ion etching (RIE) method, a lift-off method using a laser, or the like, or a combination thereof.

The support substrate is only required to be formed using, for example, various substrates exemplified as the light emitting element manufacturing substrate, or can be formed using an insulating substrate formed using AlN or the like, a semiconductor substrate formed using Si, SiC, Ge, or the like, a metal substrate, or an alloy substrate, but it is preferable to use a substrate having conductivity, or it is preferable to use a metal substrate or alloy substrate from the viewpoint of a mechanical characteristic, elastic deformation, plastic deformability, heat dissipation, and the like. A thickness of the support substrate can be, for example, 0.05 mm to 1 mm. As a method for fixing the second light reflecting layer to the support substrate, a known method such as a solder bonding method, a room temperature bonding method, a bonding method using an adhesive tape, a bonding method using wax bonding, or a method using an adhesive can be used, but it is desirable to employ the solder bonding method or the room temperature bonding method from the viewpoint of ensuring conductivity. For example, in a case where a silicon semiconductor substrate that is a conductive substrate is used as the support substrate, it is desirable to employ a method capable of bonding at a low temperature of 400° C. or lower in order to suppress warpage due to a difference in thermal expansion coefficient. In a case where a GaN substrate is used as the support substrate, a bonding temperature may be 400° C. or higher.

The first electrode electrically connected to the first compound semiconductor layer may be common to a plurality of light emitting elements, and the second electrode electrically connected to the second compound semiconductor layer may be common to the plurality of light emitting elements, or may be individually provided in the plurality of light emitting elements.

In a case where the light emitting element manufacturing substrate is left, it is only required to form the first electrode on the first surface opposing the second surface of the light emitting element manufacturing substrate, or on the first surface opposing the second surface of the compound semiconductor substrate. Furthermore, in a case where the light emitting element manufacturing substrate is not left, it is only required to form the first electrode on the first surface of the first compound semiconductor layer included in the stacked structure. Note that, in this case, since the first light reflecting layer is formed on the first surface of the first compound semiconductor layer, for example, it is only required to form the first electrode so as to surround the first light reflecting layer. The first electrode desirably has a single-layer configuration or a multilayer configuration including, for example, at least one metal (including an alloy) selected from the group consisting of gold (Au), silver (Ag), palladium (Pd), platinum (Pt), nickel (Ni), titanium (Ti), vanadium (V), tungsten (W), chromium (Cr), aluminum (Al), copper (Cu), zinc (Zn), tin (Sn), and indium (In). Specifically, for example, Ti/Au, Ti/Al, Ti/Al/Au, Ti/Pt/Au, Ni/Au, Ni/Au/Pt, Ni/Pt, Pd/Pt, and Ag/Pd can be exemplified. Note that a layer before “/” in the multilayer configuration is positioned closer to the active layer. A similar configuration applies to the following description. The first electrode can be formed by, for example, a physical vapor deposition (PVD) method such as a vacuum vapor deposition method or a sputtering method.

In a case where the first electrode is formed so as to surround the first light reflecting layer, the first light reflecting layer and the first electrode can be in contact with each other. Alternatively, the first light reflecting layer and the first electrode can be separated from each other. In some cases, the first electrode can be formed up to an edge portion of the first light reflecting layer, or the first light reflecting layer can be formed up to an edge portion of the first electrode.

Specifically, examples of planar shapes of the first light reflecting layer, the protrusion, and the second light reflecting layer can include a circle, an ellipse, an oval, a quadrangle, and a regular polygon (a regular triangle, a square, a regular hexagon, or the like). In addition, the first light reflecting layer, the protrusion, and the second light reflecting layer are desirably similar or approximate.

The second electrode can be formed using a transparent conductive material. Examples of the transparent conductive material of the second electrode can include an indium-based transparent conductive material [specifically, for example, indium tin oxide (ITO) (including Sn-doped In₂O₃, crystalline ITO, and amorphous ITO), indium zinc oxide (IZO), indium gallium oxide (IGO), indium-doped gallium zinc oxide (IGZO) (In—GaZnO₄), IFO (F-doped In₂O₃), ITiO (Ti-doped In₂O₃), InSn, or InSnZnO], a tin-based transparent conductive material [specifically, for example, tin oxide (SnOₓ), ATO (Sb-doped SnO₂), or FTO (F-doped SnO₂)], a zinc-based transparent conductive material [specifically, for example, zinc oxide (ZnO) (Al-doped ZnO (AZO) or B-doped ZnO), gallium-doped zinc oxide (GZO), AlMgZnO (aluminum oxide and magnesium oxide-doped zinc oxide)], NiO, TiO_{X}, and graphene. Alternatively, examples of the second electrode can include a transparent conductive film having gallium oxide, titanium oxide, niobium oxide, antimony oxide, nickel oxide, or the like as a base layer, and a transparent conductive material such as a spinel-type oxide or an oxide having a YbFe₂O₄ structure can be used. However, the material of the second electrode depends on a disposition state of the second light reflecting layer and the second electrode, but is not limited to the transparent conductive material, and a metal such as palladium (Pd), platinum (Pt), nickel (Ni), gold (Au), cobalt (Co), or rhodium (Rh) can also be used. The second electrode is only required to be formed using at least one of these materials. The second electrode can be formed by, for example, a PVD method such as a vacuum vapor deposition method or a sputtering method. Alternatively, a low-resistance semiconductor layer can be used as a transparent electrode layer, and in this case, specifically, an n-type GaN-based compound semiconductor layer can also be used. Furthermore, in a case where a layer adjacent to the n-type GaN-based compound semiconductor layer is the p type, an electrical resistance of an interface can be reduced by bonding the n-type GaN-based compound semiconductor layer and the p-type layer via a tunnel junction. As the second electrode is formed using the transparent conductive material, a current can be expanded in a lateral direction (an in-plane direction of the second compound semiconductor layer) and can be efficiently supplied to a current injection region (as described later).

A first pad electrode and a second pad electrode may be provided on the first electrode and the second electrode in order to be electrically connected to an external electrode or circuit (which may hereinafter be referred to as an “external circuit or the like”). The pad electrode desirably has a single-layer configuration or a multilayer configuration including at least one metal selected from the group consisting of titanium (Ti), aluminum (Al), platinum (Pt), gold (Au), nickel (Ni), and palladium (Pd). Alternatively, the pad electrode may have a multilayer configuration exemplified by a Ti/Pt/Au multilayer configuration, a Ti/Au multilayer configuration, a Ti/Pd/Au multilayer configuration, a Ti/Pd/Au multilayer configuration, a Ti/Ni/Au multilayer configuration, and a Ti/Ni/Au/Cr/Au multilayer configuration. In a case where the first electrode includes an Ag layer or an Ag/Pd layer, it is preferable that a cover metal layer formed using, for example, Ni/TiW/Pd/TiW/Ni is formed on a surface of the first electrode, and the pad electrode having, for example, the Ti/Ni/Au multilayer configuration or the Ti/Ni/Au/Cr/Au multilayer configuration is formed on the cover metal layer.

The light reflecting layers (distributed Bragg reflector (DBR) layers) constituting the first light reflecting layer and the second light reflecting layer are each formed using, for example, a semiconductor multilayer film or a dielectric multilayer film. Examples of the dielectric material can include oxides, nitrides (for example, SiN_{X}, AlN_{X}, AlGaN_{X}, GaN_{X}, BN_{X}, and the like), and fluorides of Si, Mg, Al, Hf, Nb, Zr, Sc, Ta, Ga, Zn, Y, B, Ti, and the like. Specifically, SiO_{X}, TiO_{X}, NbO_{X}, ZrO_{X}, TaO_{X}, ZnO_{X}, AlO_{X}, HfO_{X}, SiN_{X}, AlN_{X}, and the like can be exemplified. Then, the light reflecting layer can be obtained by alternately stacking two or more kinds of dielectric films formed using dielectric materials having different refractive indexes among these dielectric materials. For example, a multilayer film of SiO_{X}/SiN_{Y}, SiO_{X}/TaO_{X}, SiO_{X}/NbO_{Y}, SiO_{X}/ZrO_{Y}, SiO_{X}/AlN_{Y}, or the like is preferable. It is sufficient if a material of each dielectric film, a film thickness, the number of stacked layers, and the like are appropriately selected in order to obtain a desired light reflectance. The thickness of each dielectric film can be appropriately adjusted according to the material to be used or the like, and is determined by an oscillation wavelength (emission wavelength) λ₀ and a refractive index n at the oscillation wavelength λ₀ of the material to be used. Specifically, an odd multiple of λ₀/(4n) is preferable. For example, in the light emitting element having the oscillation wavelength λ₀ of 410 nm, in a case where the light reflecting layer is formed using SiO_{X}/NbO_{Y}, about 40 nm to 70 nm can be exemplified. The number of stacked layers may be two or more, preferably, about five to twenty. The thickness of the entire light reflecting layer can be, for example, about 0.6 μm to 1.7 μm. In addition, the light reflectance of the light reflecting layer is desirably 95% or more. A size and shape of the light reflecting layer are not particularly limited as long as the light reflecting layer covers the current injection region or an element region (which will be described later).

The light reflecting layer can be formed on the basis of a known method, and specifically, examples of the known method can include a PVD method such as a vacuum vapor deposition method, a sputtering method, a reactive sputtering method, an ECR plasma sputtering method, a magnetron sputtering method, an ion beam assisted vapor deposition method, an ion plating method, or a laser ablation method; various CVD methods; an application method such as a spray method, a spin coating method, or a dipping method; a method in which two or more of these methods are combined; and a method in which these methods are combined with any one or more of whole or partial pretreatment, irradiation of inert gas (Ar, He, Xe, or the like) or plasma, irradiation of oxygen gas or ozone gas and plasma, oxidation treatment (heat treatment), and exposure treatment.

The current injection region is provided to regulate current injection into the active layer. Specifically, examples of a shape of a boundary between the current injection region and a current non-injection/inner region, a shape of a boundary between the current non-injection/inner region and a current non-injection/outer region, and a planar shape of an opening provided in the element region or a current constriction region can include a circle, an ellipse, an oval, a quadrangle, and a regular polygon (a regular triangle, a square, a regular hexagon, or the like). The shape of the boundary between the current injection region and the current non-injection/inner region and the shape of the boundary between the current non-injection/inner region and the current non-injection/outer region are desirably similar or approximate. Here, the “element region” refers to a region into which a constricted current is injected, a region in which light is confined due to a refractive index difference or the like, a region where laser oscillation occurs in a region sandwiched between the first light reflecting layer and the second light reflecting layer, or a region actually contributing to laser oscillation in a region sandwiched between the first light reflecting layer and the second light reflecting layer.

In the light emitting element of the present disclosure and the like, a bump can be arranged on a second surface of the light emitting element (an exposed surface of the light emitting element on a second light reflecting layer side). Examples of the bump can include a gold (Au) bump, a solder bump, and an indium (In) bump, and a method for arranging the bump can be a known method. Specifically, the bump is provided on the second pad electrode provided on the second electrode, or is provided on an extension portion of the second pad electrode. Alternatively, a brazing material can be used instead of the bump. Examples of the brazing material can include indium (In) (melting point: 157° C.); an indium-gold-based low melting point alloy; a tin (Sn)-based high-temperature solder such as Sn₈₀Ag₂₀ (melting point: 220 to 370° C.) or Sn₉₅Cu₅ (melting point: 227 to 370° C.); a lead (Pb)-based high-temperature solder such as Pb_{97.5}Ag_{2.5} (melting point: 304° C.), Pb_{94.5}Ag_{5.5} (melting point: 304 to 365° C.), or Pb_{97.5}Ag_{1.5}Sn_{1.0} (melting point: 309° C.); a zinc (Zn)-based high-temperature solder such as Zn₉₅Al₅ (melting point: 380° C.); a tin-lead-based standard solder such as Sn₅Pb₉₅ (melting point: 300 to 314° C.) or Sn₂Pb₉₈ (melting point: 316 to 322° C.); and Au₈₈Ga₁₂ (melting point: 381° C.) (the above subscripts all represent atom %).

A side surface or an exposed surface of the stacked structure may be covered by a coating layer (insulating film). The coating layer (insulating film) can be formed on the basis of a known method. A refractive index of a material of the coating layer (insulating film) is preferably smaller than a refractive index of the material of the stacked structure. Examples of the material of the coating layer (insulating film) can include a SiO_{X}-based material including SiO₂, a SiN_{X}-based material, a SiO_{Y}N_{Z}-based material, TaO_{X}, ZrO_{X}, AlN_{X}, AlO_{X}, and GaO_{X}, or an organic material such as a polyimide-based resin can be used. Examples of a method for forming the coating layer (insulating film) can include a PVD method such as a vacuum vapor deposition method or a sputtering method, and a CVD method, and the coating layer (insulating film) can also be formed on the basis of a coating method.

### Embodiment 1

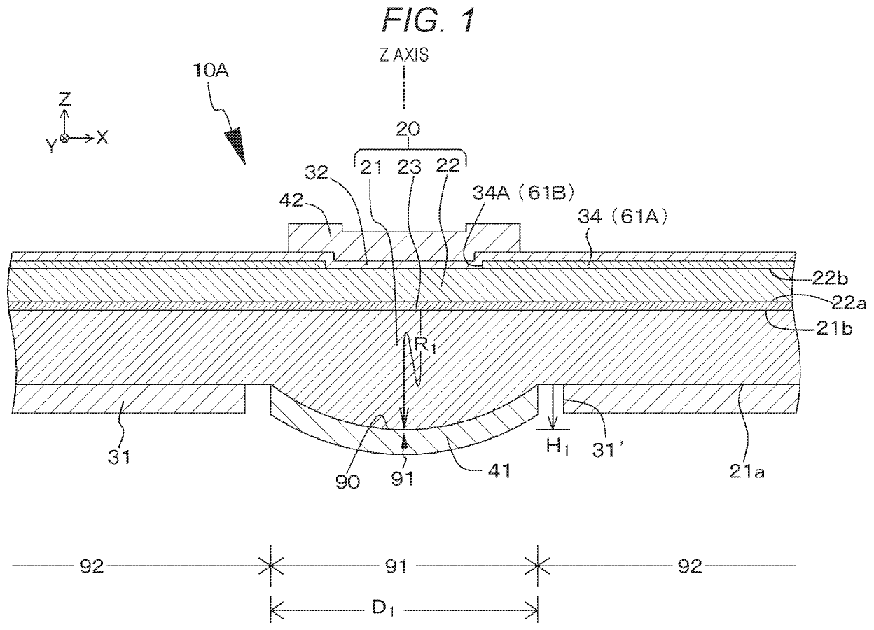

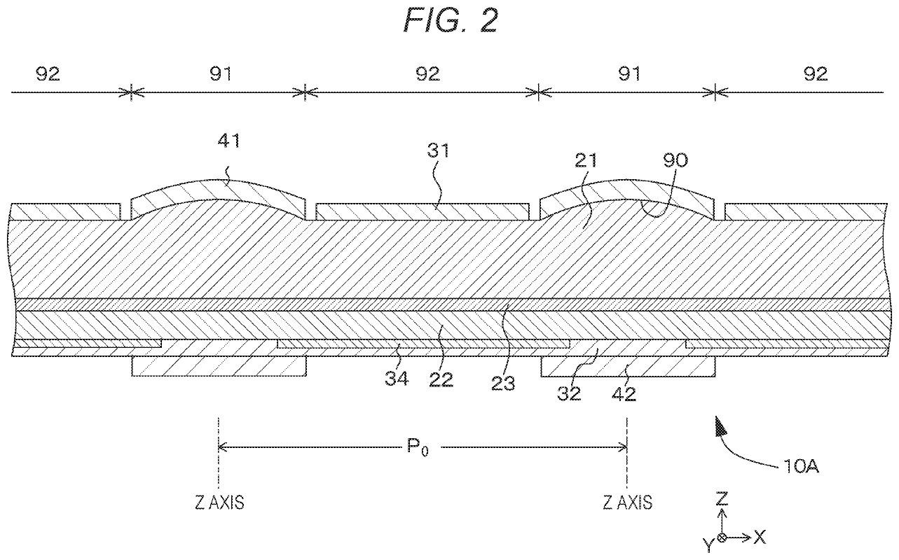

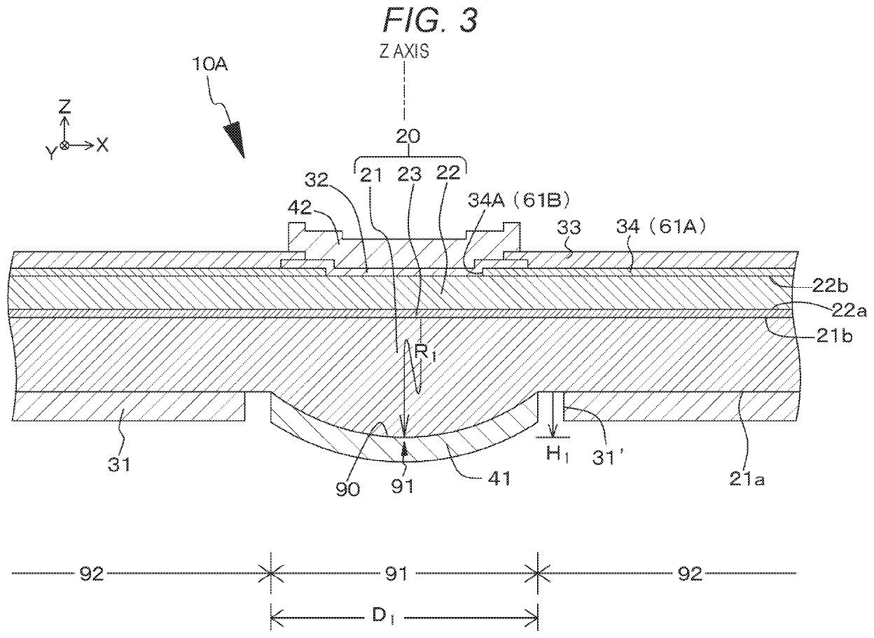

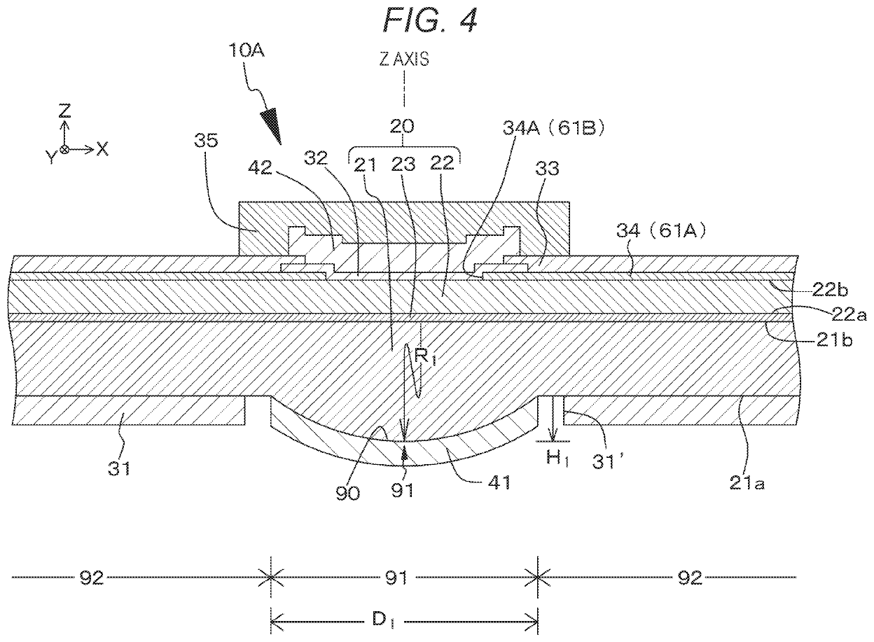

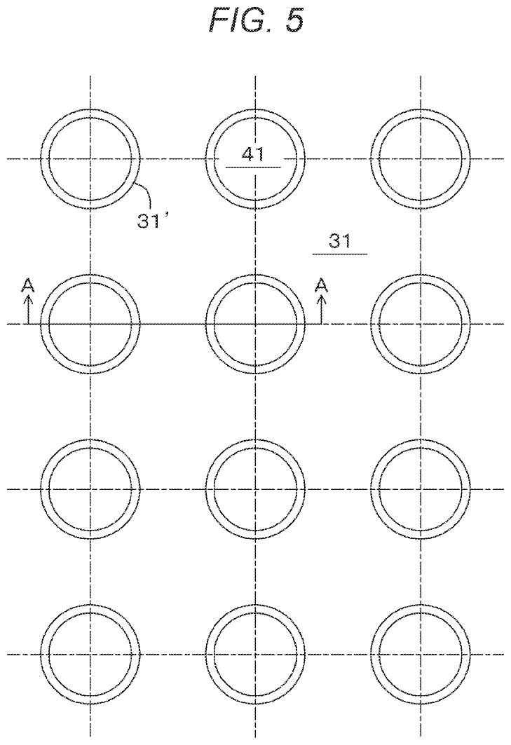

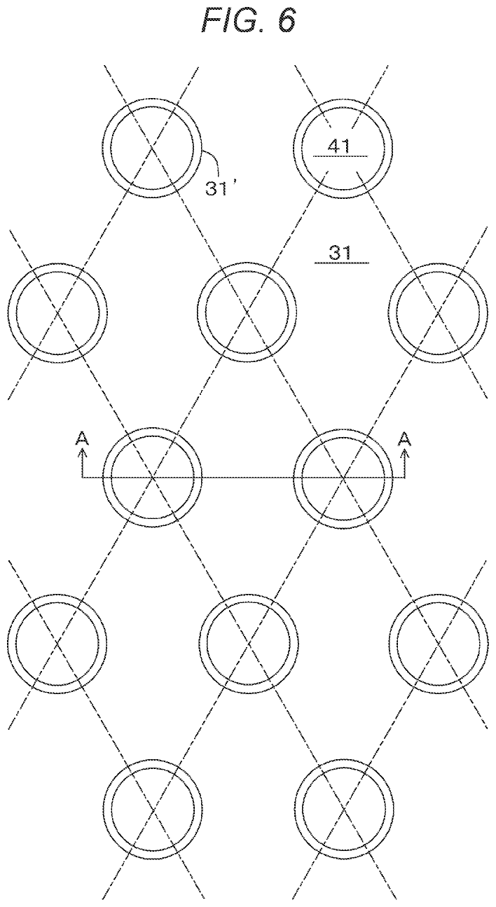

Embodiment 1 relates to the light emitting element according to the first aspect of the present disclosure, the method for manufacturing the light emitting element according to the first aspect of the present disclosure, and the light emitting element array of the present disclosure. FIG. 1 is a schematic partial cross-sectional view of a light emitting element of Embodiment 1, FIG. 2 is a schematic partial cross-sectional view of a light emitting element array including a plurality of light emitting elements of Embodiment 1, FIGS. 3 and 4 are schematic partial cross-sectional views of Modified Example-1 and Modified Example-2 of the light emitting element of Embodiment 1, and FIGS. 5 and 6 are schematic plan views illustrating disposition of the first light reflecting layer and the first electrode in the light emitting element array including the plurality of light emitting elements of Embodiment 1. Note that the schematic partial cross-sectional views of the light emitting element or the light emitting element array are schematic partial cross-sectional views taken along arrow A-A in FIGS. 5 and 6, FIG. 5 illustrates a case where the light emitting element is positioned at a vertex (intersection portion) of a square lattice, and FIG. 6 illustrates a case where the light emitting element is positioned at a vertex (intersection portion) of a regular triangle lattice. In the drawings, a Z axis indicates an axial line of a first light reflecting layer 41 included in the light emitting element (a perpendicular line with respect to a stacked structure 20 passing through the center of the first light reflecting layer 41).

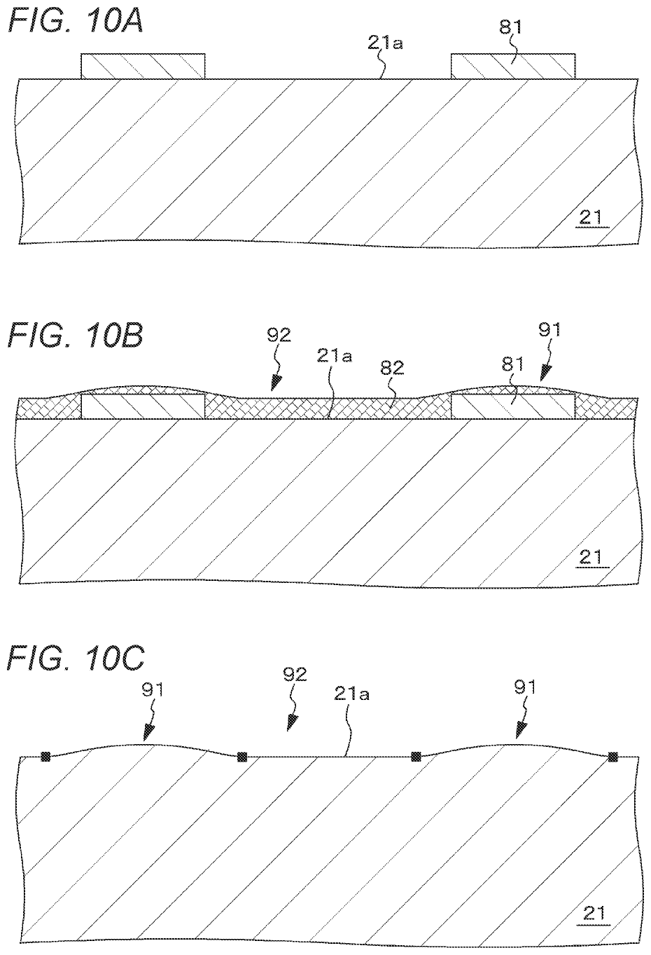

Note that, in FIGS. 10A, 10B, 10C, 13A, 13B, 25, 26A, 26B, 28, 29, 30A, and 30B, illustration of the active layer, the second compound semiconductor layer, the second light reflecting layer, and the like is omitted.

The light emitting element of Embodiment 1 or Embodiments 2 to 24 as described later includes:

the stacked structure 20 in which a first compound semiconductor layer 21 having a first surface 21a and a second surface 21b opposing the first surface 21a, an active layer (light emitting layer) 23 facing the second surface 21b of the first compound semiconductor layer 21, and a second compound semiconductor layer 22 having a first surface 22a facing the active layer 23 and a second surface 22b opposing the first surface 22a are stacked;

the first light reflecting layer 41; and

a second light reflecting layer 42 formed on a second surface side of the second compound semiconductor layer 22 and having a flat shape,

in which a base surface 90 positioned on a first surface side of the first compound semiconductor layer 21 has a protrusion 91 protruding in a direction away from the active layer 23,

a cross-sectional shape of the protrusion 91 in a case where the base surface 90 is cut along a virtual plane (for example, an XZ plane in the illustrated example) including a stacking direction of the stacked structure 20 includes a smooth curve, and

the first light reflecting layer 41 is formed on at least the protrusion 91.

Then, in a light emitting element 10A of Embodiment 1,

2×10⁻⁶ m(2 μm)≤D₁≤2.5×10⁻⁵m(25 μm),

preferably, 1×10⁻⁵ m(10 μm)≤D₁≤2.4×10⁻⁵ m(24 μm), and

more preferably, 1.6×10⁻⁵ m(16 μm)≤D₁≤2.0×10⁻⁵ m(20 μm),

1×10⁻⁸ m(10 nm)≤H₁≤5×10⁻⁷ m(0.5 μm),

preferably, 1×10⁻⁸ m(10 nm)≤H₁≤2×10⁻⁷ m(0.2 μm), and

more preferably, 1×10⁻⁸ m(10 nm)≤H₁≤1×10⁻⁷ m(0.1 μm),

1×10⁻⁴ m(0.1 mm)≤R₁,

preferably, 5×10⁻⁴ m(0.5 mm)≤R₁, and

more preferably, 9×10⁻⁴ m(0.9 mm)≤R₁, and

Ra_{Pj}≤1.0 nm,

preferably, Ra_{Pj}≤0.7 nm, and

more preferably, Ra_{Pj}≤0.3 nm,

where a diameter of the protrusion 91 is D₁, a height of the protrusion 91 is H₁, a radius of curvature of a top portion of the protrusion 91 is R₁, and a surface roughness of the protrusion 91 is Ra_{Pj}.

Furthermore, the light emitting element array of Embodiment 1 includes a plurality of light emitting elements,

in which each of the light emitting elements includes the light emitting element 10A of Embodiment 1, and

a formation pitch P₀ (a distance from an axial line of the first light reflecting layer 41 included in the light emitting element to an axial line of a first light reflecting layer 41 included in an adjacent light emitting element) of the light emitting elements is 3×10⁻⁵ m (30 μm) or less, preferably, 2×10⁻⁶ m (2 μm)≤P₀≤2.8×10⁻⁵ m (28 μm), and more preferably, 1×10⁻⁵ m (10 μm)≤P₀≤2×10⁻⁵ m (20 μm).

In the light emitting element 10A of Embodiment 1, the first surface 21a of the first compound semiconductor layer 21 constitutes the base surface 90. That is, the light emitting element 10A of Embodiment 1 is a light emitting element of the first configuration.

Then, in the light emitting element 10A of Embodiment 1, the first light reflecting layer 41 is formed on at least the protrusion 91. Specifically, the first light reflecting layer 41 is formed on the protrusion 91. However, the present disclosure is not limited thereto, and an extension portion of the first light reflecting layer 41 may be formed in a region of the base surface 90 other than the protrusion 91. Note that the region of the base surface 90 other than a region where the protrusion 91 is formed is denoted by Reference Sign 92, and will hereinafter be referred to as a “second region” for convenience.

In the light emitting element 10A of Embodiment 1 illustrated in FIG. 1, a figure drawn by the protrusion 91 in a case where the protrusion 91 is cut along a virtual plane (for example, the XZ plane in the illustrated example) including the stacking direction (Z-axis direction) of the stacked structure 20 is, for example, a part of a circle.

The stacked structure 20 can be formed using at least one material selected from the group consisting of a GaN-based compound semiconductor, an InP-based compound semiconductor, and a GaAs-based compound semiconductor. In Embodiment 1, specifically, the stacked structure 20 is formed using a GaN-based compound semiconductor.

Specifically, the first compound semiconductor layer 21 includes, for example, an n-GaN layer doped with about 2×10¹⁶ cm⁻³ Si, the active layer 23 has a five-layered multiple quantum well structure in which an In_{0.04}Ga_{0.96}N layer (barrier layer) and an In_{0.16}Ga_{0.84}N layer (well layer) are stacked, and the second compound semiconductor layer 22 includes, for example, a p-GaN layer doped with about 1×10¹⁹ cm⁻³ magnesium. A plane orientation of the first compound semiconductor layer 21 is not limited to a {0001} plane, and may be, for example, a {20-21} plane which is a semipolar plane. The first electrode 31 formed using Ti/Pt/Au is electrically connected to an external circuit or the like via the first pad electrode (not illustrated) formed using Ti/Pt/Au or V/Pt/Au, for example. On the other hand, a second electrode 32 is formed on the second compound semiconductor layer 22, and the second light reflecting layer 42 is formed on the second electrode 32. The second light reflecting layer 42 on the second electrode 32 has a flat shape. The second electrode 32 is formed using a transparent conductive material, specifically, ITO having a thickness of 30 nm. A second pad electrode 33 formed using, for example, Pd/Ti/Pt/Au, Ti/Pd/Au, or Ti/Ni/Au for electrical connection with an external circuit or the like may be formed on or connected to an edge portion of the second electrode 32 (see FIGS. 3 and 4). The first light reflecting layer 41 and the second light reflecting layer 42 have a structure in which a Ta₂O₅ layer and a SiO₂ layer are stacked or a structure in which a SiN layer and a SiO₂ layer are stacked. The first light reflecting layer 41 and the second light reflecting layer 42 each have a multilayer structure as described above, but are illustrated as having one layer for simplification of the drawing. A planar shape of each of the first electrode 31 (specifically, an opening 31′ provided in the first electrode 31), the first light reflecting layer 41, the second light reflecting layer 42, and an opening 34A provided in an insulating layer (current constriction layer) 34 is a circle.

In order to obtain the current constriction region, as described above, the insulating layer (current constriction layer) 34 formed using an insulating material (for example, SiO_{X}, SiN_{X}, or AlO_{X}) may be formed between the second electrode 32 and the second compound semiconductor layer 22, and the insulating layer (current constriction layer) 34 has the opening 34A for injecting a current into the second compound semiconductor layer 22. Alternatively, in order to obtain the current constriction region, the second compound semiconductor layer 22 may be etched by an RIE method or the like to form a mesa structure. Alternatively, a partial layer of the stacked second compound semiconductor layer 22 may be partially oxidized in the lateral direction to form the current constriction region. Alternatively, an impurity (for example, boron) may be ion-implanted into the second compound semiconductor layer 22 to form the current constriction region including a region with a decreased conductivity. Alternatively, these may be appropriately combined. However, the second electrode 32 needs to be electrically connected to a portion (current injection region) of the second compound semiconductor layer 22 through which a current flows due to current confinement.

In the examples illustrated in FIG. 1, the second electrode 32 is common to the light emitting elements 10A included in the light emitting element array, and the second electrode 32 is connected to an external circuit or the like via the first pad electrode (not illustrated). The first electrode 31 is also common to the light emitting elements 10A included in the light emitting element array, and is connected to an external circuit or the like via the first pad electrode (not illustrated). Then, light may be emitted to the outside via the first light reflecting layer 41, or light may be emitted to the outside via the second light reflecting layer 42.

Alternatively, as illustrated in FIG. 3 which is a schematic partial cross-sectional view of Modified Example-1 of the light emitting element 10A of Embodiment 1, the second electrode 32 is individually formed in the light emitting element 10A included in the light emitting element array, and is connected to an external circuit or the like via the second pad electrode 33. The first electrode 31 is common to the light emitting elements 10A included in the light emitting element array, and is connected to an external circuit or the like via the first pad electrode (not illustrated). Then, light may be emitted to the outside via the first light reflecting layer 41, or light may be emitted to the outside via the second light reflecting layer 42.

Alternatively, as illustrated in FIG. 4 which is a schematic partial cross-sectional view of Modified Example-2 of the light emitting element 10A of Embodiment 1, the second electrode 32 is individually formed in the light emitting element 10A included in the light emitting element array. Furthermore, a bump 35 is formed on the second pad electrode 33 formed on the second electrode 32, and connection to an external circuit or the like is made via the bump 35. The first electrode 31 is common to the light emitting elements 10A included in the light emitting element array, and is connected to an external circuit or the like via the first pad electrode (not illustrated). The bump 35 is arranged at a portion on the second surface side of the second compound semiconductor layer 22 facing the base surface 90, and covers the second light reflecting layer 42. Examples of the bump 35 can include a gold (Au) bump, a solder bump, and an indium (In) bump. A method for arranging the bump 35 can be a known method. Then, light is emitted to the outside via the first light reflecting layer 41. Note that the bump 35 may be provided in the light emitting element 10A illustrated in FIG. 1. Examples of a shape of the bump 35 can include a cylindrical shape, an annular shape, and a hemispherical shape.

A value of a thermal conductivity of the stacked structure 20 is higher than a value of a thermal conductivity of the first light reflecting layer 41. A value of a thermal conductivity of a dielectric material of the first light reflecting layer 41 is about 10 watts/(mK) or less. On the other hand, a value of a thermal conductivity of the GaN-based compound semiconductor of the stacked structure 20 is about 50 to 100 watts/(m·K).

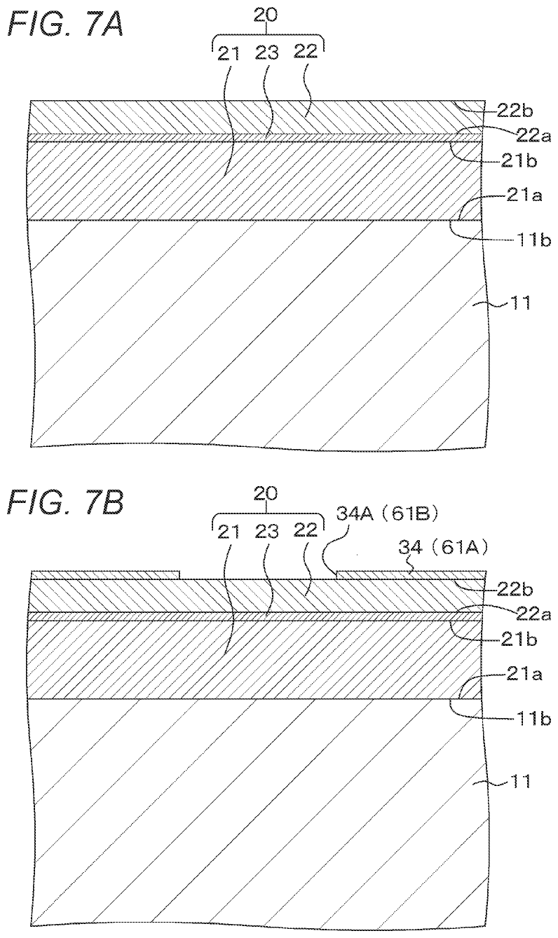

element of Embodiment 1 will be described with reference to FIGS. 7A, 7B, 8, 9, 10A, 10B, and 10C which are schematic partial end views of the first compound semiconductor layer and the like, and the method for manufacturing the light emitting element according to Embodiment 1 or Embodiment 2 as described later is a method for manufacturing the light emitting element including:

the stacked structure 20 in which the first compound semiconductor layer 21 having the first surface 21a and the second surface 21b opposing the first surface 21a, the active layer 23 facing the second surface 21b of the first compound semiconductor layer 21, and the second compound semiconductor layer 22 having the first surface 22a facing the active layer 23 and the second surface 22b opposing the first surface 22a are stacked;

the first light reflecting layer 41; and

the second light reflecting layer 42 formed on the second surface side of the second compound semiconductor layer 22 and having a flat shape,

in which the base surface 90 positioned on the first surface side of the first compound semiconductor layer 21 has the protrusion 91 protruding in a direction away from the active layer 23, and the cross-sectional shape of the protrusion 91 in a case where the base surface 90 is cut along the virtual plane (XZ plane) including the stacking direction of the stacked structure 20 includes a smooth curve.

Then, the method for manufacturing the light emitting element of Embodiment 1 includes:

forming the second light reflecting layer 42 on the second surface side of the second compound semiconductor layer 22 after forming the stacked structure 20;

forming a first sacrificial layer 81 on the base surface 90 on which the protrusion 91 is to be formed;

forming a second sacrificial layer 82 on the entire surface, and then performing etching back from the base surface 90 inward by using the second sacrificial layer 82 and the first sacrificial layer 81 as etching masks to form the protrusion 91 on the base surface 90; and

forming the first light reflecting layer 41 on at least the protrusion 91.

### [Step-100]

Specifically, the stacked structure 20 which is formed using a GaN-based compound semiconductor and in which the first compound semiconductor layer 21 having the first surface 21a and the second surface 21b opposing the first surface 21a, the active layer (light emitting layer) 23 facing the second surface 21b of the first compound semiconductor layer 21, and the second compound semiconductor layer 22 having the first surface 22a facing the active layer 23 and the second surface 22b opposing the first surface 22a are stacked is formed on a second surface 11b of a compound semiconductor substrate 11 having a thickness of about 0.4 mm. More specifically, the stacked structure 20 can be obtained by sequentially forming the first compound semiconductor layer 21, the active layer 23, and the second compound semiconductor layer 22 on the second surface 11b of the compound semiconductor substrate 11 on the basis of an epitaxial growth method by a known MOCVD method (see FIG. 7A).

### [Step-110]

Next, the insulating layer (current constriction layer) 34 having the opening 34A and formed using SiO₂ is formed on the second surface 22b of the second compound semiconductor layer 22 on the basis of a combination of a film forming method such as a CVD method, a sputtering method, or a vacuum vapor deposition method and a wet etching method or a dry etching method (see FIG. 7B). The current constriction region (a current injection region 61A and a current non-injection region 61B) is defined by the insulating layer 34 having the opening 34A. That is, the current injection region 61A is defined by the opening 34A.

In order to obtain the current constriction region, the insulating layer (current constriction layer) 34 formed using an insulating material (for example, SiO_{X}, SiN_{X}, or AlO_{X}) may be formed between the second electrode 32 and the second compound semiconductor layer 22, and the insulating layer (current constriction layer) 34 has the opening 34A for injecting a current into the second compound semiconductor layer 22. Alternatively, in order to obtain the current constriction region, the second compound semiconductor layer 22 may be etched by an RIE method or the like to form a mesa structure. Alternatively, a partial layer of the stacked second compound semiconductor layer 22 may be partially oxidized in the lateral direction to form the current constriction region. Alternatively, an impurity (for example, boron) may be ion-implanted into the second compound semiconductor layer 22 to form the current constriction region including a region with a decreased conductivity. Alternatively, these may be appropriately combined. However, the second electrode 32 needs to be electrically connected to a portion (current injection region) of the second compound semiconductor layer 22 through which a current flows due to current confinement.

### [Step-120]

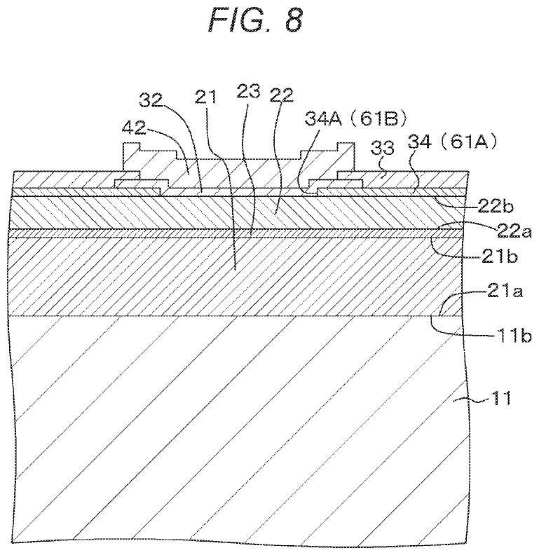

Thereafter, the second electrode 32 and the second light reflecting layer 42 are formed on the second compound semiconductor layer 22. Specifically, the second electrode 32 is formed on the second surface 22b of the second compound semiconductor layer 22 exposed at a bottom surface of the opening 34A (current injection region 61A) and on the insulating layer 34, for example, on the basis of a lift-off method, and further, as desired, the second pad electrode 33 is formed on the basis of a combination of a film forming method such as a sputtering method or a vacuum vapor deposition method and a patterning method such as a wet etching method or a dry etching method. Next, the second light reflecting layer 42 is formed on the second electrode 32 and on the second pad electrode 33 on the basis of a combination of a film forming method such as a sputtering method or a vacuum vapor deposition method and a patterning method such as a wet etching method or a dry etching method. The second light reflecting layer 42 on the second electrode 32 has a flat shape. In this way, the structure illustrated in FIG. 8 can be obtained. Thereafter, as desired, the bump 35 may be arranged at a portion on the second surface side of the second compound semiconductor layer 22 facing the top portion (central portion) of the protrusion 91 of the base surface 90. Specifically, as illustrated in FIG. 4, the bump 35 may be formed on the second pad electrode 33 formed on the second electrode 32 so as to cover the second light reflecting layer 42, and the second electrode 32 is connected to an external circuit or the like via the bump 35.

### [Step-130]

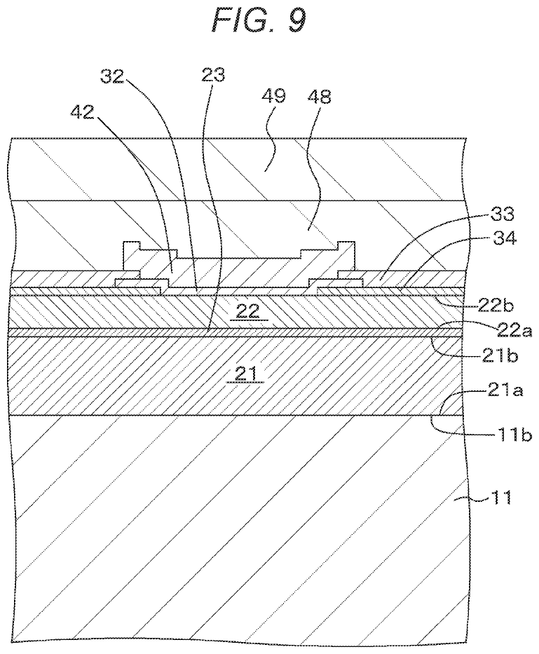

Next, the second light reflecting layer 42 is fixed to a support substrate 49 via a bonding layer 48 (see FIG. 9). Specifically, the second light reflecting layer 42 (or the bump 35) is fixed to the support substrate 49 formed using a sapphire substrate by using the bonding layer 48 formed using an adhesive.

### [Step-140]

Next, the compound semiconductor substrate 11 is thinned on the basis of a mechanical polishing method or a CMP method, and etching is further performed to remove the compound semiconductor substrate 11.

### [Step-150]

Thereafter, the first sacrificial layer 81 is formed on the base surface 90 on which the protrusion 91 is to be formed. Specifically, the first sacrificial layer 81 (specifically, the first sacrificial layer 81 having a quadrangular cross-sectional shape in the XZ plane) is formed on a region where the protrusion 91 of the base surface 90 (more specifically, the first surface 21a of the first compound semiconductor layer 21) on which the first light reflecting layer 41 is to be formed is to be formed. More specifically, a first resist material layer is formed on the first surface 21a of the first compound semiconductor layer 21, and the first resist material layer is patterned so as to leave the first resist material layer on the region where the protrusion 91 is to be formed, thereby obtaining the first sacrificial layer 81 illustrated in FIG. 10A. It is unnecessary to apply heating treatment for deforming the cross-sectional shape to the first sacrificial layer 81. In this way, the first sacrificial layer 81 can be formed on the base surface 90 on which the protrusion 91 is to be formed. In some cases, a surface of the first sacrificial layer 81 may be subjected to asking treatment (plasma irradiation treatment) to modify the surface of the first sacrificial layer 81, thereby preventing occurrence of damage, deformation, or the like of the first sacrificial layer 81 when the second sacrificial layer 82 is formed in the next step. Furthermore, depending on a material of the first resist material layer, the first resist material layer may be heated or irradiated with ultraviolet light to cure the first resist material layer.

### [Step-160]

Thereafter, the second sacrificial layer 82 is formed on the entire surface (see FIG. 10B), and then etching back is performed from the base surface 90 inward (that is, from the first surface 21a of the first compound semiconductor layer 21 to the inside of the first compound semiconductor layer 21) by using the second sacrificial layer 82 and the first sacrificial layer 81 as the etching masks to form the protrusion 91 on the base surface 90 (see FIG. 10C). A connection portion between the protrusion 91 and a second region 92 is indicated by a black square. The etching back can be performed on the basis of a dry etching method such as an RIE method, or can be performed on the basis of a wet etching method using, for example, a hydrochloric acid, a nitric acid, a hydrofluoric acid, or a phosphoric acid, or a mixture thereof. If the second sacrificial layer 82 is formed so that a value of a surface roughness Rq of the second sacrificial layer 82 is lower than a value of a surface roughness Rq of the first compound semiconductor layer 21, a value of a surface roughness Rq of the protrusion 91 after etching back can be lower than that before etching back, such that a scattering loss can be suppressed, and performance as the resonator can be improved. Further, as a result, it is possible to reduce a threshold current of laser oscillation of the light emitting element, reduce power consumption, and improve an output structure, light emission efficiency, and reliability. The value of the surface roughness Rq of the second sacrificial layer 82 is preferably 0.3 nm or less. In addition, speeds at which the second sacrificial layer 82, the first sacrificial layer 81, and the base surface 90 are etched are preferably equal. Note that the surface roughness Rq is specified in JIS B-610:2001, and can be specifically measured on the basis of observation based on AFM or cross-sectional TEM.

Specifically, the second sacrificial layer 82 formed using, for example, a photoresist is formed on the entire surface on the basis of a spin coating method. A film thickness of the second sacrificial layer 82 needs to be smaller than a film thickness at which a surface of the second sacrificial layer 82 including a top portion of the first sacrificial layer 81 becomes flat. A rotation speed in the spin coating method is 10 rpm or more, and for example, 6000 rpm is preferable. As a result, the second sacrificial layer 82 is accumulated at a boundary between the first sacrificial layer 81 and the first compound semiconductor layer 21. Thereafter, baking treatment is performed on the second sacrificial layer 82. A baking temperature is 90° C. or higher, and for example, 120° C. is preferable. With the steps so far, it is possible to obtain the second sacrificial layer 82 having a convex portion on an upper side of the first sacrificial layer 81 and a fan-shaped portion on an upper side of a bottom portion of the first sacrificial layer 81. Thereafter, etching back can performed from the base surface 90 inward (that is, from the first surface 21a of the first compound semiconductor layer 21 to the inside of the first compound semiconductor layer 21) by using the second sacrificial layer 82 and the first sacrificial layer 81 as the etching masks on the basis of an RIE method using SiCl₄ gas and Cl₂ gas as etching gases to form the protrusion 91 on the base surface 90.

In some cases, when the second sacrificial layer 82 is formed on the entire surface, the second sacrificial layer 82 may be formed a plurality of times. Alternatively, after the protrusion 91 is formed on the base surface 90, the second sacrificial layer 82 may be formed on the entire surface, and then etching back may be performed from the base surface 90 inward (that is, from the first surface 21a of the first compound semiconductor layer 21 to the inside of the first compound semiconductor layer 21) by using the second sacrificial layer 82 as the etching mask to form the protrusion 91 on the base surface 90. In this case, the formation of the second sacrificial layer 82 may be performed a plurality of times.

Furthermore, in some cases, in [Step-150], the first sacrificial layer 81 may be formed on the basis of a nanoimprint method.

Furthermore, in some cases, in [Step-150], etching back can be performed from the base surface 90 inward (that is, from the first surface 21a of the first compound semiconductor layer 21 to the inside of the first compound semiconductor layer 21) by using the first sacrificial layer 81 as the etching mask, and in [Step-160], the second sacrificial layer 82 can be formed on the entire surface, and then, etching back can be performed from the base surface 90 inward (that is, from the first surface 21a of the first compound semiconductor layer 21 to the inside of the first compound semiconductor layer 21) by using the second sacrificial layer 82 as the etching mask to form the protrusion 91 on the base surface 90.

The material of the first sacrificial layer 81 and the second sacrificial layer 82 is not limited to the resist material, and it is sufficient if an appropriate material for the first compound semiconductor layer 21, such as a ceramic material such as SOG, an oxide material (for example, SiO₂, SiN, or TiO₂), a semiconductor material (for example, Si, GaN, InP, or GaAs), or a metal material (for example, Ni, Au, Pt, Sn, Ga, In, or Al), is selected. In addition, as a resist material having an appropriate viscosity is used as the resist material of the first sacrificial layer 81 and the second sacrificial layer 82, and as a thickness of the first sacrificial layer 81, a thickness of the second sacrificial layer 82, a diameter of the first sacrificial layer 81, and the like are appropriately set and selected, a value of the radius R₁ of curvature of the protrusion 91, a convex shape of the base surface 90 (for example, the diameter D₁ and the height H₁), and the cross-sectional shape of the protrusion 91 can be set to a desired value and shape. A similar configuration applies to Embodiments 2 to 3 as described later.

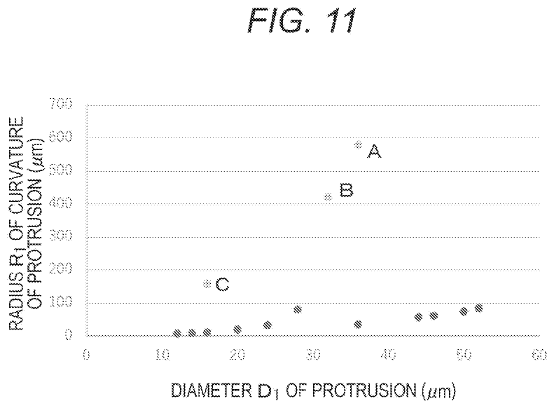

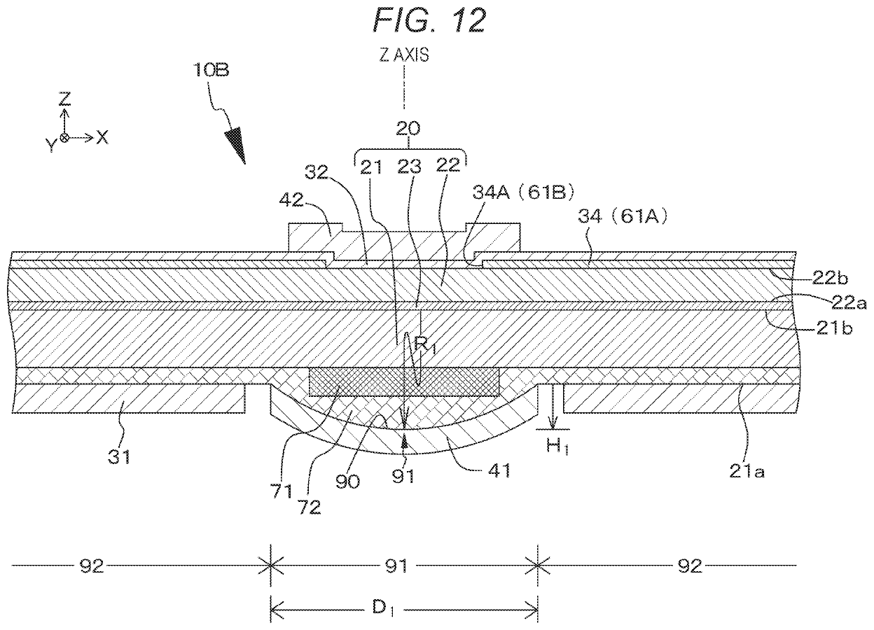

Note that FIG. 11 illustrates a graph in which a relationship between the resist material of the second sacrificial layer 82, the diameter D₁ of the protrusion 91, and the radius R₁ of curvature of the top portion of the protrusion 91 is obtained. However, it is understood that the protrusion 91 having a large radius R₁ of curvature with respect to the diameter D₁ of the protrusion 91 can be obtained as illustrated in “A”, “B”, and “C” in FIG. 11 by appropriately selecting the resist material of the second sacrificial layer 82.

### [Step-170]

Next, the first light reflecting layer 41 is formed on at least the top portion of the protrusion 91 of the base surface 90. Specifically, after the first light reflecting layer 41 is formed on the entire surface of the base surface 90 on the basis of a film forming method such as a sputtering method or a vacuum vapor deposition method, the first light reflecting layer 41 is patterned to obtain the first light reflecting layer 41 on the protrusion 91 of the base surface 90. Thereafter, the first electrode 31 common to the respective light emitting elements 10A is formed on the second region 92 of the base surface 90. As described above, the light emitting element array or the light emitting element 10A of Embodiment 1 can be obtained. In a case where the first electrode 31 protrudes further than the first light reflecting layer 41, the first light reflecting layer 41 can be protected.

### [Step-180]

Thereafter, the support substrate 49 is peeled off, and the light emitting element array is individually separated. Then, the light emitting element array is only required to be electrically connected to an external electrode or circuit (a circuit for driving the light emitting element array). Specifically, it is sufficient if the first compound semiconductor layer 21 is connected to an external circuit or the like via the first electrode 31 and the first pad electrode (not illustrated), and the second compound semiconductor layer 22 is connected to an external circuit or the like via the second pad electrode 33 or the bump 35. Next, the light emitting element array of Embodiment 1 is completed by packaging or sealing.

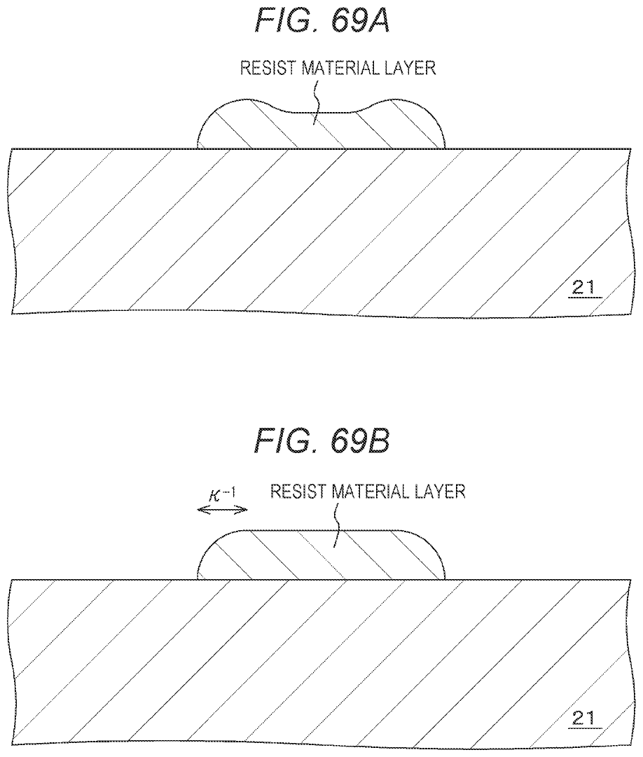

Meanwhile, as described above, due to an influence of wettability, surface tension, gravity, or the like between the first compound semiconductor layer 21 and the resist material layer, or due to specifications required for the first light reflecting layer 41, the resist material layer does not have a desired cross-sectional shape, and as a result, the first light reflecting layer having a desired cross-sectional shape is not obtained in some cases. Specifically, for example, as illustrated in FIGS. 69A and 69B which are schematic partial cross-sectional views, an edge portion of the resist material layer rises and a central portion thereof is recessed (recessed shape), or a top surface of the resist material layer is flat. For example, in the state illustrated in FIG. 69B, a value of K⁻¹ (capillary length) can be expressed as K⁻¹={(γ/(Δρ·g)}^{1/2}. Here, γ is a surface tension (N/m) at an interface, Δρ is a density difference (kg/m³) between a density of the resist material and a density of the first compound semiconductor layer, and g is gravitational acceleration (m/s²). Then, in a case where r_{Resist}>κ⁻¹, where a radius of the resist material layer is r_{Resist}, the top surface of the resist material layer is flat.

In addition, in a case where the resist material layer is thinned, an obtained contact angle is limited due to an influence of a surface tension between the surface of the first compound semiconductor layer 21 and the resist material layer. Therefore, a small contact angle cannot be obtained, and a shape of the resist material layer becomes flat or concave. In order to manufacture a high-output light emitting element, it is necessary to increase the light output of one light emitting element and to form a high-density array. In increasing the light output of one light emitting element, it is sufficient if a light output region is widened, and for this purpose, it is sufficient if a radius of curvature of the first light reflecting layer is increased. In addition, it is sufficient if a large number of light emitting elements are densely arranged in a small region in order to implement a high-density array. That is, it is required to arrange the light emitting elements each including the first light reflecting layer having a small diameter and a large radius of curvature at a small formation pitch. However, in the conventional technology, as described above, there is a theoretical limit to production of the first light reflecting layer. For example, in a case where an attempt is made to form a resist material layer having a diameter of 20 μm and a radius of curvature of 400 μm by the conventional technology, a height of the resist material layer is 124 nm on the basis of the following formula under the assumption that volumes of the resist material layer before and after the heating treatment are equal. Then, in this case, the contact angle between the first compound semiconductor layer 21 and the resist material layer is 0.7 degrees.

(π/4)×D²×t={(π·s)/24}(3D²+4s²)

Here,

D: a diameter of the resist material layer before the heating treatment (=a diameter of the resist material layer after the heating treatment)

t: a thickness of the resist material layer before the heating treatment, and

s: a thickness of the resist material layer after the heating treatment.

However, it is extremely difficult to obtain a material for obtaining a resist material layer having such a shape. This can theoretically only be achieved in a limited system in the vicinity of a boundary between a condition with complete wettability and a condition with complete wettability and incomplete wettability. In particular, in the latter case, in order to implement the contact angle of 0.7 degrees according to the Young-Dupre law, a relationship between tensions in three directions based on a relationship between the first compound semiconductor layer, the resist material layer, and the air needs to satisfy an extremely limited condition expressed as:

(γₛₒ−≡ₛₗ)/γ=cos(θ_{E})=0.9999. Here,

γₛₒ: a surface tension of the first compound semiconductor layer (a force for expanding the resist material layer),

γₛₗ: a surface tension between the first compound semiconductor layer and the resist material layer (a force for preventing an increase in energy due to expansion of an interface between the first compound semiconductor layer and the resist material layer),

γ: a surface tension of the resist material layer, and

θ_{E}: a contact angle.

Therefore, in many material systems, a shape after reflow does not become a spherical surface but becomes a flat or recessed shape. For example, the contact angle between the resist material layer and the first compound semiconductor layer to be used is usually about 15 degrees, and there is a large deviation from the required contact angle of 0.7 degrees.

There is a method of increasing the radius of curvature of the first compound semiconductor layer after etching back by setting a value (etching selectivity) of (a speed at which the first compound semiconductor layer is etched)/(a speed at which the resist material layer is etched) at the time of etching back to be less than 1. However, since the resist material layer as the etching mask is etched earlier, there is a problem that a time for which the first compound semiconductor layer is exposed to an etchant during etching back increases, and the value of the surface roughness of the first compound semiconductor layer after etching back increases. In a case where the value of the surface roughness increases, an optical loss increases, and thus, the threshold current of the light emitting element increases, the light emission efficiency decreases, the output decreases, and the like, which is not preferable. Results of determination of the etching selectivity and the value of the surface roughness Rq of the first compound semiconductor layer after etching back are shown in Table 1 below.

TABLE 1

| Etching selectivity | Rq | |
|---|---|---|
| 0.56 | 1.7 | nm |
| 0.91 | 0.47 | nm |

Furthermore, in a case where the light emitting elements are arranged in the light emitting element array, a footprint diameter of the first sacrificial layer cannot exceed the formation pitch of the light emitting elements. Therefore, in order to decrease the formation pitch in the light emitting element array, it is necessary to decrease the footprint diameter of the first sacrificial layer. Further, the radius R₁ of curvature of the protrusion of the base surface has a positive correlation with the footprint diameter. That is, the footprint diameter decreases as the formation pitch decreases, and as a result, the radius R₁ of curvature decreases. For example, the radius R₁ of curvature of about 30 μm is reported for the footprint diameter of 24 μm. In addition, a radiation angle of light emitted from the light emitting element has a negative correlation with the footprint diameter. That is, the footprint diameter decreases as the formation pitch decreases, and as a result, the radius R₁ of curvature decreases, and a far field pattern (FFP) is expanded. The radiation angle may be several degrees or more at the radius R₁ of curvature of less than 30 μm. Depending on an application field of the light emitting element array, light emitted from the light emitting element may be required to have a small radiation angle of 2 to 3 degrees or less.

In Embodiment 1, the thickness of the first sacrificial layer 81 is 1.1 μm, and the diameter is 20 μm. In addition, specifications of the obtained protrusion 91, the resonator length L_{OR}, the formation pitch P₀ of the light emitting elements in the light emitting element array, and the oscillation wavelength (emission wavelength) λ₀ of the light emitting element are as shown in Table 2 below. Note that a figure drawn by the protrusion 91 in a case where the protrusion 91 is cut along the virtual plane (XZ plane) including the stacking direction of the stacked structure 20 is a part of a circle.

TABLE 2

D₁ = 16 μm
H₁ = 66 nm
R₁ = 570 μm
Ra_{Pj} = 0.3 nm
L_{OR} = 25 μm
P₀ = 20 μm
λ₀ = 450 μm

Furthermore, the radius R₁ of curvature of the light emitting element obtained in a case where the diameter D₁ is 24 μm and the height H₁ is changed was examined. The results are shown in Table 3 below, and it is understood that a larger radius R₁ of curvature can be obtained as the height H₁ decreases.

TABLE 3
Diameter D₁ = 24 μm

| Height H₁ | Radius R₁ of curvature |
|---|---|
| 0.35 μm | 200 μm |
| 0.18 μm | 400 μm |
| 0.11 μm | 650 μm |

In Embodiment 1 or Embodiment 2 as described later, since the protrusion is formed on the base surface on the basis of the first sacrificial layer and the second sacrificial layer, and since the protrusion is formed on the base surface on the basis of the first layer and the second layer in Embodiment 3 as described later, it is possible to form the protrusion having a small diameter D₁, a small height H₁, a large radius R₁ of curvature, and a low surface roughness Ra_{Pj}. As a result, it is possible to obtain the first light reflecting layer having a small diameter, a small height, a large radius of curvature without distortion, and a low surface roughness Ra. Moreover, since it is basically unnecessary to perform heating treatment for deforming the cross-sectional shape of the first sacrificial layer, thermal deterioration of other constituent materials of the light emitting element and characteristic deterioration of the light emitting element can be suppressed.

Moreover, in Embodiment 1, since the protrusion is formed on the base surface on the basis of the first sacrificial layer and the second sacrificial layer, and since the protrusion is formed on the base surface on the basis of the first layer and the second layer in Embodiment 3 as described later, it is possible to obtain the first light reflecting layer having a large radius R₁ of curvature without distortion even in a case where the light emitting elements are arranged at a small formation pitch. Therefore, it is possible to obtain a light emitting element array in which light emitting elements are arranged at a high density. In addition, the radiation angle of the light emitted from the light emitting element can be set to a small radiation angle of 2 to 3 degrees or less or to be as small as possible, such that a light emitting element having a small FFP, a light emitting element having high orientation, and a light emitting element having high beam quality can be provided. Furthermore, since a wide light emission region can be obtained, it is possible to increase the light output of the light emitting element and improve the light emission efficiency.

In addition, since the height (thickness) of the protrusion can be decreased (thinned), when the light emitting element array is connected to and bonded to an external circuit or the like using the bump, a cavity (void) is less likely to be generated in the bump, thermal conductivity can be improved, and mounting is facilitated.

In addition, in the light emitting element of Embodiment 1 or Embodiments 2 to 3 as described later, since the first light reflecting layer also functions as a concave mirror, light diffracted and spreading from the active layer as a starting point and then incident on the first light reflecting layer can be reliably reflected toward the active layer and collected on the active layer. Therefore, an increase in diffraction loss can be avoided, laser oscillation can be reliably performed, and a problem of thermal saturation can be avoided since a long resonator is provided. In addition, since the resonator length can be increased, a tolerance of a process for manufacturing the light emitting element is increased, and as a result, a yield can be improved. Note that the “diffraction loss” refers to a phenomenon in which laser light reciprocating in the resonator is gradually scattered toward the outside of the resonator and lost because light generally tends to spread due to a diffraction effect. In addition, stray light can be suppressed, and optical crosstalk between the light emitting elements can be suppressed. Here, when light emitted from a certain light emitting element flies to an adjacent light emitting element and is absorbed by an active layer of the adjacent light emitting element or coupled to a resonance mode, the light affects a light emitting operation of the adjacent light emitting element and causes noise generation. Such a phenomenon is referred to as optical crosstalk. Moreover, since the top portion of the protrusion is, for example, a spherical surface, an effect of lateral light confinement is reliably exhibited.

In addition, except for Embodiment 8 as described later, a GaN substrate is used in the process of manufacturing the light emitting element, but a GaN-based compound semiconductor is not formed on the basis of a method of epitaxial growing in the lateral direction such as an ELO method. Therefore, as the GaN substrate, not only a polar GaN substrate but also a semipolar GaN substrate or a nonpolar GaN substrate can be used. In a case where a polar GaN substrate is used, light emission efficiency tends to decrease due to an effect of a piezoelectric field in the active layer, but in a case where a nonpolar GaN substrate or a semipolar GaN substrate is used, such a problem can be solved or alleviated.

### Embodiment 2

Embodiment 2 relates to the light emitting element according to the second aspect of the present disclosure. In the light emitting element of Embodiment 2,

2×10⁻³ m(2 mm)≤D₁,

preferably, 5×10⁻³ m(5 mm)≤D₁, and

more preferably, 1×10⁻² m(10 mm)≤D₁,

1×10⁻³ m(1 mm)≤R₁,

preferably, 5×10⁻³ m(5 mm)≤R₁, and

more preferably, 1×10⁻² m(10 mm)≤R₁, and

Ra_{Pj}≤1.0 nm,

preferably, Ra_{Pj}≤_{0.7} nm, and

more preferably, Ra_{Pj}≤0.3 nm.

The light emitting element of Embodiment 2 can be manufactured by a method substantially similar to the method for manufacturing the light emitting element of Embodiment 1. However, in Embodiment 2, the first sacrificial layer 81 has a thickness of 1 μm and a diameter of 2 mm. In addition, specifications of the obtained protrusion 91, the resonator length L_{OR}, and the oscillation wavelength (emission wavelength) λ₀ of the light emitting element are as shown in Table 4 below. Note that a figure drawn by the protrusion 91 in a case where the protrusion 91 is cut along the virtual plane (XZ plane) including the stacking direction of the stacked structure 20 is a part of a circle. As described above, as the thickness of the first sacrificial layer 81, the thickness of the second sacrificial layer 82, the diameter of the first sacrificial layer 81, and the like are appropriately set and selected, the value of the radius of curvature of the protrusion 91, the convex shape of the base surface 90 (for example, the diameter D₁ and the height H₁), and the cross-sectional shape of the protrusion 91 can be set to a desired value and shape.

TABLE 4

D₁ = 2 mm
H₁ = 1 μm
R₁ = 0.5 m
Ra_{Pj} = 0.3 nm
L_{OR} = 25 μm
λ₀ = 450 μm

Alternatively, the first sacrificial layer 81 has a thickness of 50 nm and a diameter of 20 μm. In addition, specifications of the obtained protrusion 91, the resonator length L_{OR}, the formation pitch P₀ of the light emitting elements in the light emitting element array, and the oscillation wavelength (emission wavelength) λ₀ of the light emitting element are as shown in Table 5 below. Note that a figure drawn by the protrusion 91 in a case where the protrusion 91 is cut along the virtual plane (XZ plane) including the stacking direction of the stacked structure 20 is a part of a circle.

TABLE 5

D₁ = 20 μm
H₁ = 50 nm
R₁ = 0.95 mm
Ra_{Pj} = 0.3 nm
L_{OR} = 25 μm
P₀ = 20 μm
λ₀ = 454 μm

In the light emitting element of Embodiment 2 having the specifications shown in Table 5, in a case where a refractive index n₀ of GaN is 2.45, a value of σ of a near field pattern (NFP) can be obtained by the following formula, and σ=1.5. In a case where a diameter of the opening 34A (current injection region 61A) is 6 μm, a size (diameter) of an element region can be represented by 4σ, and thus, the diameter of the element region is 6 μm. Here, “4σ” refers to a region where a light intensity changes from 1.00 to (1/e²) on the basis of a maximum light intensity (1.00) of light emitted from the active layer. Therefore, laser light can be extracted from 100% of the opening 34A (current injection region 61A), and a light output of 25 milliwatts class can be obtained from one light emitting element. In addition, in a case where a light emitting element array including 40 light emitting elements is assumed, it is possible to obtain a watt-class light output.

σ=(½)[{(λ₀/(n₀·π)}(L_{OL}·R₁−L_{OL}²)]^{1/2}

In addition, it is known that a light emitting element in which a transverse mode is a single mode can be obtained as the value of the radius R₁ of curvature increases (see H. Nakajima et. al., “Single transverse mode operation of GaN-based vertical-cavity surface emitting laser with monolithically incorporated curved mirror”, Applied Physics Express 12, 084003 (2019)). Then, in a case where the diameter of the opening 34A (current injection region 61A) is 8 μm, L_{OR}=25 μm, and

λ₀=454 μm, the value of the radius R₁ of curvature is 447 μm or more, and the transverse mode is a single mode. Further, in the light emitting element having the specifications shown in Table 5, it was possible to confirm that the transverse mode is a single mode.

### Embodiment 3

Embodiment 3 relates to the light emitting element according to the third aspect of the present disclosure and the method for manufacturing the light emitting element according to the second aspect of the present disclosure. FIG. 12 is a schematic partial cross-sectional view of a light emitting element 10B of Embodiment 3.

The light emitting element 10B of Embodiment 3 includes:

a stacked structure 20 in which a first compound semiconductor layer 21 having a first surface 21a and a second surface 21b opposing the first surface 21a, an active layer 23 facing the second surface 21b of the first compound semiconductor layer 21, and a second compound semiconductor layer 22 having a first surface 21a facing the active layer 23 and a second surface 21b opposing the first surface 21a are stacked;

the first light reflecting layer 41; and

a second light reflecting layer 42 formed on a second surface side of the second compound semiconductor layer 22 and having a flat shape,

in which a base surface 90 positioned on a first surface side of the first compound semiconductor layer 21 has a protrusion 91 protruding in a direction away from the active layer 23,

the protrusion 91 is constituted by a first layer 71 and a second layer 72 covering the first layer 71,

a cross-sectional shape of the protrusion 91 in a case where the base surface 90 is cut along a virtual plane (for example, an XZ plane in the illustrated example) including a stacking direction of the stacked structure 20 includes a smooth curve, and

the first light reflecting layer 41 is formed on at least the protrusion 91.

Here, the first layer 71 is specifically formed using, for example, an acryl-based resin, and the second layer 72 is specifically formed using, for example, SOG.

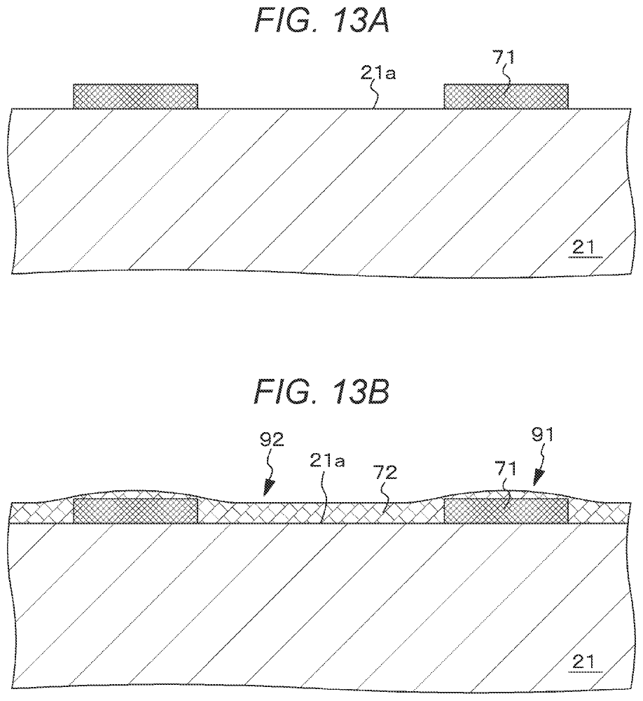

Hereinafter, a method for manufacturing the light emitting element of Embodiment 3 will be described with reference to FIGS. 13A and 13B which are schematic partial end views of the first compound semiconductor layer and the like.

### [Step-300]

In the method for manufacturing the light emitting element of Embodiment 3, first, steps similar to [Step-100] to [Step-140] of Embodiment 1 are performed.

### [Step-310]

Then, the first layer 71 is formed on a portion of the base surface 90 on which the protrusion 91 is to be formed. Specifically, the first layer/forming layer is formed on a portion of a region where the protrusion 91 of the base surface 90 (more specifically, the first surface 21a of the first compound semiconductor layer 21) on which the first light reflecting layer 41 is to be formed is to be formed, and the first layer/forming layer is patterned so as to leave the first layer/forming layer on the portion of the region where the protrusion 91 is to be formed, whereby the first layer 71 illustrated in FIG. 13A can be obtained. It is unnecessary to apply heating treatment for deforming the cross-sectional shape to the first layer 71. In some cases, the first layer 71 may be formed on the basis of a nanoimprint method.

### [Step-320]

Thereafter, the second layer 72 covering the first layer 71 is formed, such that the protrusion 91 constituted by the first layer 71 and the second layer 72 covering the first layer 71 is formed on the base surface 90 (see FIG. 13B). Specifically, the second layer 72 formed using, for example, a photoresist is formed on the entire surface on the basis of a spin coating method. A film thickness of the second layer 72 needs to be smaller than a film thickness at which a surface of the second layer 71 including a top portion of the first layer 72 becomes flat. A rotation speed in the spin coating method is 10 rpm or more, and for example, 6000 rpm is preferable. As a result, the second layer 72 is accumulated at a boundary between the first layer 71 and the first surface 21a of the first compound semiconductor layer 21. Thereafter, baking treatment is performed on the second sacrificial layer 82. A baking temperature is 90° C. or higher, and for example, 120° C. is preferable. With the steps so far, it is possible to obtain the second layer 72 having a convex portion on an upper side of the first layer 71 and a fan-shaped portion on an upper side of a bottom portion of the first layer 71.

### [Step-330]

Next, the first light reflecting layer 41 is formed on at least the protrusion 91. Specifically, steps similar to [Step-170] to [Step-180] of Embodiment 1 are performed. In this way, the light emitting element 10B of Embodiment 3 can be obtained.

Note that, in the step of forming the second layer 72 on the entire surface, the formation of the second layer 72 may be performed a plurality of times.

### Embodiment 4

Embodiment 4 is a modification of Embodiments 1 to 3.

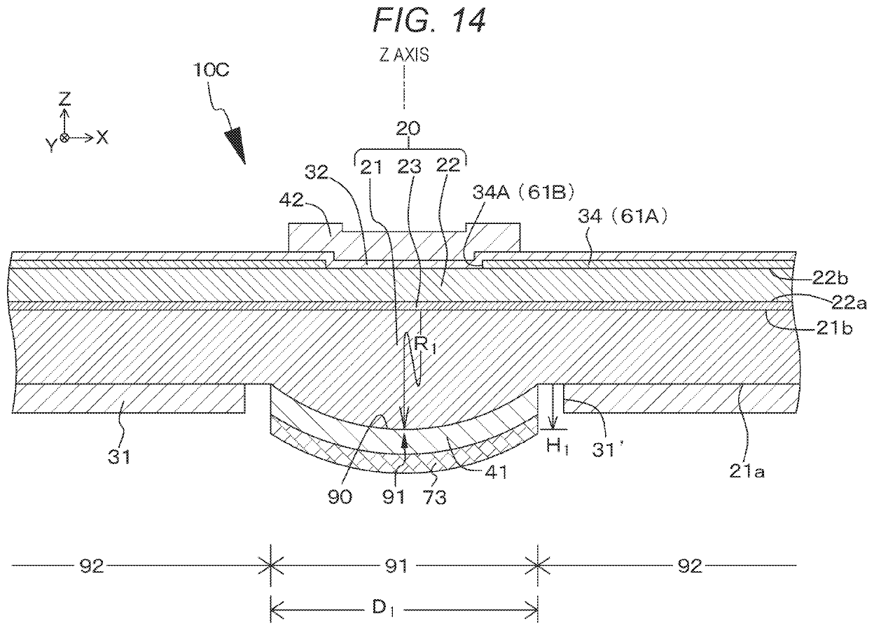

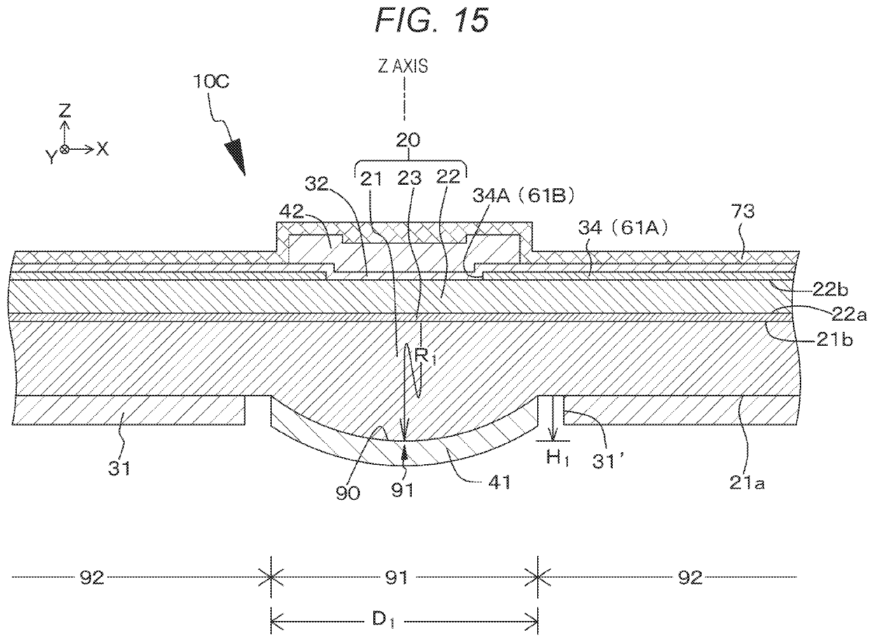

As illustrated in FIGS. 14 and 15 which are schematic partial cross-sectional views of a light emitting element 10C of Embodiment 4, in the light emitting element 10C of Embodiment 4, a wavelength conversion material layer (color conversion material layer) 73 is provided in a region of the light emitting element 10C where light is emitted. Then, white light is emitted via the wavelength conversion material layer (color conversion material layer) 73. Specifically, in a case where light emitted from the active layer 23 is emitted to the outside via the first light reflecting layer 41, it is sufficient if the wavelength conversion material layer (color conversion material layer) 73 is formed on a light emitting side of the first light reflecting layer 41 (see FIG. 14), and in a case where light emitted from the active layer 23 is emitted to the outside via the second light reflecting layer 42, it is sufficient if the wavelength conversion material layer (color conversion material layer) 73 is formed on a light emitting side of the second light reflecting layer 42 (see FIG. 15).

Except for the above point, the light emitting element of Embodiment 4 can have a similar configuration and structure to those of the light emitting elements of Embodiments 1 to 3, and thus a detailed description thereof will be omitted.

### Embodiment 5

Embodiment 5 is a modification of Embodiments 1 to 4.

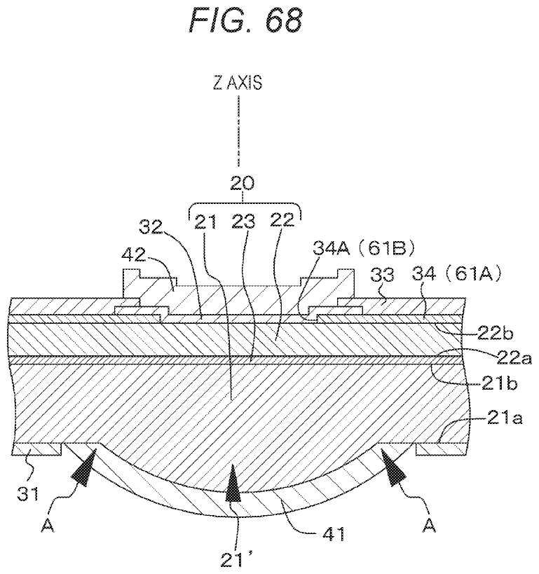

Meanwhile, in the technology disclosed in this International Publication, as illustrated in FIG. 68 which is a schematic partial end view, a convex portion 21′ rises from the flat first compound semiconductor layer 21. A value of a supplementary angle of a rising angle θ_{CA} (as described later) is, for example, 15 degrees or more. Note that a rising portion of the convex portion is indicated by an arrow “A” in FIG. 68. Therefore, in a case where a strong external force is applied to the light emitting element for some reason, stress concentrates on the rising portion of the convex portion, and damage may occur in the first compound semiconductor layer or the like. Furthermore, in a case where such damage reaches the resonator structure, an optical scattering loss occurs, which leads to an increase in threshold current.

The light emitting element of Embodiment 5 has a configuration and structure that are hardly damaged even in a case where a strong external force is applied.

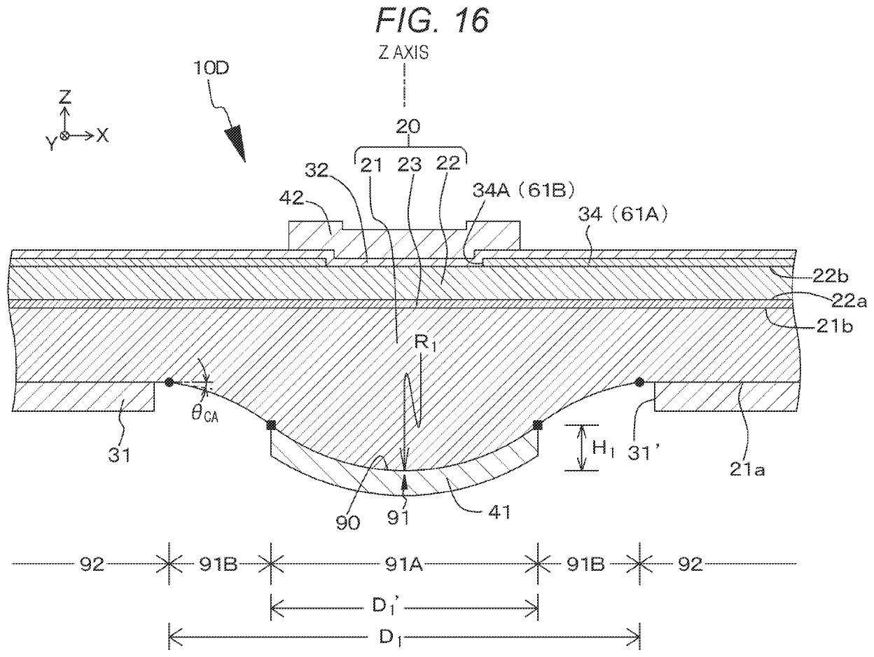

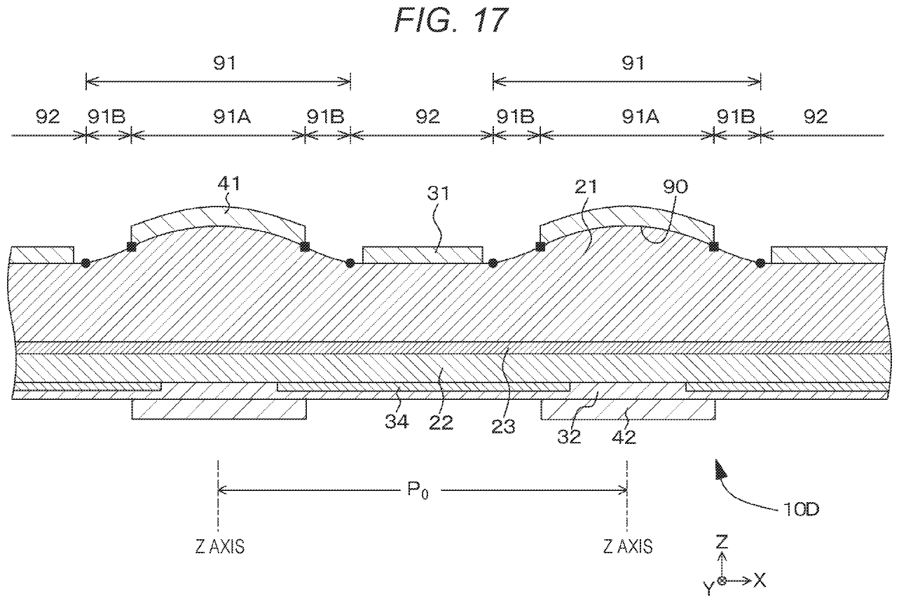

That is, as illustrated in FIG. 16 which is a schematic partial cross-sectional view of a light emitting element 10D of Embodiment 5, and FIG. 17 which is a schematic partial cross-sectional view of a light emitting element array including a plurality of light emitting elements 10D of Embodiment 5, in the light emitting element 10D of Embodiment 5, the base surface 90 positioned on the first surface side of the first compound semiconductor layer 21 has the protrusion 91 protruding in a direction away from the active layer, and the second region 92 surrounding the protrusion 91 and having a flat surface.

Further, the protrusion 91 has a 1-A-th region 91A including the top portion of the protrusion 91 and a 1-B-th region 91B surrounding the 1-A-th region 91A, the first light reflecting layer 41 is formed on at least the 1-A-th region 91A, a first curve formed by the 1-A-th region 91A in a cross-sectional shape of the base surface 90 in a case where the base surface 90 is cut along a virtual plane (for example, the XZ plane in the illustrated example) including the stacking direction of the stacked structure 20 includes an upward convex smooth curve (that is, a smooth curve having a convex shape in a direction away from the active layer 23), a supplementary angle θ_{CA} of an angle formed by a second curve formed by the 1-B-th region 91B and a straight line formed by the second region 92 in the cross-sectional shape of the base surface 90 at an intersection of the second curve and the straight line has a value exceeding 0 degrees (specifically, a value of 1 degree or more and 6 degrees or less), and

the second curve includes at least one kind of figure selected from the group consisting of a downward convex curve (a curve having a convex shape in a direction toward the active layer 23), a line segment, and a combination of arbitrary curves.

Alternatively, the first light reflecting layer 41 is formed on at least the top portion of the protrusion 91, and a supplementary angle θ_{CA} of an angle formed by a curve formed by the protrusion 91 and the straight line formed by the second region 92 in the cross-sectional shape of the base surface 90 in a case where the base surface 90 is cut along the virtual plane (for example, the XZ plane in the illustrated example) including the stacking direction of the stacked structure 20 at an intersection of the curve and the straight line is 1 degree or more and 6 degrees or less.

The first curve can be a figure similar to the above-described figure drawn by the protrusion 91 in a case where the protrusion is cut along the virtual plane including the stacking direction of the stacked structure 20.

Meanwhile, the second curve includes at least one kind of figure selected from the group consisting of a downward convex curve, a line segment, and a combination of arbitrary curves. Specifically, the “downward convex curve” can be a curve similar to the above-described first curve (a part of a circle, a part of a parabola, a part of a sine curve, a part of an ellipse, or a part of a catenary curve). Furthermore, the “combination of arbitrary curves” also includes a line segment and an upward convex curve.

A connection portion between the first curve and the second curve, or a connection portion between a plurality of curves or the like in a case where the second curve includes the plurality of curves or the like may be continuous or smooth in terms of analytics (that is, the connection portion may be differentiable), may be discontinuous in terms of analytics, or does not have to be smooth in terms of analytics (that is, the connection portion may be undifferentiable).

The following combinations can be exemplified as a combination of the first curve and the second curve, in which a “downward convex curve” is represented by [A], a line segment is represented by [B], a combination of arbitrary curves is represented by [C], and “⇒” means “connected” (connection portion).

(1) First curve ⇒[A]

(2) First curve ⇒[B]

(3) First curve ⇒[C]

(4) First curve ⇒any one of [A, B, and C]⇒any one of [A, B, and C]

(5) First curve ⇒any one of [A, B, and C]⇒any one of [A, B, and C]⇒any one of [A, B, and C]

For example, the above (4) means that the first curve is connected to any one of a downward convex curve, a line segment, and a combination of arbitrary curves, and any one of the downward convex curve, the line segment, and the combination of arbitrary curves is further connected to any one of a downward convex curve, a line segment, and a combination of arbitrary curves (however, the curves or the like are not the same as each other).

In the light emitting element 10D of Embodiment 5, the first light reflecting layer 41 is formed in at least the 1-A-th region 91A of the base surface 90. Specifically, the first light reflecting layer 41 is formed in the 1-A-th region 91A of the base surface 90. However, the present disclosure is not limited thereto, and the extension portion of the first light reflecting layer 41 may be formed in the 1-B-th region 91B of the base surface 90, and further, the extension portion of the first light reflecting layer 41 may be formed in the second region 92 of the base surface 90 that occupies the peripheral region.

The light emitting element 10D of Embodiment 5 illustrated in FIGS. 16 and 17 corresponds to the above (1), and in the light emitting element 10D, a figure (first curve) drawn by the 1-A-th region 91A in a case where the 1-A-th region 91A is cut along a virtual plane (for example, the XZ plane in the illustrated example) including the stacking direction (Z-axis direction) of the stacked structure 20 is, for example, a part of a circle. In addition, the second curve formed by the 1-B-th region 91B is a downward convex curve, specifically, for example, a part of a circle. The connection portion between the first curve and the second curve (indicated by a black square) is continuous and smooth in terms of analytics (that is, the connection portion is differentiable). A connection portion between the protrusion 91 (1-B-th region 91B) and the second region 92 is indicated by a black circle.

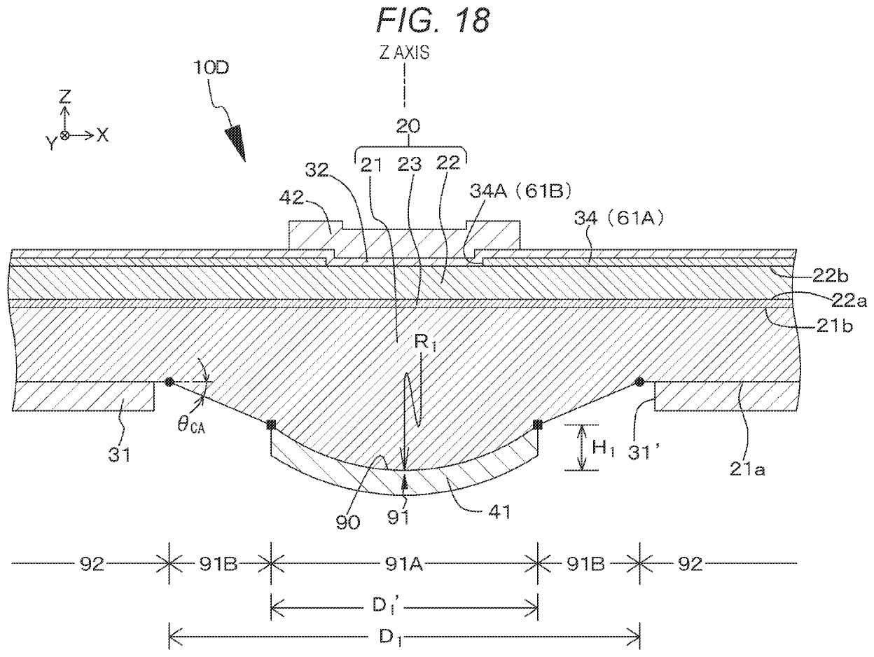

FIG. 18 is a schematic partial cross-sectional view of Modified Example-1 of the light emitting element 10D of Embodiment 5. In Modified Example-1 corresponding to the above (2), the second curve includes a line segment. The connection portion between the first curve and the second curve (indicated by a black square) is continuous and smooth in terms of analytics (that is, the connection portion is differentiable). Alternatively, the connection portion between the first curve and the second curve is not continuous or smooth in terms of analytics (that is, the connection portion is not differentiable).

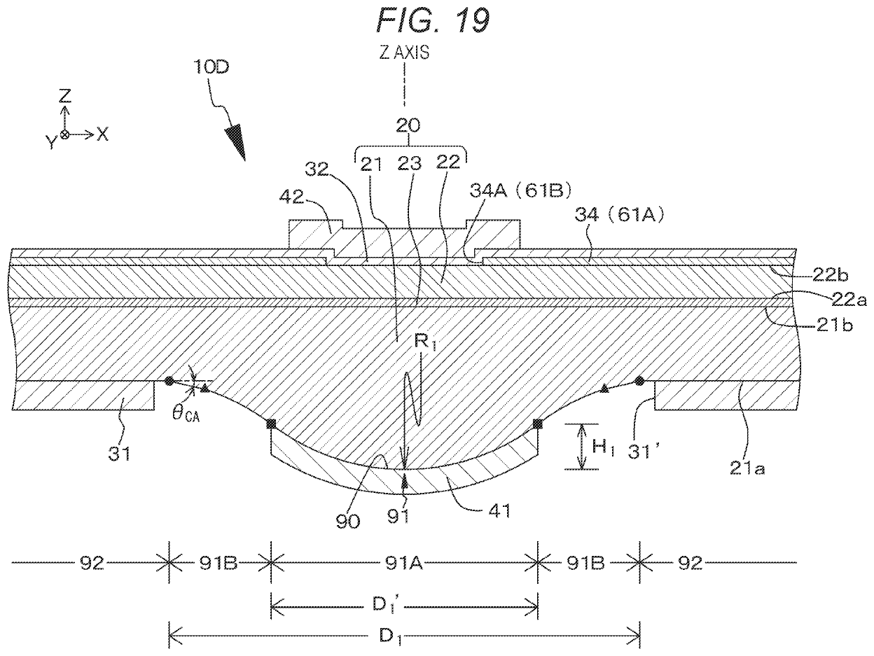

Alternatively, FIG. 19 is a schematic partial cross-sectional view of Modified Example-2 of the light emitting element 10D of Embodiment 5. In Modified Example-2 corresponding to the above (4), the second curve includes a combination of a downward convex curve and a line segment. The connection portion between the first curve and the second curve (indicated by a black square) is continuous and smooth in terms of analytics (that is, the connection portion is differentiable). Alternatively, the connection portion between the first curve and the second curve is not continuous or smooth in terms of analytics (that is, the connection portion is not differentiable). Furthermore, a connection portion (indicated by a black triangle) between the downward convex curve and the line segment included in the second curve is continuous and smooth in terms of analytics (that is, the connection portion is differentiable). Alternatively, the connection portion between the downward convex curve and the line segment included in the second curve is not continuous or smooth in terms of analytics (that is, the connection portion is not differentiable).

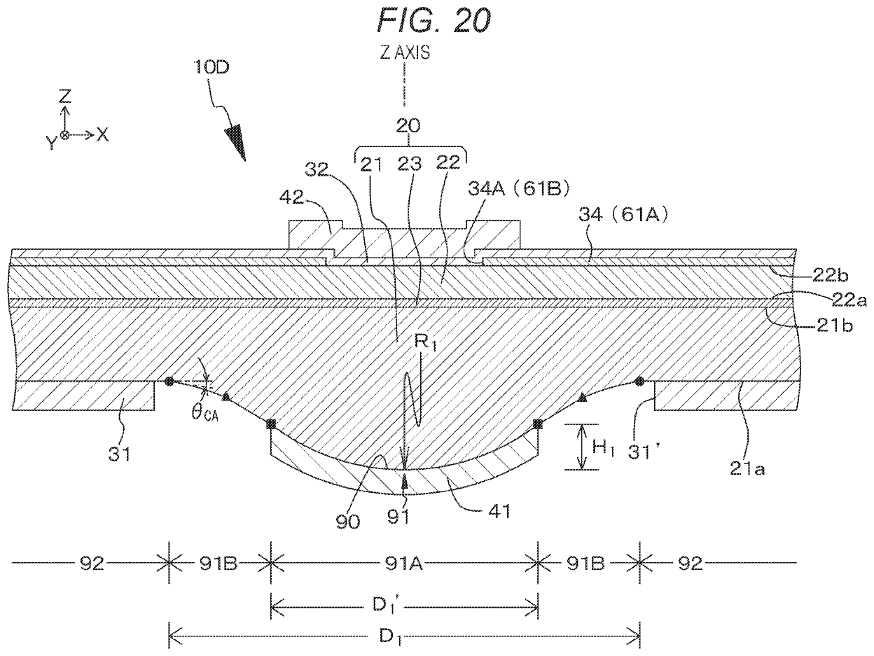

Alternatively, FIG. 20 is a schematic partial cross-sectional view of Modified Example-3 of the light emitting element 10D of Embodiment 5. In Modified Example-3 corresponding to the above (4), the second curve includes a combination of a line segment and a downward convex curve. The connection portion between the first curve and the second curve (indicated by a black square) is continuous and smooth in terms of analytics (that is, the connection portion is differentiable). Alternatively, the connection portion between the first curve and the second curve is not continuous or smooth in terms of analytics (that is, the connection portion is not differentiable). Furthermore, a connection portion (indicated by a black triangle) between the line segment and the downward convex curve included in the second curve is continuous and smooth in terms of analytics (that is, the connection portion is differentiable). Alternatively, the connection portion between the downward convex curve and the line segment included in the second curve is not continuous or smooth in terms of analytics (that is, the connection portion is not differentiable).

The configuration examples of the second curve illustrated in FIG. 18, FIG. 19, and FIG. 20 are examples, and can be appropriately changed as long as the second curve includes at least one type of figure selected from the group consisting of a downward convex curve, a line segment, and a combination of arbitrary curves.

In the light emitting element of Embodiment 5, the supplementary angle θ_{CA} has a value exceeding 0 degrees, and the second curve in the base surface 90 includes at least one kind of figure selected from the group consisting of a downward convex curve, a line segment, and a combination of arbitrary curves. Alternatively, the value of the supplementary angle θ_{CA} is defined. Therefore, even in a case where a strong external force is applied to the light emitting element for some reason, it is possible to reliably avoid problems in the conventional technology such as stress concentration on the rising portion of the base surface, and there is no possibility that the first compound semiconductor layer or the like is damaged. In particular, the light emitting element array is connected to and bonded to an external circuit or the like using the bump, and it is necessary to apply a large load (for example, about 50 MPa) to the light emitting element array at the time of bonding. However, in the light emitting element array of Embodiment 5, even in a case where such a large load is applied, there is no possibility that the light emitting element array is damaged.

### Embodiment 6

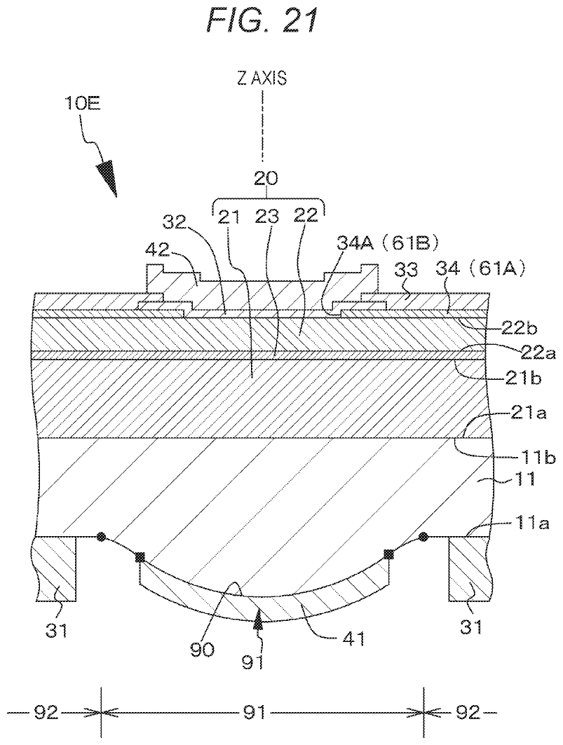

Embodiment 6 is a modification of Embodiments 1 to 5, and relates to the light emitting element of the second configuration. In a light emitting element 10E of Embodiment 6 of which the schematic partial end view is illustrated in FIG. 21, the compound semiconductor substrate 11 is disposed (left) between the first surface 21a of the first compound semiconductor layer 21 and the first light reflecting layer 41, and the base surface 90 is constituted by a surface (first surface 11a) of the compound semiconductor substrate 11.

Note that FIGS. 21, 22, 23, 24A, 24B, 24C, 31, 32, 33, 35, 36, 37, 38, 39, 40, 41, 42, and 43 are schematic partial cross-sectional views of light emitting elements as combinations with Embodiment 5, and it goes without saying that the light emitting element of each embodiment as described later can be applied to the light emitting elements of Embodiments 1 to 4.

In a light emitting element 10E of Embodiment 6, the compound semiconductor substrate 11 is thinned and mirror-finished in a step similar to [Step-140] of Embodiment 1. A value of a surface roughness Rq of the first surface 11a of the compound semiconductor substrate 11 is preferably 10 nm or less. Thereafter, it is sufficient if steps similar to [Step-150] to [Step-180] of Embodiment 1 or [Step-310] to [Step-330] of Embodiment 3 are performed on the first surface 11a of the compound semiconductor substrate 11, and the base surface 90 having the protrusion 91 and the second region 92 is provided in the compound semiconductor substrate 11 instead of the first compound semiconductor layer 21 in Embodiment 1 to complete the light emitting element or the light emitting element array.

Except for the above point, the light emitting element of Embodiment 6 can have a similar configuration and structure to those of the light emitting elements of Embodiments 1 to 5, and thus a detailed description thereof will be omitted.

### Embodiment 7

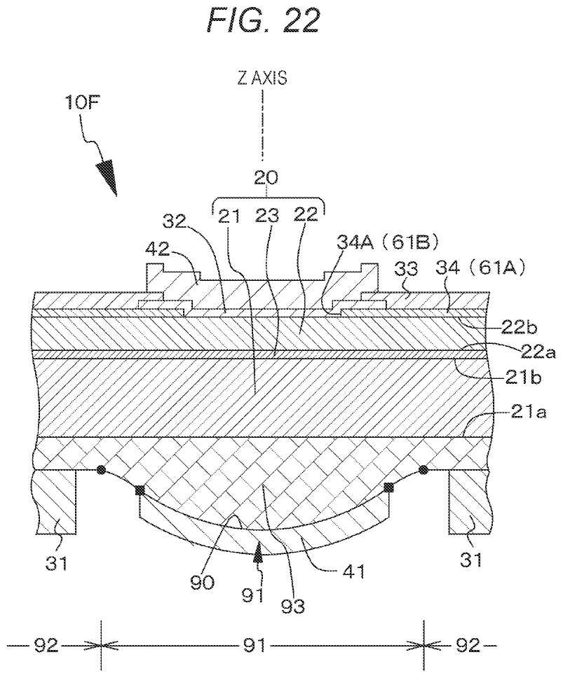

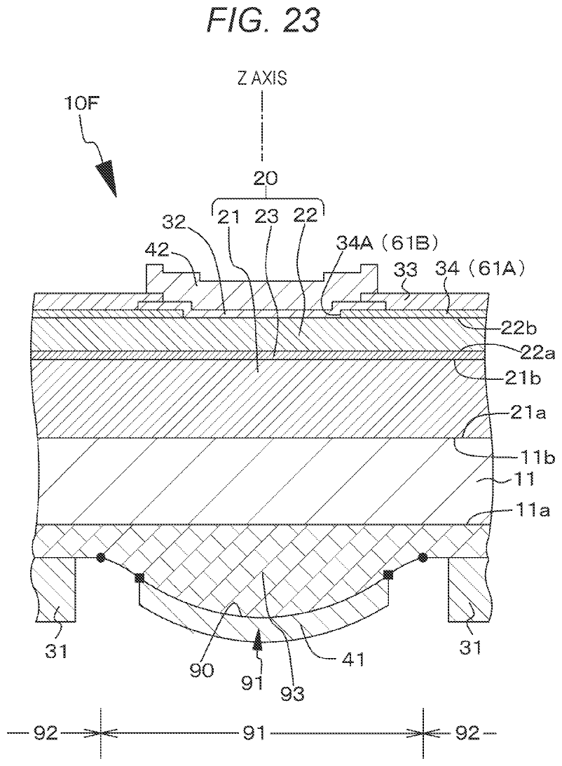

Embodiment 7 is also a modification of Embodiments 1 to 5, and relates to the light emitting element of the third configuration. In a light emitting element 10F of Embodiment 7 of which the schematic partial end view is illustrated in FIG. 22, a base material 93 is disposed between the first surface 21a of the first compound semiconductor layer 21 and the first light reflecting layer 41, and the base surface 90 is constituted by a surface of the base material 93. Alternatively, in a modified example of the light emitting element 10F of Embodiment 7 illustrated in FIG. 23 which is a schematic partial end view, the compound semiconductor substrate 11 and the base material 93 are disposed between the first surface 21a of the first compound semiconductor layer 21 and the first light reflecting layer 41, and the base surface 90 is constituted by the surface of the base material 93. Examples of a material of the base material 93 can include a transparent dielectric material such as TiO₂, Ta₂O₅, or SiO₂, a silicone-based resin, and an epoxy-based resin.

In the light emitting element 10F of Embodiment 7 illustrated in FIG. 22, the compound semiconductor substrate 11 is removed in a step similar to [Step-140] of Embodiment 1, and the base material 93 having the base surface 90 is formed on the first surface 21a of the first compound semiconductor layer 21. Specifically, for example, a TiO₂ layer or a Ta₂O₅ layer is formed on the first surface 21a of the first compound semiconductor layer 21. Then, it is sufficient if steps similar to [Step-150] to [Step-180] of Embodiment 1 or [Step-310] to [Step-330] of Embodiment 3 are performed on the TiO₂ layer or the Ta₂O₅ layer, and the base surface 90 having the protrusion 91 and the second region 92 is provided in the base material 93 (TiO₂ layer or Ta₂O₅ layer) instead of the first compound semiconductor layer 21 in Embodiment 1 to complete the light emitting element or the light emitting element array.

Alternatively, in the light emitting element 10F of Embodiment 7 illustrated in FIG. 23, the base material 93 having the base surface 90 is formed on an exposed surface (first surface 11a) of the compound semiconductor substrate 11 after thinning and mirror-finishing the compound semiconductor substrate 11 in a step similar to [Step-140] of Embodiment 1. Specifically, for example, a TiO₂ layer or a Ta₂O₅ layer is formed on the exposed surface (first surface 11a) of the compound semiconductor substrate 11. Then, it is sufficient if steps similar to [Step-150] to [Step-180] of Embodiment 1 or [Step-310] to [Step-330] of Embodiment 3 are performed on the TiO₂ layer or the Ta₂O₅ layer, and the base surface 90 having the protrusion 91 and the second region 92 is provided in the base material 93 (TiO₂ layer or Ta₂O₅ layer) instead of the first compound semiconductor layer 21 in Embodiment 1 to complete the light emitting element or the light emitting element array.

Except for the above point, the light emitting element of Embodiment 7 can have a similar configuration and structure to those of the light emitting elements of Embodiments 1 to 5, and thus a detailed description thereof will be omitted.

### Embodiment 8

Embodiment 8 is a modification of Embodiment 7. A schematic partial end view of the light emitting element of Embodiment 8 is substantially similar to FIG. 23, and the light emitting element of Embodiment 8 can have a substantially similar configuration and structure to those of the light emitting element of Embodiment 7, and thus, a detailed description thereof will be omitted.

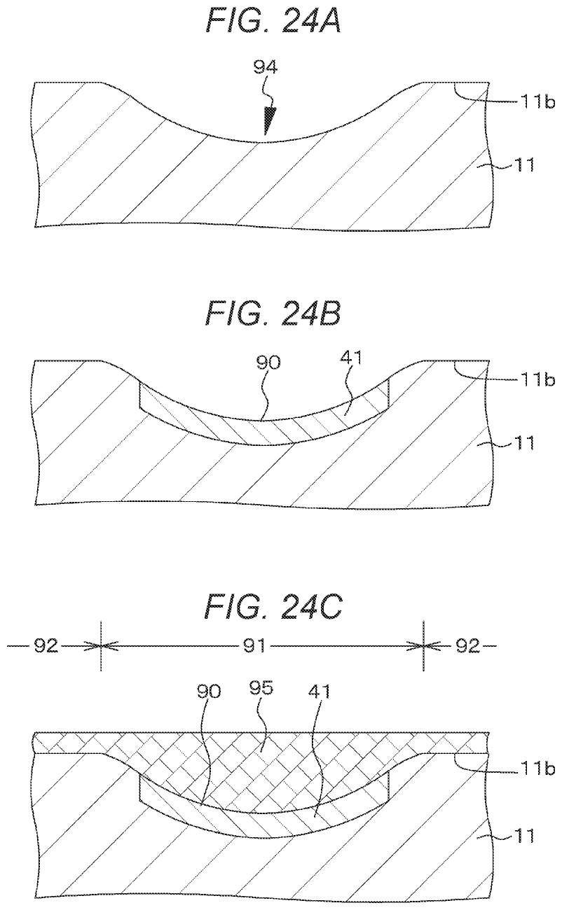

In Embodiment 8, first, an uneven portion 94 for forming the base surface 90 is formed in a second surface 11b of a light emitting element manufacturing substrate 11 (see FIG. 24A). Then, after the first light reflecting layer 41 formed using a multilayer film is formed in the second surface 11b of the light emitting element manufacturing substrate 11 (see FIG. 24B), a planarization film 95 is formed on the first light reflecting layer 41 and the second surface 11b, and the planarization film 95 is subjected to planarization processing (see FIG. 24C).

Next, the stacked structure 20 is formed on the planarization film 95 of the light emitting element manufacturing substrate 11 including the first light reflecting layer 41 on the basis of lateral growth by using a method of epitaxial growing in the lateral direction such as an ELO method. Thereafter, [Step-110] and [Step-120] of Embodiment 1 are performed. Then, the light emitting element manufacturing substrate 11 is removed, and the first electrode 31 is formed on the exposed planarization film 95. Alternatively, the first electrode 31 is formed on a first surface 11a of the light emitting element manufacturing substrate 11 without removing the light emitting element manufacturing substrate 11.

### Embodiment 9

Embodiment 9 is a modification of Embodiments 1 to 8. In Embodiments 1 to 8, the stacked structure 20 is formed using a GaN-based compound semiconductor. On the other hand, in Embodiment 9, the stacked structure 20 is formed using an InP-based compound semiconductor or a GaAs-based compound semiconductor. Specifications of the light emitting element of Embodiment 9 are shown in Table 6 below.

TABLE 6
Second light reflecting layer 42 SiO₂/Ta₂O₅ (11.5 pairs)
Second electrode 32 ITO (thickness: 22 nm)
Second compound semiconductor layer 22 p-InP
Active layer 23 InGaAs (multiple quantum well structure), AlInGaAsP
(multiple quantum well structure), or InAs quantum dot
First compound semiconductor layer 21 n-InP
First light reflecting layer 41 SiO₂/Ta₂O₅ (14 pairs)
Resonator length L_{OR} 25 μm
Oscillation wavelength (emission wavelength) λ₀ 1.6 μm

Specifications of the light emitting element in the light emitting element array of Embodiment 9 (however, the stacked structure 20 is formed using a GaAs-based compound semiconductor) are shown in Table 7 below.

TABLE 7

Second light reflecting layer 42 SiO₂/SiN (9 pairs)
Second electrode 32 ITO (thickness: 22 nm)
Second compound semiconductor layer 22 p-GaAs
Active layer 23 InGaAs (multiple quantum well structure), GaInNAs
(multiple quantum well structure), or InAs quantum dot
First compound semiconductor layer 21 n-GaAs
First light reflecting layer 41 SiO₂/Ta₂O₅ (14 pairs)
Resonator length L_{OR} 25 μm
Oscillation wavelength (emission wavelength) λ₀ 0.94 μm

Hereinafter, various modified examples of the light emitting elements of Embodiments 1 to 9 and the light emitting element of the present disclosure and the like having the above-described preferable form and configuration will be described, and then Embodiments 10 to 24 will be described.

In the light emitting element of the present disclosure and the like having the above-described preferable form and configuration can have a configuration in which a current injection region and a current non-injection region surrounding the current injection region are provided in the second compound semiconductor layer, and the shortest distance D_{CI} from an area center point of the current injection region to a boundary between the current injection region and the current non-injection region satisfies the following formula. Here, the light emitting element having such a configuration is referred to as a “light emitting element of a fourth configuration” for convenience. Note that, for derivation of the following formula, see, for example, H. KogeInik and T. Li, “Laser Beams and Resonators”, Applied Optics/Vol. 5, No. 10/October 1966. Furthermore, ω₀ is also called a beam waist radius.

D_{CI}≥ω₀/2 (1-1)

Provided that,

ω₀²≡(λ₀/π){L_{OR}(R₁−L_{OR})}^{1/2} (1-2)

where

λ₀: a desired wavelength of light mainly emitted from the light emitting element (oscillation wavelength)

L_{OR}: a resonator length

R₁: a radius of curvature of the top portion of the protrusion of the base surface (that is, the radius of curvature of the first light reflecting layer)

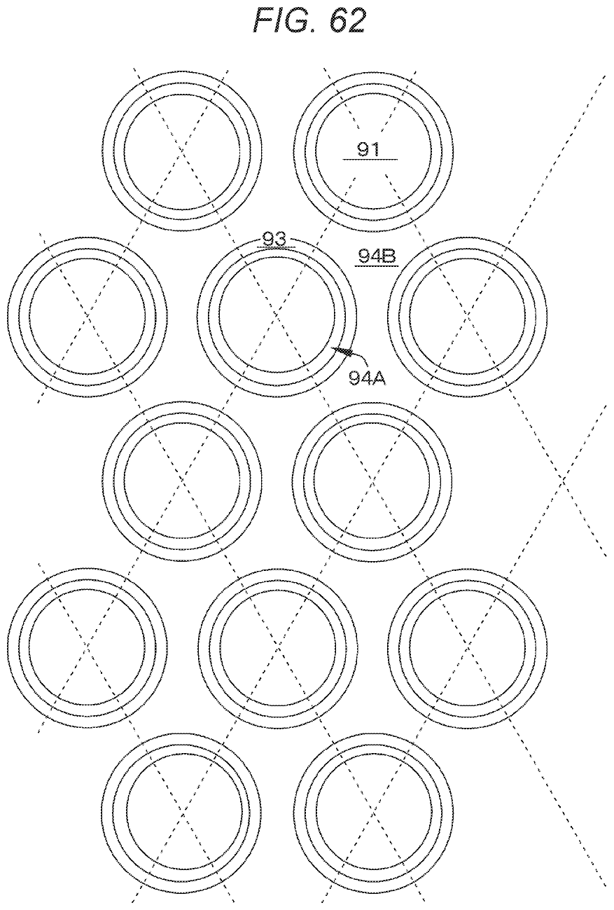

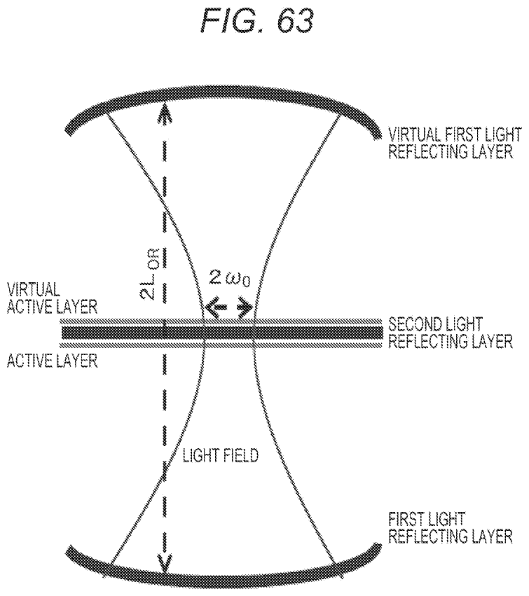

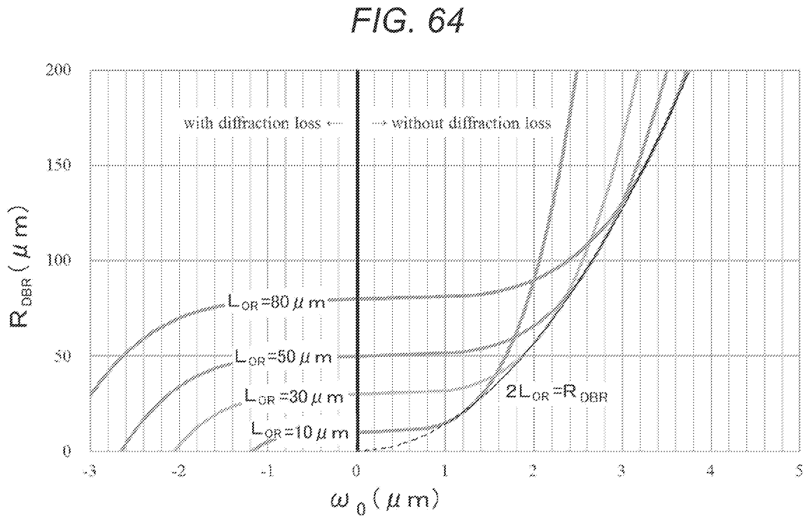

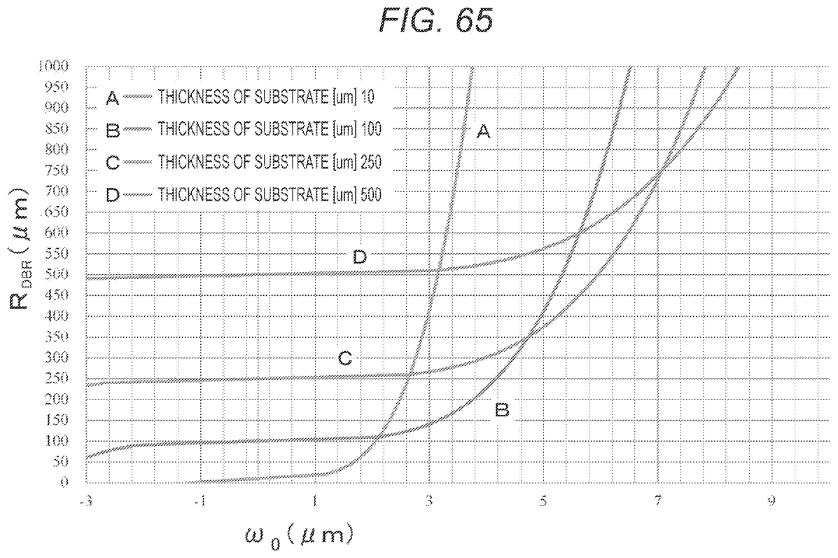

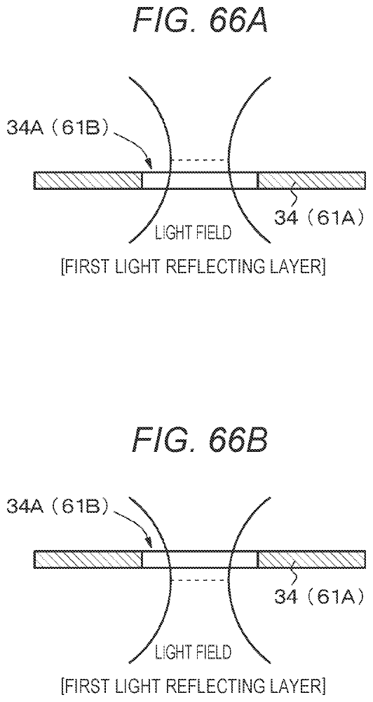

Here, in the light emitting element of the present disclosure and the like, only the first light reflecting layer has a concave mirror shape, but considering symmetry of the second light reflecting layer with respect to a flat mirror, the resonator can be expanded to a Fabry-Perot resonator sandwiched between two concave mirror portions having the same radius of curvature (see the schematic diagram of FIG. 63). At this time, a resonator length of a virtual Fabry-Perot resonator is twice the resonator length L_{OR} FIGS. 64 and 65 are graphs illustrating a relationship between a value of ω₀, a value of the resonator length L_{OR}, and a value of the radius R₁ of curvature of the first light reflecting layer. Note that, in FIGS. 64 and 65, the radius R₁ of curvature is indicated by “R_{DBR}”. The value of ω₀ being “positive” indicates that laser light is schematically in the state illustrated in FIG. 66A, and the value of ω₀ being “negative” indicates that laser light is schematically in the state illustrated in FIG. 66B. The state of the laser light may be the state illustrated in FIG. 66A or the state illustrated in FIG. 66B. However, in the virtual Fabry-Perot resonator having the two concave mirror portions, when the radius R₁ of curvature becomes smaller than the resonator length L_{OR}, the state of the laser light becomes the state illustrated in FIG. 66B, such that confinement becomes excessive and a diffraction loss occurs. Therefore, the state illustrated in FIG. 66A in which the radius R₁ of curvature is larger than the resonator length L_{OR} is preferable. Note that, in a case where the active layer is disposed close to a flat light reflecting layer of two light reflecting layers, specifically, the second light reflecting layer, the light field is further collected in the active layer. That is, light field confinement in the active layer is enhanced, and laser oscillation is facilitated. A position of the active layer, that is, a distance from the surface of the second light reflecting layer facing the second compound semiconductor layer to the active layer is not limited, but λ₀/2 to 10λ₀ can be exemplified.

By the way, in a case where a region where light reflected by the first light reflecting layer is collected is not included in the current injection region corresponding to a region where the active layer has a gain by current injection, there is a possibility that stimulated emission of light from a carrier is inhibited, and eventually laser oscillation is inhibited. In a case where the above Formulas (1-1) and (1-2) are satisfied, it is possible to ensure that the region where the light reflected by the first light reflecting layer is collected is included in the current injection region, and laser oscillation can be reliably achieved.

Further, the light emitting element of the fourth configuration can have a configuration in which a mode loss acting portion provided on the second surface of the second compound semiconductor layer and constituting a mode loss acting region acting on an increase or decrease in oscillation mode loss, the second electrode formed on the second surface of the second compound semiconductor layer and on the mode loss acting portion, and the first electrode electrically connected to the first compound semiconductor layer are further included, the second light reflecting layer is formed on the second electrode, the current injection region, a current non-injection/inner region surrounding the current injection region, and a current non-injection/outer region surrounding the current non-injection/inner region are formed in the stacked structure, and an orthogonal projection image of the mode loss acting region and an orthogonal projection image of the current non-injection/outer region overlap each other.

Then, the light emitting element of the fourth configuration having such a preferable configuration can have a configuration in which a radius r₁ (=D₁′/2) of a light reflection effective region of the first light reflecting layer satisfies ω₀≤r₁≤20·ω₀, preferably, ω₀≤r₁≤10·ω₀. Furthermore, the light emitting element of the fourth configuration having such a preferable configuration can have a configuration in which D_{CI}≥ω₀.

In addition, the light emitting element of the present disclosure and the like having the above-described preferable form and configuration can have a configuration in which the mode loss acting portion provided on the second surface of the second compound semiconductor layer and constituting the mode loss acting region acting on an increase or decrease in oscillation mode loss, the second electrode formed on the second surface of the second compound semiconductor layer and on the mode loss acting portion, and the first electrode electrically connected to the first compound semiconductor layer are further included, the second light reflecting layer is formed on the second electrode, the current injection region, the current non-injection/inner region surrounding the current injection region, and the current non-injection/outer region surrounding the current non-injection/inner region are formed in the stacked structure, and the orthogonal projection image of the mode loss acting region and the orthogonal projection image of the current non-injection/outer region overlap each other. Here, the light emitting element having such a configuration is referred to as a “light emitting element of a fifth configuration” for convenience.

Alternatively, the light emitting element of the present disclosure and the like having the above-described preferable form and configuration can have a configuration in which the second electrode formed on the second surface of the second compound semiconductor layer, the second light reflecting layer formed on the second electrode, the mode loss acting portion provided on the first surface of the first compound semiconductor layer and constituting the mode loss acting region acting on an increase or decrease in oscillation mode loss, and the first electrode electrically connected to the first compound semiconductor layer are further included, the first light reflecting layer is formed on the first surface of the first compound semiconductor layer and on the mode loss acting portion, the current injection region, the current non-injection/inner region surrounding the current injection region, and the current non-injection/outer region surrounding the current non-injection/inner region are formed in the stacked structure, and the orthogonal projection image of the mode loss acting region and the orthogonal projection image of the current non-injection/outer region overlap each other. Here, the light emitting element having such a configuration is referred to as a “light emitting element of a sixth configuration” for convenience. Note that definition of the light emitting element of the sixth configuration can be applied to the light emitting element of the fourth configuration.

In the light emitting element of the fifth configuration or the light emitting element of the sixth configuration, the current non-injection region (a generic term of the current non-injection/inner region and the current non-injection/outer region) is formed in the stacked structure, but specifically, the current non-injection region may be formed in a region on a side of the second compound semiconductor layer where the second electrode is present in the thickness direction, may be formed in the entire second compound semiconductor layer, may be formed in the second compound semiconductor layer and the active layer, or may be formed in the second compound semiconductor layer and in a part of the first compound semiconductor layer. Although the orthogonal projection image of the mode loss acting region and the orthogonal projection image of the current non-injection/outer region overlap each other, in a region sufficiently away from the current injection region, the orthogonal projection image of the mode loss acting region and the orthogonal projection image of the current non-injection/outer region do not have to overlap each other.

The light emitting element of the fifth configuration can have a configuration in which the current non-injection/outer region is positioned below the mode loss acting region.

The light emitting element of the fifth configuration having the above-described preferable configuration can have a configuration in which 0.01≤S₁/(S₁+S₂)≤0.7, where an area of an orthogonal projection image of the current injection region is Si, and an area of an orthogonal projection image of the current non-injection/inner region is S₂. Further, the light emitting element of the sixth configuration can have a configuration in which 0.01≤S₁′/(S₁′+S₂′)≤0.7, where an area of the orthogonal projection image of the current injection region is S₁′, and an area of the orthogonal projection image of the current non-injection/inner region is S₂′. However, a range of S₁/(S₁′+S₂) and a range of S₁′/(S₁′+S₂′) are not limited or restricted to the above-described ranges.

In the light emitting element of the fifth configuration or the light emitting element of the sixth configuration having the above-described preferable configuration can have a configuration in which the current non-injection/inner region and the current non-injection/outer region are formed by ion implantation into the stacked structure. The light emitting element having such a configuration is referred to as a “light emitting element of a 5-A-th configuration” or a “light emitting element of a 6-A-th configuration” for convenience. Then, in this case, an ion type may be at least one type of ion (that is, one type of ion or two or more types of ions) selected from the group consisting of boron, proton, phosphorus, arsenic, carbon, nitrogen, fluorine, oxygen, germanium, zinc, and silicon.

Alternatively, in the light emitting element of the fifth configuration or the light emitting element of the sixth configuration having the above-described preferable configuration can have a configuration in which the current non-injection/inner region and the current non-injection/outer region are formed by plasma irradiation on the second surface of the second compound semiconductor layer, asking treatment on the second surface of the second compound semiconductor layer, or reactive ion etching treatment on the second surface of the second compound semiconductor layer. The light emitting element having such a configuration is referred to as a “light emitting element of a 5-B-th configuration” or a “light emitting element of a 6-B-th configuration” for convenience. In these treatments, since the current non-injection/inner region and the current non-injection/outer region are exposed to plasma particles, conductivity of the second compound semiconductor layer is deteriorated, and the current non-injection/inner region and the current non-injection/outer region are in a high resistance state. That is, the current non-injection/inner region and the current non-injection/outer region can be formed by exposure of the second surface of the second compound semiconductor layer to the plasma particles. Specifically, examples of the plasma particles can include argon, oxygen, and nitrogen.

Alternatively, the light emitting element of the fifth configuration or the light emitting element of the sixth configuration having the above-described preferable configuration can have a configuration in which the second light reflecting layer has a region that reflects or scatters light from the first light reflecting layer toward the outside of the resonator structure including the first light reflecting layer and the second light reflecting layer. The light emitting element having such a configuration is referred to as a “light emitting element of a 5-C-th configuration” or a “light emitting element of a 6-C-th configuration” for convenience. Specifically, a region of the second light reflecting layer positioned above a side wall of the mode loss acting portion (a side wall of an opening provided in the mode loss acting portion) has a forward tapered inclination, or has a region curved convexly toward the first light reflecting layer. Alternatively, the light emitting element of the fifth configuration or the light emitting element of the sixth configuration having the above-described preferable configuration can have a configuration in which the first light reflecting layer has a region that reflects or scatters light from the second light reflecting layer toward the outside of the resonator structure including the first light reflecting layer and the second light reflecting layer. Specifically, it is sufficient if a forward tapered inclination is formed in a partial region of the first light reflecting layer, or a convexly curved portion is formed toward the second light reflecting layer, or a region of the first light reflecting layer positioned above the side wall of the mode loss acting portion (the side wall of the opening provided in the mode loss acting portion) has a forward tapered inclination, or has a region curved convexly toward the second light reflecting layer. In addition, by scattering light at a boundary (side wall edge portion) between a top surface of the mode loss acting portion and the side wall of the opening provided in the mode loss acting portion, light can be scattered toward the outside of the resonator structure including the first light reflecting layer and the second light reflecting layer.

The light emitting element of the 5-A-th configuration, the light emitting element of the 5-B-th configuration, or the light emitting element of the 5-C-th configuration described above can have a configuration in which OL₀>OL₂, where an optical distance from the active layer to the second surface of the second compound semiconductor layer in the current injection region is OL₂, and an optical distance from the active layer to the top surface of the mode loss acting portion in the mode loss acting region is OL₀. Further, the light emitting element of the 6-A-th configuration, the light emitting element of the 6-B-th configuration, or the light emitting element of the 6-C-th configuration described above can have a configuration in which, OL₀′>OL₁′, where an optical distance from the active layer to the first surface of the first compound semiconductor layer in the current injection region is OL₁′, and an optical distance from the active layer to the top surface of the mode loss acting portion in the mode loss acting region is OL₀′. Furthermore, the light emitting element of the 5-A-th configuration, the light emitting element of the 6-A-th configuration, the light emitting element of the 5-B-th configuration, the light emitting element of the 6-B-th configuration, the light emitting element of the 5-C-th configuration, or the light emitting element of the 6-C-th configuration described above having these configurations can have a configuration in which generated light having a higher-order mode is scattered toward the outside of the resonator structure including the first light reflecting layer and the second light reflecting layer and lost by the mode loss acting region, and thus an oscillation mode loss is increased. That is, light field intensities of a basic mode and the higher-order mode generated decrease as the distance from the Z axis increases in the orthogonal projection image of the mode loss acting region due to the presence of the mode loss acting region acting on an increase or decrease in oscillation mode loss, but a mode loss of the higher-order mode is larger than the decrease in light field intensity of the basic mode, such that the basic mode can thus be further stabilized, and since the mode loss can be suppressed as compared with a case where a current injection inner region is not present, a threshold current can be reduced. Note that, for convenience, an axial line (the perpendicular line with respect to the stacked structure passing through the center of the first light reflecting layer) passing through the center of the resonator formed by two light reflecting layers is the Z axis, and a virtual plane orthogonal to the Z axis is an XY plane.

Furthermore, in the light emitting element of the 5-A-th configuration, the light emitting element of the 6-A-th configuration, the light emitting element of the 5-B-th configuration, the light emitting element of the 6-B-th configuration, the light emitting element of the 5-C-th configuration, or the light emitting element of the 6-C-th configuration described above can have a configuration in which the mode loss acting portion is formed using a dielectric material, a metal material, or an alloy material. Examples of the dielectric material can include SiO_{X}, SiN_{X}, AlN_{X}, AlO_{X}, TaO_{X}, and ZrO_{X}, and examples of the metal material or the alloy material can include titanium, gold, platinum, and an alloy thereof, but are not limited to these materials. Light can be absorbed by the mode loss acting portion formed using these materials, thereby increasing the mode loss. Alternatively, the mode loss can be controlled by disturbing a phase without directly absorbing light. In this case, the mode loss acting portion can be formed using the dielectric material, and an optical thickness to of the mode loss acting portion can be a value deviating from an integral multiple of ¼ of the wavelength λ₀ of the light generated in the light emitting element. That is, it is possible to destroy a standing wave by disturbing a phase of light circulating in the resonator and forming the standing wave at the mode loss acting portion and to give a corresponding mode loss. Alternatively, the mode loss acting portion can be formed using the dielectric material, and the optical thickness to of the mode loss acting portion (a refractive index is no) can be an integral multiple of ¼ of the wavelength λ₀ of the light generated in the light emitting element. That is, the optical thickness to of the mode loss acting portion can be a thickness at which the standing wave is not destroyed without disturbing the phase of the light generated in the light emitting element. However, it is not necessary that the optical thickness t₀ is strictly an integral multiple of ¼, and it is sufficient if (λ₀/4n₀)×m−(λ₀/8n₀)≤t₀≤(λ₀/4n₀)×2m+(λ₀/8n₀). Alternatively, by forming the mode loss acting portion by using the dielectric material, the metal material, or the alloy material, light passing through the mode loss acting portion can be disturbed in phase or absorbed by the mode loss acting portion. Then, by employing these configurations, the oscillation mode loss can be controlled with a higher degree of freedom, and the degree of freedom in designing the light emitting element can be further increased.

Alternatively, the light emitting element of the fifth configuration having the above-described preferable configuration can have a configuration in which the convex portion is formed on the second surface side of the second compound semiconductor layer, and the mode loss acting portion is formed on a region of the second surface of the second compound semiconductor layer surrounding the convex portion. The light emitting element having such a configuration is referred to as a “light emitting element of a 5-D-th configuration” for convenience. The convex portion occupies the current injection region and the current non-injection/inner region. Then, in this case, OL₀<OL₂, where the optical distance from the active layer to the second surface of the second compound semiconductor layer in the current injection region is OL₂, and the optical distance from the active layer to the top surface of the mode loss acting portion in the mode loss acting region is OL₀. Furthermore, in these cases, the generated light having the higher-order mode is confined in the current injection region and the current non-injection/inner region by the mode loss acting region, and thus the oscillation mode loss can be reduced. That is, the light field intensities of the basic mode and higher-order mode generated increase in the orthogonal projection images of the current injection region and the current non-injection/inner region due to the presence of the mode loss acting region acting on an increase or decrease in oscillation mode loss. Furthermore, in these cases, the mode loss acting portion can be formed using a dielectric material, a metal material, or an alloy material. Here, examples of the dielectric material, the metal material, or the alloy material can include the above-described various materials.

Alternatively, the light emitting element of the sixth configuration having the above-described preferable configuration can have a configuration in which the convex portion is formed on the first surface side of the first compound semiconductor layer, and the mode loss acting portion is formed on a region of the first surface of the first compound semiconductor layer surrounding the convex portion, or the mode loss acting portion includes a region of the first compound semiconductor layer surrounding the convex portion. The light emitting element having such a configuration is referred to as a “light emitting element of a 6-D-th configuration” for convenience. The convex portion coincides with the orthogonal projection images of the current injection region and the current non-injection/inner region. Then, in this case, OL₀′<OL₁′, where an optical distance from the active layer to the first surface of the first compound semiconductor layer in the current injection region is OL₁′, and an optical distance from the active layer to the top surface of the mode loss acting portion in the mode loss acting region is OL₀′. Furthermore, in these cases, the generated light having the higher-order mode is confined in the current injection region and the current non-injection region by the mode loss acting region, and thus, the oscillation mode loss can be reduced. Moreover, in these cases, the mode loss acting portion can be formed using a dielectric material, a metal material, or an alloy material. Here, examples of the dielectric material, the metal material, or the alloy material can include the above-described various materials.

Furthermore, the light emitting element of the present disclosure and the like having the above-described preferable form and configuration can have a configuration in which at least two light absorbing material layers are formed in the stacked structure including the second electrode in parallel with the virtual plane (XY plane) occupied by the active layer. Here, the light emitting element having such a configuration is referred to as a “light emitting element of a seventh configuration” for convenience.

In the light emitting element of the seventh configuration, it is preferable that at least four light absorbing material layers are formed.

In the light emitting element of the seventh configuration having the above-described preferable configuration, it is preferable that 0.9×{(m·λ₀)/(2·n_{eq})}≤L_{Abs}≤1.1×{(m·λ₀)/(2·n_{eq})}, where the oscillation wavelength (which is a wavelength of light mainly emitted from the light emitting element, and is a desired oscillation wavelength) is λ₀, an equivalent refractive index of the whole of two light absorbing material layers and a portion of the stacked structure positioned between the light absorbing material layers is n_{eq}, and a distance between the light absorbing material layers is L_{Abs}. Here, m is 1 or an arbitrary integer of 2 or more including 1. The equivalent refractive index n_{eq} is represented by n_{eq}=Σ(tᵢ×nᵢ)/Σ(tᵢ), where a thickness of each of the two light absorbing material layers and each of layers constituting the portion of the stacked structure positioned between the light absorbing material layers is ti and a refractive index thereof is nᵢ. However, i=1, 2, 3, . . . , and I, and “I” is the total number of the two light absorbing material layers and the layers constituting the portion of the stacked structure positioned between the light absorbing material layers, and “Σ” means to sum up from i=1 to i=I. The equivalent refractive index n_{eq} is only required to be calculated on the basis of a known refractive index of each constituent material and a thickness obtained by observation of the constituent material by electron microscope observation or the like of a cross section of the light emitting element. In a case where m is 1, the distance between adjacent light absorbing material layers satisfies 0.9×{λ₀/(2·n_{eq})}≤L_{Abs}≤1.1×{λ₀/(2·n_{eq})} for all of a plurality of light absorbing material layers. Further, in a case where m is an arbitrary integer of 2 or more including 1, as an example, if m=1, 2, for some light absorbing material layers, the distance between adjacent light absorbing material layers satisfies 0.9×{λ₀/(2·n_{eq})}≤L_{Abs}≤1.1×{λ₀/(2·n_{eq})}, and for the remaining light absorbing material layers, the distance between adjacent light absorbing material layers satisfies 0.9×{(2·λ₀)/(2·n_{eq})}≤L_{Abs}≤1.1×{(2·λ₀)/(2·n_{eq})}. Broadly, for some light absorbing material layers, the distance between adjacent light absorbing material layers satisfies 0.9×{λ₀/(2·n_{eq})}≤L_{Abs}≤1.1×{λ₀/(2·n_{eq})}, and for the remaining various light absorbing material layers, the distance between adjacent light absorbing material layers satisfies 0.9×{(m′·λ₀)/(2·n_{eq})}≤L_{Abs}≤1.1×{(m′·λ₀)/(2·n_{eq})}. Here, m′ is an arbitrary integer of 2 or more. In addition, the distance between adjacent light absorbing material layers is a distance between the centers of gravity of the adjacent light absorbing material layers. That is, the distance between adjacent light absorbing material layers is actually a distance between the centers of the respective light absorbing material layers when cut along the virtual plane (XZ plane) in the thickness direction of the active layer.

Furthermore, in the light emitting element of the seventh configuration having the above-described various preferable configurations, a thickness of the light absorbing material layer is preferably λ₀/(4·n_{eq}) or less. A lower limit value of the thickness of the light absorbing material layer can be 1 nm, for example.

Furthermore, the light emitting element of the seventh configuration having the above-described various preferable configurations can have a configuration in which the light absorbing material layer is positioned at a minimum amplitude portion generated in a standing wave of light formed inside the stacked structure.

Furthermore, the light emitting element of the seventh configuration having the above-described various preferable configurations can have a configuration in which the active layer is positioned at a maximum amplitude portion generated in the standing wave of the light formed inside the stacked structure.

Furthermore, the light emitting element of the seventh configuration having the above-described various preferable configurations can have a configuration in which the light absorbing material layer has a light absorption coefficient that is twice or more the light absorption coefficient of the compound semiconductor constituting the stacked structure. Here, the light absorption coefficient of the light absorbing material layer and the light absorption coefficient of the compound semiconductor constituting the stacked structure can be obtained by observing the constituent material by electron microscope observation or the like of the cross section of the light emitting element, and performing analogization on the basis of a known evaluation result obtained by observation of each constituent material.

Furthermore, the light emitting element of the seventh configuration having the above-described various preferable configurations can have a configuration in which the light absorbing material layer is formed using at least one material selected from the group consisting of a compound semiconductor material having a narrower band gap than the compound semiconductor constituting the stacked structure, a compound semiconductor material doped with impurities, a transparent conductive material, and a light reflecting layer constituting material having a light absorption characteristic. Here, for example, in a case where the compound semiconductor constituting the stacked structure is GaN, examples of the compound semiconductor material having a narrower band gap than the compound semiconductor constituting the stacked structure can include InGaN, examples of the compound semiconductor material doped with impurities can include n-GaN doped with Si and n-GaN doped with B, examples of the transparent conductive material can include a transparent conductive material constituting the electrode as described later, and examples of the light reflecting layer constituting material having the light absorption characteristic can include a material constituting the light reflecting layer as described later (for example, SiO_{X}, SiN_{X}, and TaO_{X}). All of the light absorbing material layers may be formed using one of these materials. Alternatively, each of the light absorbing material layers may be formed using various materials selected from these materials, but it is preferable that one light absorbing material layer is formed using one kind of material from the viewpoint of simplification of formation of the light absorbing material layer. The light absorbing material layer may be formed in the first compound semiconductor layer, may be formed in the second compound semiconductor layer, may be formed in the first light reflecting layer, or may be formed in the second light reflecting layer, or any combination thereof is possible. Alternatively, the light absorbing material layer can also serve as the electrode formed using the transparent conductive material as described later.

### Embodiment 10

Embodiment 10 is a modification of Embodiments 1 to 9, and relates to the light emitting element of the fourth configuration. As described above, the current constriction region (the current injection region 61A and the current non-injection region 61B) is defined by the insulating layer 34 having the opening 34A. That is, the current injection region 61A is defined by the opening 34A. That is, in the light emitting element of Embodiment 10, the current injection region 61A and the current non-injection region 61B surrounding the current injection region 61A are provided in the second compound semiconductor layer 22, and the shortest distance D_{CI} from an area center point of the current injection region 61A to a boundary between the current injection region 61A and the current non-injection region 61B satisfies the above Formulas (1-1) and (1-2).

In the light emitting element of Embodiment 10, a radius r₁ of a light reflection effective region of the first light reflecting layer 41 satisfies ω₀≤r₁≤20·ω₀. In addition, D_{CI}≥ω₀. As the GaN substrate, a substrate of which the main plane is a plane obtained by inclining a c plane by about 75 degrees in an m-axis direction is used. That is, the GaN substrate has a {20-21} plane which is a semipolar plane as the main plane. Note that such a GaN substrate can also be used in other embodiments.

A deviation between a central axis (Z axis) of the protrusion 91 of the base surface 90 and the current injection region 61A in an XY plane direction causes deterioration of the characteristics of the light emitting element. Both of patterning for forming the protrusion 91 and patterning for forming the opening 34A often use a lithography technology. In this case, a positional relationship therebetween is often shifted in the XY plane according to performance of an exposure machine. In particular, the opening 34A (current injection region 61A) is positioned by performing alignment from a side of the second compound semiconductor layer 22. On the other hand, the protrusion 91 is positioned by performing alignment from a side of the compound semiconductor substrate 11. Therefore, in the light emitting element of Embodiment 10, the opening 34A (current injection region 61) is formed to be larger than a region where light is narrowed by the protrusion 91, thereby implementing a structure in which an oscillation characteristic is not affected even in a case where the deviation occurs between the central axis (Z axis) of the protrusion 91 and the current injection region 61A in the XY plane direction.

That is, in a case where a region where light reflected by the first light reflecting layer is collected is not included in the current injection region corresponding to a region where the active layer has a gain by current injection, there is a possibility that stimulated emission of light from a carrier is inhibited, and eventually laser oscillation is inhibited. However, in a case where the above Formulas (1-1) and (1-2) are satisfied, it is possible to ensure that the region where the light reflected by the first light reflecting layer is collected is included in the current injection region, and laser oscillation can be reliably achieved.

### Embodiment 11

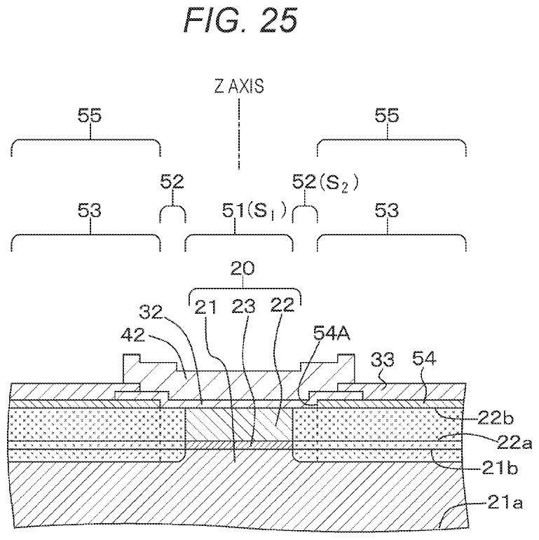

Embodiment 11 is a modification of Embodiments 1 to 10, and relates to the light emitting element of the fifth configuration, specifically, the light emitting element of the 5-A-th configuration. FIG. 25 is a schematic partial end view of the light emitting element of Embodiment 11.

Meanwhile, in order to control a flow path (current injection region) of a current flowing between the first electrode and the second electrode, the current non-injection region is formed so as to surround the current injection region. In a GaAs-based surface emitting laser element (a surface emitting laser element formed using a GaAs-based compound semiconductor), the current non-injection region surrounding the current injection region can be formed by oxidizing the active layer from the outside along the XY plane. The oxidized region of the active layer (current non-injection region) has a refractive index lower than that of the non-oxidized region (current injection region). As a result, an optical path length (represented by the product of a refractive index and a physical distance) of the resonator is smaller in the current non-injection region than in the current injection region. Then, as a result, a kind of “lens effect” is generated, which leads to an action of confining laser light in a central portion of the surface emitting laser element. In general, since light tends to spread due to a diffraction effect, laser light reciprocating in the resonator is gradually scattered toward the outside of the resonator and lost (diffraction loss), and adverse effects such as an increase in threshold current occur. However, since the lens effect compensates for this diffraction loss, an increase in threshold current and the like can be suppressed.

However, in the light emitting element formed using the GaN-based compound semiconductor, it is difficult to oxidize the active layer from the outside along the XY plane (in the lateral direction) due to the characteristics of the material. Therefore, as described in Embodiments 1 to 10, the insulating layer 34 formed using SiO₂ and having an opening is formed on the second compound semiconductor layer 22, the second electrode 32 formed using a transparent conductive material is formed on the second compound semiconductor layer 22 exposed at the bottom of the opening 34A and on the insulating layer 34, and the second light reflecting layer 42 having a stacked structure of an insulating material is formed on the second electrode 32. In this manner, as the insulating layer 34 is formed, the current non-injection region 61B is formed. Then, a portion of the second compound semiconductor layer 22 positioned in the opening 34A provided in the insulating layer 34 becomes the current injection region 61A.

In a case where the insulating layer 34 is formed on the second compound semiconductor layer 22, the resonator length in the region where the insulating layer 34 is formed (current non-injection region 61B) is longer than the resonator length in the region where the insulating layer 34 is not formed (current injection region 61A) by an optical thickness of the insulating layer 34. Therefore, laser light reciprocating in the resonator formed by two light reflecting layers 41 and 42 of the surface emitting laser element (light emitting elements) is emitted and scattered toward the outside of the resonator and lost. Such an action is referred to as a “reversed lens effect” for convenience. Then, as a result, the oscillation mode loss occurs in the laser light, and there is a possibility that the threshold current increases or slope efficiency deteriorates. Here, the “oscillation mode loss” is a physical quantity that increases or decreases the light field intensities of the basic mode and the higher-order mode for oscillating laser light, and different oscillation mode losses are defined for individual modes. Note that the “light field intensity” is a light field intensity with a distance L from the Z axis on the XY plane as a function. In general, in the basic mode, the “light field intensity” monotonously decreases as the distance L increases, but in the higher-order mode, the “light field intensity” decreases while increasing and decreasing once or multiple times as the distance L increases (see the conceptual diagram of (A) of FIG. 27). Note that, in FIG. 27, a solid line indicates light field intensity distribution of the basic mode, and a broken line indicates light field intensity distribution of the higher-order mode. In addition, in FIG. 27, the first light reflecting layer 41 is illustrated as being flat for convenience, but the first light reflecting layer 41 has a concave mirror shape in actual implementation.

The light emitting element of Embodiment 11 or the light emitting elements of Embodiments 12 to 15 as described later include:

(A) the stacked structure 20 which is formed using a GaN-based compound semiconductor and in which the first compound semiconductor layer 21 having the first surface 21a and the second surface 21b opposing the first surface 21a, the active layer (light emitting layer) 23 facing the second surface 21b of the first compound semiconductor layer 21, and the second compound semiconductor layer 22 having the first surface 22a facing the active layer 23 and the second surface 22b opposing the first surface 22a are stacked;

(B) a mode loss acting portion (mode loss acting layer) 54 provided on the second surface 22b of the second compound semiconductor layer 22 and constituting a mode loss acting region 55 acting on an increase or decrease in oscillation mode loss;

(C) the second electrode 32 formed on the second surface 22b of the second compound semiconductor layer 22 and on the mode loss acting portion 54;

(D) the second light reflecting layer 42 formed on the second electrode 32;

(E) the first light reflecting layer 41 provided on the first surface side of the first compound semiconductor layer 21; and

(F) the first electrode 31 electrically connected to the first compound semiconductor layer 21.

Then, a current non-injection region 51, a current non-injection/inner region 52 surrounding the current injection region 51, and a current non-injection/outer region 53 surrounding the current non-injection/inner region 52 are formed in the stacked structure 20, and an orthogonal projection image of the mode loss acting region 55 and an orthogonal projection image of the current non-injection/outer region 53 overlap each other. That is, the current non-injection/outer region 53 is positioned below the mode loss acting region 55. Note that, in a region sufficiently away from the current injection region 51 into which the current is injected, the orthogonal projection image of the mode loss acting region 55 and the orthogonal projection image of the current non-injection/outer region 53 do not have to overlap each other. Here, the current non-injection regions 52 and 53 into which no current is injected are formed in the stacked structure 20, but in the illustrated example, the current non-injection regions are formed in the second compound semiconductor layer 22 and in a part of the first compound semiconductor layer 21 in the thickness direction. However, the current non-injection regions 52 and 53 may be formed in a region on the side of the second compound semiconductor layer 22 where the second electrode is present in the thickness direction, may be formed in the entire second compound semiconductor layer 22, or may be formed in the second compound semiconductor layer 22 and the active layer 23.

The mode loss acting portion (mode loss acting layer) 54 is formed using a dielectric material such as SiO₂, and is formed between the second electrode 32 and the second compound semiconductor layer 22 in the light emitting element of Embodiment 11 or Embodiments 12 to 15 as described later. An optical thickness of the mode loss acting portion 54 can be a value deviating from an integral multiple of ¼ of the wavelength λ₀ of the light generated in the light emitting element. Alternatively, the optical thickness to of the mode loss acting portion 54 can be an integral multiple of ¼ of the wavelength λ₀ of the light generated in the light emitting element. That is, the optical thickness to of the mode loss acting portion 54 can be a thickness at which the standing wave is not destroyed without disturbing the phase of the light generated in the light emitting element. However, it is not necessary that the optical thickness to is strictly an integral multiple of ¼, and it is sufficient if (λ₀/4n₀)×m−(λ₀/8n₀)≤t₀≤(λ₀/4n₀)×2m+(λ₀/8n₀). Specifically, the optical thickness to of the mode loss acting portion 54 is preferably about 25 to 250 in a case where a value of ¼ of the wavelength of the light generated in the light emitting element is set to “100”. Then, by employing these configurations, a phase difference between laser light passing through the mode loss acting portion 54 and laser light passing through the current injection region 51 can be changed (controlled), such that the oscillation mode loss can be controlled with a higher degree of freedom, and the degree of freedom in designing the light emitting element can be further increased.

In Embodiment 11, a shape of a boundary between the current injection region 51 and the current non-injection/inner region 52 is a circle (diameter: 8 μm), and a shape of a boundary between the current non-injection/inner region 52 and the current non-injection/outer region 53 is a circle (diameter: 12 μm). That is, 0.01≤S₁/(S₁+S₂)≤0.7, where an area of an orthogonal projection image of the current injection region 51 is S₁ and an area of an orthogonal projection image of the current non-injection/inner region 52 is S₂. Specifically, S₁/(S₁+S₂)=8²/12²=0.44.

In the light emitting element of Embodiment 11 or Embodiments 12 to 13 and Embodiment 15 as described later, OL₀>OL₂, where an optical distance from the active layer 23 to the second surface of the second compound semiconductor layer 22 in the current injection region 51 is OL₂, and an optical distance from the active layer 23 to a top surface (a surface facing the second electrode 32) of the mode loss acting portion 54 in the mode loss acting region 55 is OL₀. Specifically, OL₀/OL₂=1.5. Then, generated laser light having the higher-order mode is scattered toward the outside of the resonator structure including the first light reflecting layer 41 and the second light reflecting layer 42 and lost by the mode loss acting region 55, such that the oscillation mode loss increases. That is, the light field intensities of the basic mode and the higher-order mode generated decrease as the distance from the Z axis increases in the orthogonal projection image of the mode loss acting region 55 due to the presence of the mode loss acting region 55 acting on an increase or decrease in oscillation mode loss (see the conceptual diagram of (B) of FIG. 27), but the decrease in light field intensity of the higher-order mode is larger than the decrease in the light field intensity of the basic mode, such that the basic mode can thus be further stabilized, the threshold current can be reduced, and a relative light field intensity of the basic mode can be increased. Moreover, since a skirt portion of the light field intensity of the higher-order mode is positioned farther from the current injection region than that of the conventional light emitting element (see (A) of FIG. 27), an influence of the reversed lens effect can be reduced. Note that a mixed oscillation mode is caused in a case where the mode loss acting portion 54 formed using SiO₂ is not provided.

The first compound semiconductor layer 21 includes an n-GaN layer, the active layer 23 has a five-layered multiple quantum well structure in which an In_{0.04}Ga_{0.96}N layer (barrier layer) and an In_{0.16}Ga_{0.84}N layer (well layer) are stacked, and the second compound semiconductor layer 22 includes a p-GaN layer. Furthermore, the first electrode 31 is formed using Ti/Pt/Au, and the second electrode 32 is formed using a transparent conductive material, specifically, ITO. A circular opening 54A is formed in the mode loss acting portion 54, and the second compound semiconductor layer 22 is exposed at a bottom of the opening 54A. The first pad electrode (not illustrated) formed using, for example, Ti/Pt/Au or V/Pt/Au for electrical connection with an external circuit or the like is formed or connected on an edge portion of the first electrode 31. The second pad electrode 33 formed using, for example, Ti/Pd/Au or Ti/Ni/Au for electrical connection with an external circuit or the like is formed or connected on an edge portion of the second electrode 32. The first light reflecting layer 41 and the second light reflecting layer 42 have a structure in which a SiN layer and a SiO₂ layer are stacked (the total number of stacked dielectric films: 20).

In the light emitting element of Embodiment 11, the current non-injection/inner region 52 and the current non-injection/outer region 53 are formed by ion implantation into the stacked structure 20. For example, boron is selected as the ion, but the ion is not limited to boron.

Hereinafter, an outline of a method for manufacturing the light emitting element of Embodiment 11 will be described.

### [Step-1100]

In manufacturing the light emitting element of Embodiment 11, first, a step similar to [Step-100] of Embodiment 1 is performed.

### [Step-1110]

Next, the current non-injection/inner region 52 and the current non-injection/outer region 53 are formed in the stacked structure 20 on the basis of an ion implantation method using a boron ion.

### [Step-1120]

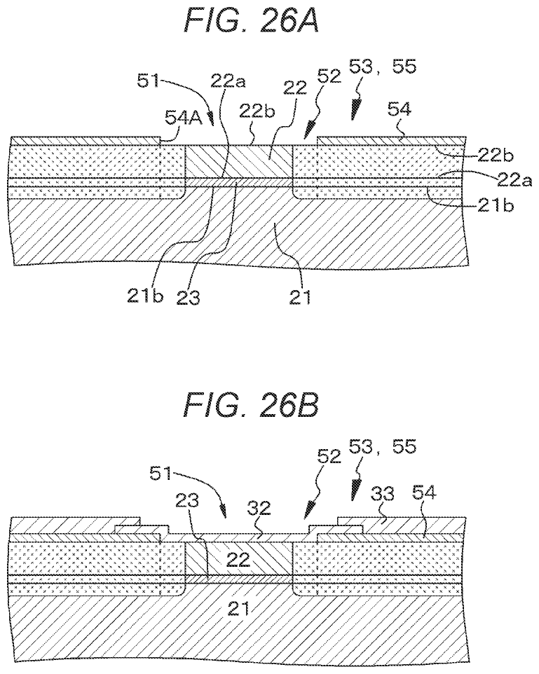

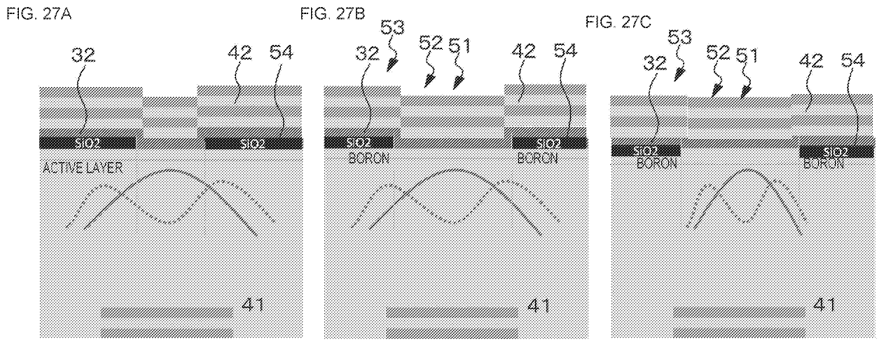

Thereafter, in a step similar to [Step-110] of Embodiment 1, the mode loss acting portion (mode loss acting layer) 54 having the opening 54A and formed using SiO₂ is formed on the second surface 22b of the second compound semiconductor layer 22 on the basis of a known method (see FIG. 26A).

### [Step-1130]

Thereafter, the light emitting element of Embodiment 11 can be obtained by performing steps similar to the steps after [Step-120] of Embodiment 1. Note that FIG. 26B illustrates a structure obtained in the middle of a step similar to [Step-120].

In the light emitting element of Embodiment 11, the current non-injection region, the current non-injection/inner region surrounding the current injection region, and the current non-injection/outer region surrounding the current non-injection/inner region are formed in the stacked structure, and the orthogonal projection image of the mode loss acting region and the orthogonal projection image of the current non-injection/outer region overlap each other. That is, the current injection region and the mode loss acting region are spaced (separated) by the current non-injection/inner region. Therefore, as illustrated in the conceptual diagram of (B) of FIG. 27, it is possible to make an increase or decrease in oscillation mode loss (specifically, an increase in Embodiment 11) be in a desired state. Alternatively, by appropriately determining a positional relationship between the current injection region and the mode loss acting region, the thickness of the mode loss acting portion constituting the mode loss acting region, and the like, it is possible to make an increase or decrease in oscillation mode loss be in a desired state. Then, as a result, it is possible to solve problems in the conventional light emitting element, such as an increase in threshold current and deterioration in slope efficiency. For example, the threshold current can be reduced by reducing the oscillation mode loss in the basic mode. Moreover, since a region to which the oscillation mode loss is given and a region to which a current is injected and which contributes to light emission can be controlled independently, that is, since the oscillation mode loss and a light emitting state of the light emitting element can be controlled independently, the degree of freedom in control and the degree of freedom in designing the light emitting element can be increased. Specifically, by setting the current injection region, the current non-injection region, and the mode loss acting region to have the above-described predetermined disposition relationship, it is possible to control a magnitude relationship of the oscillation mode loss given by the mode loss acting region to the basic mode and the higher-order mode, and it is possible to further stabilize the basic mode by making the oscillation mode loss given to the higher-order mode be relatively larger than the oscillation mode loss given to the basic mode. Moreover, since the light emitting element of Embodiment 11 has the protrusion 91, occurrence of the diffraction loss can be more reliably suppressed.

### Embodiment 12

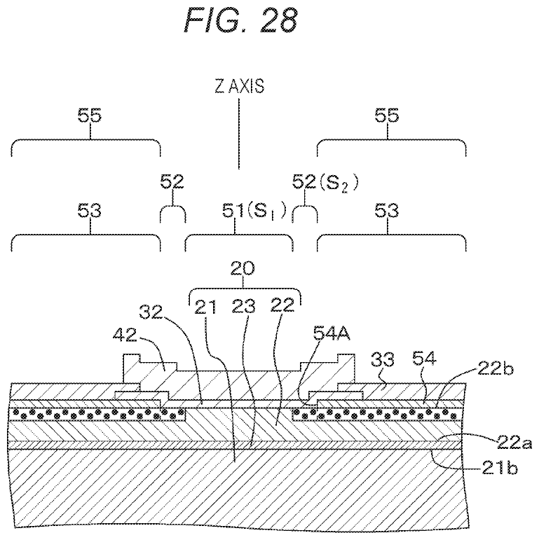

Embodiment 12 is a modification of Embodiment 11, and relates to the light emitting element of the 5-B-th configuration. As illustrated in FIG. 28 which is a schematic partial cross-sectional view, in the light emitting element of Embodiment 12, the current non-injection/inner region 52 and the current non-injection/outer region 53 are formed by plasma irradiation on the second surface of the second compound semiconductor layer 22, asking treatment on the second surface of the second compound semiconductor layer 22, or reactive ion etching (RIE) treatment on the second surface of the second compound semiconductor layer 22. Then, since the current non-injection/inner region 52 and the current non-injection/outer region 53 are exposed to plasma particles (specifically, argon, oxygen, nitrogen, and the like) as described above, conductivity of the second compound semiconductor layer 22 is deteriorated, and the current non-injection/inner region 52 and the current non-injection/outer region 53 are in a high resistance state. That is, the current non-injection/inner region 52 and the current non-injection/outer region 53 are formed by exposure of the second surface 22b of the second compound semiconductor layer 22 to the plasma particles.

Also in Embodiment 12, the shape of the boundary between the current injection region 51 and the current non-injection/inner region 52 is a circle (diameter: 10 μm), and the shape of the boundary between the current non-injection/inner region 52 and the current non-injection/outer region 53 is a circle (diameter: 15 μm). That is, 0.01≤S₁/(S₁+S₂)≤0.7, where an area of an orthogonal projection image of the current injection region 51 is S₁ and an area of an orthogonal projection image of the current non-injection/inner region 52 is S₂. Specifically, S₁/(S₁+S₂)=10²/15²=0.44.

In Embodiment 12, instead of [Step-1110] of Embodiment 11, it is sufficient if the current non-injection/inner region 52 and the current non-injection/outer region 53 are formed in the stacked structure 20 on the basis of plasma irradiation on the second surface of the second compound semiconductor layer 22, asking treatment on the second surface of the second compound semiconductor layer 22, or reactive ion etching treatment on the second surface of the second compound semiconductor layer 22.

Except for the above point, the light emitting element of Embodiment 12 can have a similar configuration and structure to those of the light emitting element of Embodiment 11, and thus a detailed description thereof will be omitted.

Even in the light emitting element of Embodiment 12 or Embodiment 13 as described later, by setting the current injection region, the current non-injection region, and the mode loss acting region to have the above-described predetermined disposition relationship, it is possible to control the magnitude relationship of the oscillation mode loss given by the mode loss acting region to the basic mode and the higher-order mode, and it is possible to further stabilize the basic mode by making the oscillation mode loss given to the higher-order mode be relatively larger than the oscillation mode loss given to the basic mode.

### Embodiment 13

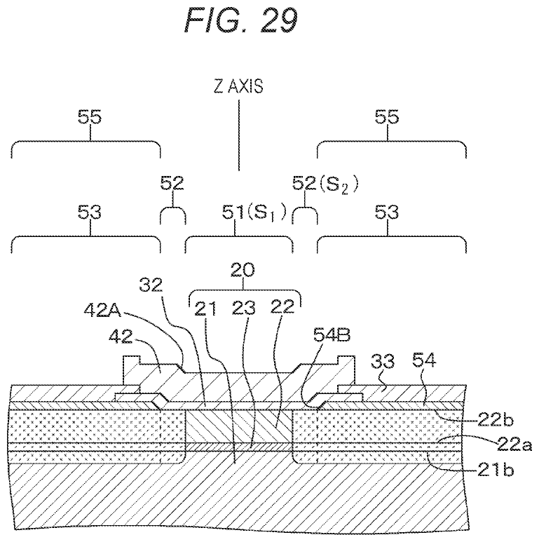

Embodiment 13 is a modification of Embodiments 11 and 12, and relates to the light emitting element of the 5-C-th configuration. As illustrated in FIG. 29 which is a schematic partial cross-sectional view, in the light emitting element of Embodiment 13, the second light reflecting layer 42 has a region that reflects or scatters light from the first light reflecting layer 41 toward the outside of the resonator structure including the first light reflecting layer 41 and the second light reflecting layer 42 (that is, toward the mode loss acting region 55). Specifically, a portion of the second light reflecting layer 42 positioned above the side wall (the side wall of the opening 54B) of the mode loss acting portion (mode loss acting layer) 54 has a forward tapered inclined portion 42A or has a region curved convexly toward the first light reflecting layer 41.

In Embodiment 13, the shape of the boundary between the current injection region 51 and the current non-injection/inner region 52 is a circle (diameter: 8 μm), and the shape of the boundary between the current non-injection/inner region 52 and the current non-injection/outer region 53 is a circle (diameter: 10 to 20 μm).

In Embodiment 13, in a step similar to [Step-1120] of Embodiment 11, in a case where the mode loss acting portion (mode loss acting layer) 54 having the opening 54B and formed using SiO₂ is formed, it is sufficient if the opening 54B having the forward tapered side wall is formed. Specifically, a resist layer is formed on the mode loss acting layer formed on the second surface 22b of the second compound semiconductor layer 22, and an opening is provided in a portion of the resist layer where the opening 54B is to be formed on the basis of a photolithography technology. The side wall of the opening is formed in a forward tapered shape on the basis of a known method. Then, by performing etching back, the opening 54B having the forward tapered side wall can be formed in the mode loss acting portion (mode loss acting layer) 54. Furthermore, by forming the second electrode 32 and the second light reflecting layer 42 on such a mode loss acting portion (mode loss acting layer) 54, the forward tapered inclined portion 42A can be provided in the second light reflecting layer 42.

Except for the above point, the light emitting element of Embodiment 13 can have a similar configuration and structure to those of the light emitting elements of Embodiments 11 and 12, and thus a detailed description thereof will be omitted.

### Embodiment 14

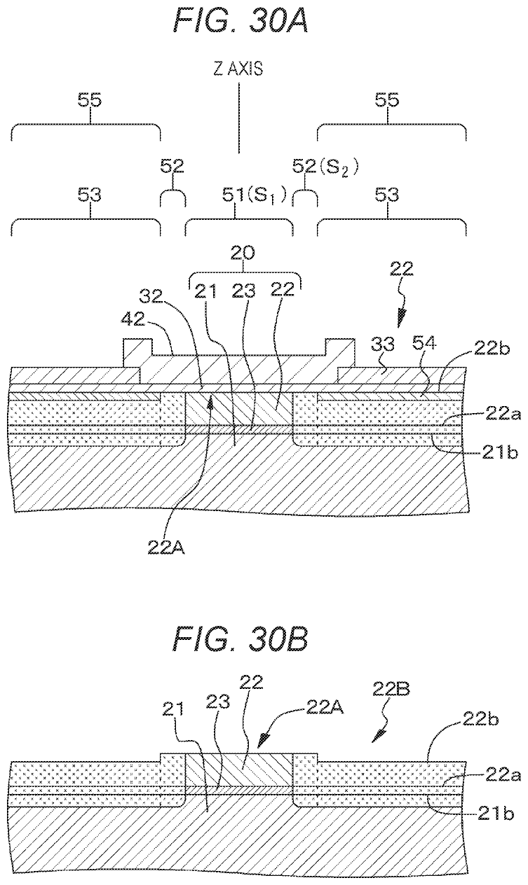

Embodiment 14 is a modification of Embodiments 11 to 13, and relates to the light emitting element of the 5-D-th configuration. As illustrated in FIG. 30A which is a schematic partial cross-sectional view of the light emitting element of Embodiment 14, and in FIG. 30B which is a schematic partial cross-sectional view obtained by cutting out a main part, a convex portion 22A is formed on the second surface side of the second compound semiconductor layer 22. Then, as illustrated in FIGS. 30A and 30B, the mode loss acting portion (mode loss acting layer) 54 is formed on a region 22B of the second surface 22b of the second compound semiconductor layer 22 surrounding the convex portion 22A. The convex portion 22A occupies the current injection region 51, the current injection region 51, and the current non-injection/inner region 52. The mode loss acting portion (mode loss acting layer) 54 is formed using a dielectric material such as SiO₂, for example, similarly to Embodiment 11. In the region 22B, the current non-injection/outer region 53 is provided. OL₀<OL₂, where the optical distance from the active layer 23 to the second surface of the second compound semiconductor layer 22 in the current injection region 51 is OL₂, and the optical distance from the active layer 23 to the top surface (the surface facing the second electrode 32) of the mode loss acting portion 54 in the mode loss acting region 55 is OL₀. Specifically, OL₂/OL₀=1.5. As a result, the lens effect is generated in the light emitting element.

In the light emitting element of Embodiment 14, the generated laser light having the higher-order mode is confined in the current injection region 51 and the current non-injection/inner region 52 by the mode loss acting region 55, such that the oscillation mode loss decreases. That is, the light field intensities of the basic mode and higher-order mode generated increase in the orthogonal projection images of the current injection region 51 and the current non-injection/inner region 52 due to the presence of the mode loss acting region 55 acting on an increase or decrease in oscillation mode loss.

In Embodiment 14, a shape of a boundary between the current injection region 51 and the current non-injection/inner region 52 is a circle (diameter: 8 μm), and a shape of a boundary between the current non-injection/inner region 52 and the current non-injection/outer region 53 is a circle (diameter: 30 μm).

In Embodiment 14, it is sufficient if the convex portion 22A is formed by removing a portion of the second compound semiconductor layer 22 from the second surface side between [Step-1110] and [Step-1120] of Embodiment 11.

Except for the above point, the light emitting element of Embodiment 14 can have a similar configuration and structure to those of the light emitting element of Embodiment 11, and thus a detailed description thereof will be omitted. In the light emitting element of Embodiment 14, it is possible to suppress the oscillation mode loss given by the mode loss acting region to various modes to not only perform multi-transverse-mode oscillation, but also reduce the threshold of laser oscillation. In addition, as illustrated in the conceptual diagram of (C) of FIG. 27, the light field intensities of the basic mode and higher-order mode generated can increase in the orthogonal projection images of the current injection region and the current non-injection/inner region due to the presence of the mode loss acting region acting on an increase/decrease (specifically, a decrease in Embodiment 14) in oscillation mode loss.

### Embodiment 15

Embodiment 15 is a modification of Embodiments 11 to 14. More specifically, the light emitting element of Embodiment 15 or Embodiment 16 as described later includes a surface emitting laser element (light emitting element) (VCSEL) that emits laser light from the first surface 21a of the first compound semiconductor layer 21 via the first light reflecting layer 41.

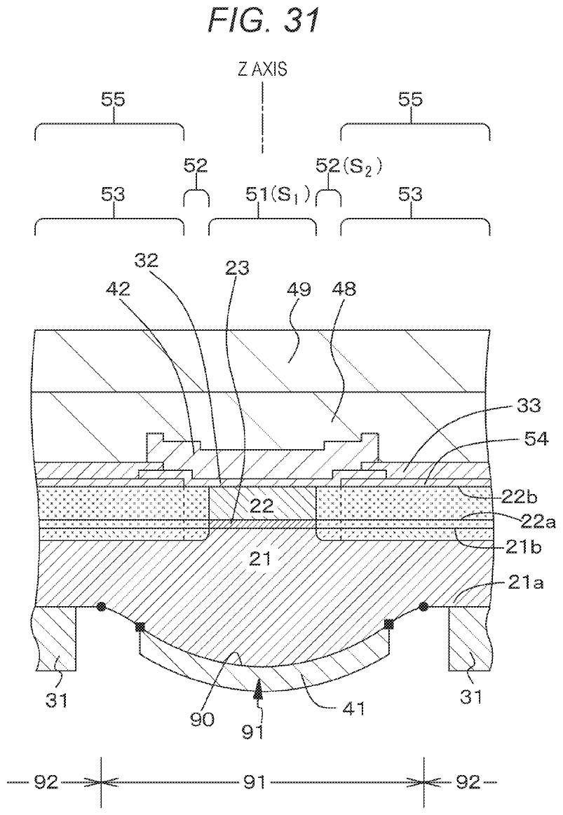

In the light emitting element of Embodiment 15, as illustrated in FIG. 31 which is a schematic partial cross-sectional view, the second light reflecting layer 42 is fixed to the support substrate 49 formed using a silicon semiconductor substrate via the bonding layer 48 formed using a gold (Au) layer or a solder layer containing tin (Sn) on the basis of a solder bonding method. In manufacturing the light emitting element of Embodiment 15, for example, it is sufficient if steps similar to [Step-1100] to [Step-1130] of Embodiment 11 are performed except for the removal of the support substrate 49, that is, without removing the support substrate 49.

Even in the light emitting element of Embodiment 15, by setting the current injection region, the current non-injection region, and the mode loss acting region to have the above-described predetermined disposition relationship, it is possible to control the magnitude relationship of the oscillation mode loss given by the mode loss acting region to the basic mode and the higher-order mode, and it is possible to further stabilize the basic mode by making the oscillation mode loss given to the higher-order mode be relatively larger than the oscillation mode loss given to the basic mode.

In the example of the light emitting element described above and illustrated in FIG. 31, an end portion of the first electrode 31 is separated from the first light reflecting layer 41. However, the present disclosure is not limited to such a structure, and the end portion of the first electrode 31 may be in contact with the first light reflecting layer 41, or the end portion of the first electrode 31 may be formed on an edge portion of the first light reflecting layer 41.

In addition, for example, after the steps similar to [Step-1100] to [Step-1130] of Embodiment 11 are performed, the light emitting element manufacturing substrate 11 may be removed to expose the first surface 21a of the first compound semiconductor layer 21, and then the first light reflecting layer 41 and the first electrode 31 may be formed on the first surface 21a of the first compound semiconductor layer 21.

### Embodiment 16

Embodiment 16 is a modification of Embodiments 1 to 15, but relates to the light emitting element of the sixth configuration, specifically, the light emitting element of the 6-A-th configuration. More specifically, the light emitting element of Embodiment 16 includes a surface emitting laser element (light emitting element) (VCSEL) that emits laser light from the first surface 21a of the first compound semiconductor layer 21 via the first light reflecting layer 41.

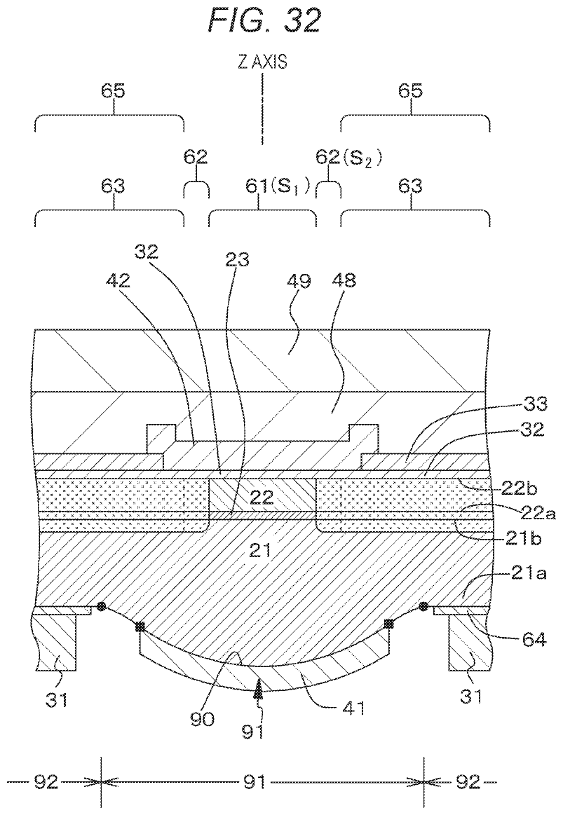

The light emitting element of Embodiment 16 illustrated in FIG. 32 which is a schematic partial end view includes:

(a) the stacked structure 20 in which the first compound semiconductor layer 21 formed using a GaN-based compound semiconductor and having the first surface 21a and the second surface 21b opposing the first surface 21a, the active layer (light emitting layer) 23 that is formed using a GaN-based compound semiconductor and is in contact with the second surface 21b of the first compound semiconductor layer 21, and the second compound semiconductor layer 22 formed using a GaN-based compound semiconductor and having the first surface 22a and the second surface 22b opposing the first surface 22a are stacked, the first surface 22a being in contact with the active layer 23;

(b) the second electrode 32 formed on the second surface 22b of the second compound semiconductor layer 22;

(c) the second light reflecting layer 42 formed on the second electrode 32;

(d) a mode loss acting portion 64 provided on the first surface 21a of the first compound semiconductor layer 21 and constituting a mode loss acting region 65 acting on an increase or decrease in oscillation mode loss;

(e) the first light reflecting layer 41 formed on the first surface 21a of the first compound semiconductor layer 21 and on the mode loss acting portion 64; and

(f) the first electrode 31 electrically connected to the first compound semiconductor layer 21. Note that, in the light emitting element of Embodiment 16, the first electrode 31 is formed on the first surface 21a of the first compound semiconductor layer 21.

Then, a current non-injection region 61, a current non-injection/inner region 62 surrounding the current injection region 61, and a current non-injection/outer region 63 surrounding the current non-injection/inner region 62 are formed in the stacked structure 20, and an orthogonal projection image of the mode loss acting region 65 and an orthogonal projection image of the current non-injection/outer region 63 overlap each other. Here, the current non-injection regions 62 and 63 are formed in the stacked structure 20, but in the illustrated example, the current non-injection regions are formed in the second compound semiconductor layer 22 and in a part of the first compound semiconductor layer 21 in the thickness direction. However, the current non-injection regions 62 and 63 may be formed in a region on the side of the second compound semiconductor layer 22 where the second electrode is present in the thickness direction, may be formed in the entire second compound semiconductor layer 22, or may be formed in the second compound semiconductor layer 22 and the active layer 23.

The configurations of the stacked structure 20, the second pad electrode 33, the first light reflecting layer 41, and the second light reflecting layer 42 can be similar to those in Embodiment 11, and the configurations of the bonding layer 48 and the support substrate 49 can be similar to those in Embodiment 15. A circular opening 64A is formed in the mode loss acting portion 64, and the first surface 21a of the first compound semiconductor layer 21 is exposed at a bottom of the opening 64A.

The mode loss acting portion (mode loss acting layer) 64 is formed using a dielectric material such as SiO₂, and is formed on the first surface 21a of the first compound semiconductor layer 21. An optical thickness to of the mode loss acting portion 64 can be a value deviating from an integral multiple of ¼ of the wavelength λ₀ of the light generated in the light emitting element. Alternatively, the optical thickness to of the mode loss acting portion 64 can be an integral multiple of ¼ of the wavelength λ₀ of the light generated in the light emitting element. That is, the optical thickness to of the mode loss acting portion 64 can be a thickness at which the standing wave is not destroyed without disturbing the phase of the light generated in the light emitting element. However, it is not necessary that the optical thickness to is strictly an integral multiple of ¼, and it is sufficient if (λ₀/4n₀)×m−(λ₀/8n₀)≤t₀≤(λ₀/4n₀)×2m+(λ₀/8n₀). Specifically, the optical thickness to of the mode loss acting portion 64 is preferably about 25 to 250 in a case where a value of ¼ of the wavelength λ₀ of the light generated in the light emitting element is set to “100”. Then, by employing these configurations, a phase difference between laser light passing through the mode loss acting portion 64 and laser light passing through the current injection region 61 can be changed (controlled), such that the oscillation mode loss can be controlled with a higher degree of freedom, and the degree of freedom in designing the light emitting element can be further increased.

In Embodiment 16, a shape of a boundary between the current injection region 61 and the current non-injection/inner region 62 is a circle (diameter: 8 μm), and a shape of a boundary between the current non-injection/inner region 62 and the current non-injection/outer region 63 is a circle (diameter: 15 μm). That is, 0.01≤S₁′/(S₁′+S₂′)≤0.7, where an area of an orthogonal projection image of the current injection region 61 is S₁′ and an area of an orthogonal projection image of the current non-injection/inner region 62 is S₂′. Specifically, S₁′/(S₁′+S₂′)=8²/15²=0.28.

In the light emitting element of Embodiment 16, OL₀′>OL₁′, where an optical distance from the active layer 23 to the first surface of the first compound semiconductor layer 21 in the current injection region 61 is OL₁′, and an optical distance from the active layer 23 to the top surface (the surface facing the first electrode 31) of the mode loss acting portion 64 in the mode loss acting region 65 is OL₀′. Specifically, OL₀′/OL₁′=1.01. Then, generated laser light having the higher-order mode is scattered toward the outside of the resonator structure including the first light reflecting layer 41 and the second light reflecting layer 42 and lost by the mode loss acting region 65, such that the oscillation mode loss increases. That is, the light field intensities of the basic mode and the higher-order mode generated decrease as the distance from the Z axis increases in the orthogonal projection image of the mode loss acting region 65 due to the presence of the mode loss acting region 65 acting on an increase or decrease in oscillation mode loss (see the conceptual diagram of (B) of FIG. 27), but the decrease in light field intensity of the higher-order mode is larger than the decrease in the light field intensity of the basic mode, such that the basic mode can thus be further stabilized, the threshold current can be reduced, and a relative light field intensity of the basic mode can be increased.

In the light emitting element of Embodiment 16, the current non-injection/inner region 62 and the current non-injection/outer region 63 are formed by ion implantation into the stacked structure 20, similarly to Embodiment 11. For example, boron is selected as the ion, but the ion is not limited to boron.

Hereinafter, a method for manufacturing the light emitting element of Embodiment 16 will be described.

### [Step-1600]

First, the stacked structure 20 can be obtained by performing a step similar to [Step-1100] of Embodiment 11. Next, by performing a step similar to [Step-1110] of Embodiment 11, the current non-injection/inner region 62 and the current non-injection/outer region 63 can be formed in the stacked structure 20.

### [Step-1610]

Next, the second electrode 32 is formed on the second surface 22b of the second compound semiconductor layer 22 on the basis of, for example, a lift-off method, and in addition, the second pad electrode 33 is formed on the basis of a known method. Thereafter, the second light reflecting layer 42 is formed on the second electrode 32 and on the second pad electrode 33 on the basis of a known method.

### [Step-1620]

Thereafter, the second light reflecting layer 42 is fixed to the support substrate 49 via the bonding layer 48.

### [Step-1630]

Next, the light emitting element manufacturing substrate 11 is removed to expose the first surface 21a of the first compound semiconductor layer 21. Specifically, first, the light emitting element manufacturing substrate 11 is thinned on the basis of a mechanical polishing method, and then the remaining portion of the light emitting element manufacturing substrate 11 is removed on the basis of a CMP method. In this way, the first surface 21a of the first compound semiconductor layer 21 is exposed, and then the base surface 90 having the protrusion 91 and the second region 92 is formed in the first surface 21a of the first compound semiconductor layer 21.

### [Step-1640]

Thereafter, the mode loss acting portion (mode loss acting layer) 64 having the opening 64A and formed using SiO₂ is formed on the first surface 21a of the first compound semiconductor layer 21 (specifically, on the second region 92 of the base surface 90) on the basis of a known method.

### [Step-1650]

Next, the first light reflecting layer 41 is formed on the protrusion 91 of the first surface 21a of the first compound semiconductor layer 21 exposed at the bottom of the opening 64A of the mode loss acting portion 64, and in addition, the first electrode 31 is formed. Note that a portion of the first electrode 31 penetrates through the mode loss acting portion (mode loss acting layer) 64 and reaches the first compound semiconductor layer 21 in a region (not illustrated). In this way, the light emitting element of Embodiment 16 having the structure illustrated in FIG. 32 can be obtained.

Also in the light emitting element of Embodiment 16, the current non-injection region, the current non-injection/inner region surrounding the current injection region, and the current non-injection/outer region surrounding the current non-injection/inner region are formed in the stacked structure, and the orthogonal projection image of the mode loss acting region and the orthogonal projection image of the current non-injection/outer region overlap each other. Therefore, as illustrated in the conceptual diagram of (B) of FIG. 27, it is possible to make an increase or decrease in oscillation mode loss (specifically, an increase in Embodiment 16) be in a desired state. Moreover, since the oscillation mode loss and the light emitting state of the light emitting element can be controlled independently, the degree of freedom in control and the degree of freedom in designing the light emitting element can be increased. Specifically, by setting the current injection region, the current non-injection region, and the mode loss acting region to have the above-described predetermined disposition relationship, it is possible to control the magnitude relationship of the oscillation mode loss given by the mode loss acting region to the basic mode and the higher-order mode, and it is possible to further stabilize the basic mode by making the oscillation mode loss given to the higher-order mode be relatively larger than the oscillation mode loss given to the basic mode. Furthermore, an influence of the reversed lens effect can be reduced. Moreover, since the light emitting element of Embodiment 16 has the protrusion 91, occurrence of the diffraction loss can be more reliably suppressed.

Also in Embodiment 16, similarly to Embodiment 12, the current non-injection/inner region 62 and the current non-injection/outer region 63 can be formed by plasma irradiation on the second surface of the second compound semiconductor layer 22, asking treatment on the second surface of the second compound semiconductor layer 22, or reactive ion etching (RIE) treatment on the second surface of the second compound semiconductor layer 22 (the light emitting element of the 6-B-th configuration). As the current non-injection/inner region 62 and the current non-injection/outer region 63 are exposed to plasma particles as described above, conductivity of the second compound semiconductor layer 22 is deteriorated, and the current non-injection/inner region 62 and the current non-injection/outer region 63 are in a high resistance state. That is, the current non-injection/inner region 62 and the current non-injection/outer region 63 are formed by exposure of the second surface 22b of the second compound semiconductor layer 22 to the plasma particles.

Furthermore, similarly to Embodiment 13, the second light reflecting layer 42 can have a region that reflects or scatters light from the first light reflecting layer 41 toward the outside of the resonator structure including the first light reflecting layer 41 and the second light reflecting layer 42 (that is, toward the mode loss acting region 65) (the light emitting element of the 6-C-th configuration).

In addition, similarly to Embodiment 14, the mode loss acting portion (mode loss acting layer) 64 may be formed (the light emitting element of the 6-D-th configuration). It is sufficient if the mode loss acting portion (mode loss acting layer) 64 is formed on a region of the first surface 21a of the first compound semiconductor layer 21 surrounding a convex portion. The convex portion occupies the current injection region 61, the current injection region 61, and the current non-injection/inner region 62. Then, as a result, the generated laser light having the higher-order mode is confined in the current injection region 61 and the current non-injection/inner region 62 by the mode loss acting region 65, such that the oscillation mode loss decreases. That is, the light field intensities of the basic mode and higher-order mode generated increase in the orthogonal projection images of the current injection region 61 and the current non-injection/inner region 62 due to the presence of the mode loss acting region 65 acting on an increase or decrease in oscillation mode loss. Also in a modified example of the light emitting element of Embodiment 16 having such a configuration, it is possible to suppress the oscillation mode loss given by the mode loss acting region 65 to various modes to not only perform multi-transverse-mode oscillation, but also reduce the threshold current of laser oscillation. In addition, as illustrated in the conceptual diagram of (C) of FIG. 27, the light field intensities of the basic mode and higher-order mode generated can increase in the orthogonal projection images of the current injection region and the current non-injection/inner region due to the presence of the mode loss acting region 65 acting on an increase/decrease (specifically, a decrease in the modified example of the light emitting element of Embodiment 16) in oscillation mode loss.

### Embodiment 17

Embodiment 17 is a modification of Embodiments 1 to 16, and relates to the light emitting element of the seventh configuration.

Meanwhile, the resonator length L_{OR} in the stacked structure including two DBR layers and a stacked structure formed therebetween is represented by L=(m·λ₀)/(2·n_{eq}), where an equivalent refractive index of the entire stacked structure is n_{eq}, and a wavelength of laser light to be emitted from a surface emitting laser element (light emitting element) is λ₀. Here, m is a positive integer. Then, in the surface emitting laser element (light emitting element), a wavelength at which oscillation is possible is determined by the resonator length L_{OR}. Each oscillatable oscillation mode is called a longitudinal mode. Then, among the longitudinal modes, a longitudinal mode that matches a gain spectrum determined by the active layer can be laser-oscillated. An interval Δλ between the longitudinal modes is represented by λ₀²/(2n_{eff}·L), where an effective refractive index is n_{eff}. That is, the larger the resonator length L_{OR}, the smaller the interval Δλ between the longitudinal modes. Therefore, in a case where the resonator length L_{OR} is large, a plurality of longitudinal modes can exist in the gain spectrum, and thus the plurality of longitudinal modes can oscillate. Note that the equivalent refractive index n_{eq} and the effective refractive index n_{eff} have the following relationship in which the oscillation wavelength is λ₀.

n_{eff}=n_{eq}−λ₀·(dn_{eq}/dλ₀)

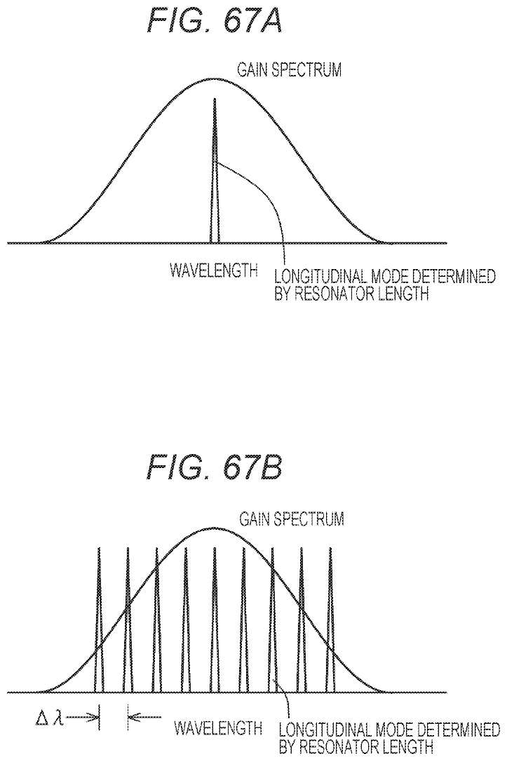

Here, in a case where the stacked structure includes a GaAs-based compound semiconductor layer, the resonator length L_{OR} is usually 1 μm or less, which is small, and one type (one wavelength) of laser light in the longitudinal mode is emitted from the surface emitting laser element (see the conceptual diagram of FIG. 67A). Therefore, it is possible to accurately control the oscillation wavelength of the laser light in the longitudinal mode emitted from the surface emitting laser element. On the other hand, in a case where the stacked structure includes a GaN-based compound semiconductor layer, the resonator length L_{OR} is usually several times the wavelength of the laser light emitted from the surface emitting laser element, which is large. Therefore, a plurality of types of laser light in the longitudinal mode is emitted from the surface emitting laser element (see the conceptual diagram of FIG. 67B), and it thus becomes difficult to accurately control the oscillation wavelength of the laser light that can be emitted from the surface emitting laser element.

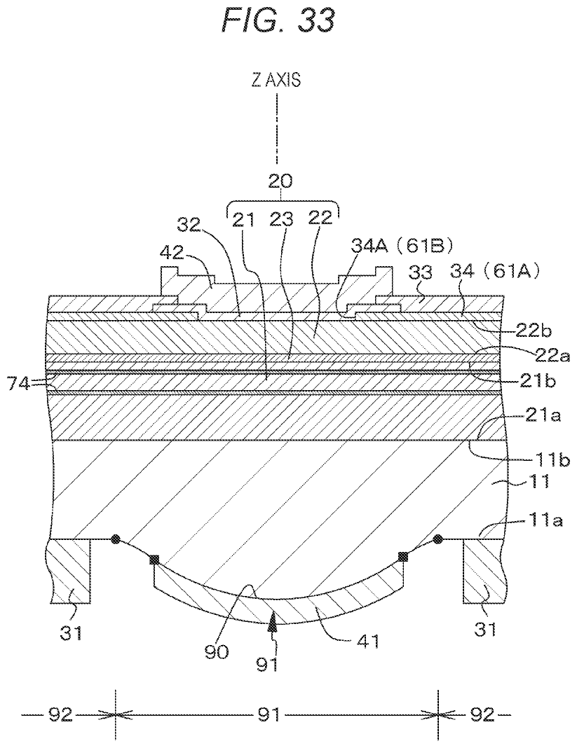

As illustrated in FIG. 33 which is a schematic partial cross-sectional view, in the light emitting element of Embodiment 17 or the light emitting elements of Embodiments 18 to 20 as described later, at least two light absorbing material layers 74, preferably, at least four light absorbing material layers 74, and specifically, 20 light absorbing material layers 74 in Embodiment 17 are formed in the stacked structure 20 including the second electrode 32 in parallel with the virtual plane (XY plane) occupied by the active layer 23. Note that, in order to simplify the drawing, only two light absorbing material layers 74 are illustrated in the drawing.

In Embodiment 17, the oscillation wavelength (a desired oscillation wavelength emitted from the light emitting element) λ₀ is 450 nm. The 20 light absorbing material layers 74 are formed using a compound semiconductor material having a band gap narrower than that of the compound semiconductor constituting the stacked structure 20, specifically, n-In_{0.2}Ga_{0.8}N, and are formed inside the first compound semiconductor layer 21. A thickness of the light absorbing material layer 74 is λ₀/(4·n_{eq}) or less, specifically, 3 nm. Furthermore, a light absorption coefficient of the light absorbing material layer 74 is two times or more, specifically, 1×10³ times the light absorption coefficient of the first compound semiconductor layer 21 including an n-GaN layer.

In addition, the light absorbing material layer 74 is positioned at a minimum amplitude portion generated in a standing wave of light formed inside the stacked structure, and the active layer 23 is positioned at a maximum amplitude portion generated in a standing wave of light formed inside the stacked structure. A distance between a center of the active layer 23 in the thickness direction and a center of the light absorbing material layer 74 adjacent to the active layer 23 in the thickness direction is 46.5 nm. Furthermore, 0.9×{(m·λ₀)/(2·n_{eq})}≤L_{Abs}≤1.1×{(m·λ₀)/(2·n_{eq})}, where an equivalent refractive index of the whole of two light absorbing material layers 74 and a portion (specifically, the first compound semiconductor layer 21 in Embodiment 17) of the stacked structure positioned between the light absorbing material layers 74 is n_{eq}, and a distance between the light absorbing material layers 74 is L_{Abs}. Here, m is 1 or an arbitrary integer of 2 or more including 1. However, in Embodiment 17, m is 1. Therefore, the distance between adjacent light absorbing material layers 74 satisfies 0.9×{λ₀/(2·n_{eq})}≤L_{Abs}≤1.1×{λ₀/(2·n_{eq})} for all of the plurality of light absorbing material layers 74 (20 light absorbing material layers 74). A value of the equivalent refractive index n_{eq} is specifically 2.42, and in a case where m=1, specifically, L_{Abs}=1×450/(2×2.42)=93.0 nm. Note that, in some of the 20 light absorbing material layers 74, m may be an arbitrary integer of 2 or more.

In manufacturing the light emitting element of Embodiment 17, the stacked structure 20 is formed in a step similar to [Step-100] of Embodiment 1, and at this time, the 20 light absorbing material layers 74 are also formed inside the first compound semiconductor layer 21. Except for this point, the light emitting element of Embodiment 17 can be manufactured on the basis of a method similar to that for the light emitting element of Embodiment 1.

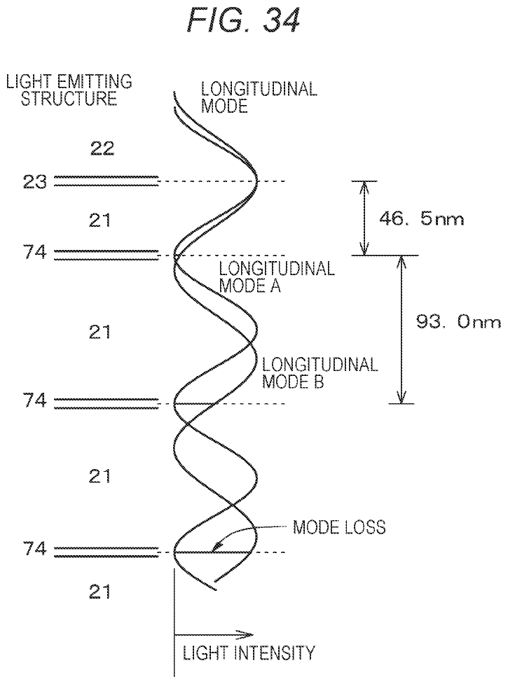

FIG. 34 schematically illustrates a case where a plurality of longitudinal modes is generated in the gain spectrum determined by the active layer 23. Note that FIG. 34 illustrates two longitudinal modes, a longitudinal mode A and a longitudinal mode B. Then, in this case, it is assumed that the light absorbing material layer 74 is positioned at a minimum amplitude portion of the longitudinal mode A and is not positioned at a minimum amplitude portion of the longitudinal mode B. Then, a mode loss of the longitudinal mode A is minimized, but a mode loss of the longitudinal mode B is large. In FIG. 34, the mode loss of the longitudinal mode B is schematically indicated by a solid line. Therefore, the longitudinal mode A oscillates more easily than the longitudinal mode B. Therefore, by using such a structure, that is, by controlling the position and period of the light absorbing material layer 74, a specific longitudinal mode can be stabilized and oscillation can be facilitated. Meanwhile, since it is possible to increase mode losses of other undesirable longitudinal modes, it is possible to suppress oscillation of other undesirable longitudinal modes.

As described above, in the light emitting element of Embodiment 17, since at least two light absorbing material layers are formed inside the stacked structure, it is possible to suppress oscillation of laser light of an undesired longitudinal mode among laser light of a plurality of longitudinal modes that can be emitted from the surface emitting laser element. As a result, the oscillation wavelength of the emitted laser light can be accurately controlled. Moreover, since the light emitting element of Embodiment 17 has the protrusion 91, occurrence of the diffraction loss can be reliably suppressed.

### Embodiment 18

Embodiment 18 is a modification of Embodiment 17. In Embodiment 17, the light absorbing material layer 74 is formed using a compound semiconductor material having a band gap narrower than that of the compound semiconductor constituting the stacked structure 20. On the other hand, in Embodiment 18, 10 light absorbing material layers 74 are formed using a compound semiconductor material doped with impurities, specifically, a compound semiconductor material having an impurity concentration (impurity: Si) of 1×10¹⁹/cm³ (specifically, n-GaN:Si). Furthermore, in Embodiment 18, the oscillation wavelength λ₀ is 515 nm. Note that a composition of the active layer 23 is In_{0.3}Ga_{0.7}N. In Embodiment 18, m=1, a value of L_{Abs} is 107 nm, the distance between the center of the active layer 23 in the thickness direction and the center of the light absorbing material layer 74 adjacent to the active layer 23 in the thickness direction is 53.5 nm, and the thickness of the light absorbing material layer 74 is 3 nm. Except for the above point, the light emitting element of Embodiment 18 can have a similar configuration and structure to those of the light emitting element of Embodiment 17, and thus a detailed description thereof will be omitted. Note that, in some of the 10 light absorbing material layers 74, m may be an arbitrary integer of 2 or more.

### Embodiment 19

Embodiment 19 is also a modification of Embodiment 17. In Embodiment 19, five light absorbing material layers (referred to as “first light absorbing material layers” for convenience) have a configuration similar to that of the light absorbing material layer 74 of Embodiment 17, that is, the first light absorbing material layer is formed using n-In_{0.3}Ga_{0.7}N. Furthermore, in Embodiment 19, one light absorbing material layer (referred to as a “second light absorbing material layer” for convenience) is formed using a transparent conductive material. Specifically, the second light absorbing material layer also serves as the second electrode 32 formed using ITO. In Embodiment 19, the oscillation wavelength λ₀ is 450 nm. In addition, m=1 and 2. In a case where m=1, a value of L_{Abs} is 93.0 nm, a distance between the center of the active layer 23 in the thickness direction and the center of the first light absorbing material layer adjacent to the active layer 23 in the thickness direction is 46.5 nm, and a thickness of the five first light absorbing material layers is 3 nm. That is, for the five first light absorbing material layers, 0.9×{λ₀/(2·n_{eq})}≤L_{Abs}≤1.1×{λ₀/(2·n_{eq})}. In addition, m=2 for the first light absorbing material layer adjacent to the active layer 23 and the second light absorbing material layer. That is, 0.9×{(2·λ₀)/(2·n_{eq})}≤L_{Abs}≤1.1×{(2·λ₀)/(2·n_{eq})}. One second light absorbing material layer also serving as the second electrode 32 has a light absorption coefficient of 2000 cm⁻¹ and a thickness of 30 nm, and a distance from the active layer 23 to the second light absorbing material layer is 139.5 nm. Except for the above point, the light emitting element of Embodiment 19 can have a similar configuration and structure to those of the light emitting element of Embodiment 17, and thus a detailed description thereof will be omitted. Note that, in some of the five first light absorbing material layers, m may be an arbitrary integer of 2 or more. Note that, unlike Embodiment 17, the number of light absorbing material layers 74 can also be one. Also in this case, a positional relationship between the second light absorbing material layer also serving as the second electrode 32 and the light absorbing material layer 74 needs to satisfy the following formula.

0.9×{(m·λ₀)/(2·n_{eq})}≤L_{Abs}≤1.1×{(m·λ₀)/(2·n_{eq})}

### Embodiment 20

Embodiment 20 is a modification of Embodiments 17 to 19. More specifically, the light emitting element of Embodiment 20 includes a surface emitting laser element (VCSEL) that emits laser light from the first surface 21a of the first compound semiconductor layer 21 via the first light reflecting layer 41.

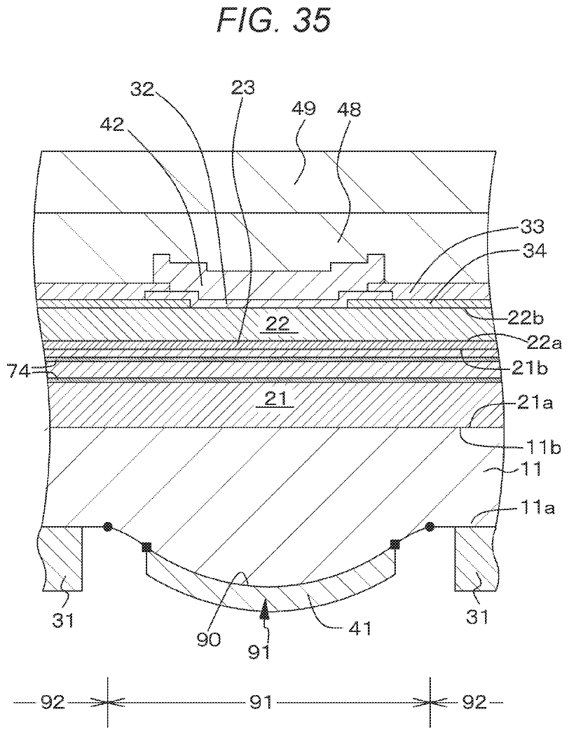

In the light emitting element of Embodiment 20, as illustrated in FIG. 35 which is a schematic partial cross-sectional view, the second light reflecting layer 42 is fixed to the support substrate 49 formed using a silicon semiconductor substrate via the bonding layer 48 formed using a gold (Au) layer or a solder layer containing tin (Sn) on the basis of a solder bonding method.

The light emitting element of Embodiment 20 can be manufactured on the basis of a method similar to that for the light emitting element of Embodiment 1 except that 20 light absorbing material layers 74 are also formed inside the first compound semiconductor layer 21 and the support substrate 49 is not removed.

### Embodiment 21

Embodiment 21 is a modification of Embodiments 1 to 20. In the light emitting element in which the first light reflecting layer functions as a kind of concave mirror, there is a possibility that optical crosstalk in which stray light generated in a certain light emitting element enters an adjacent light emitting element occurs in some structures. The light emitting element of Embodiment 21 has a configuration and structure capable of preventing occurrence of such optical crosstalk.

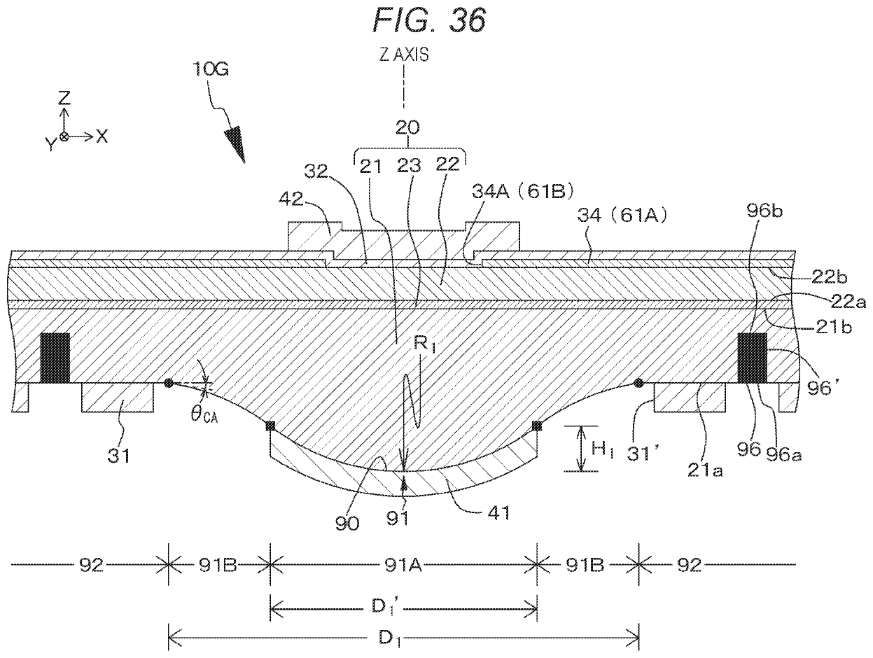

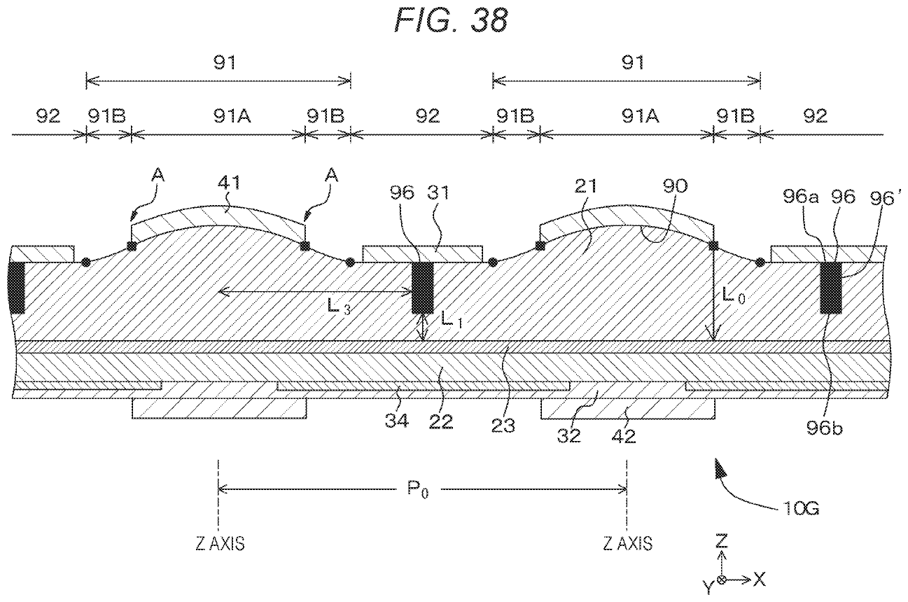

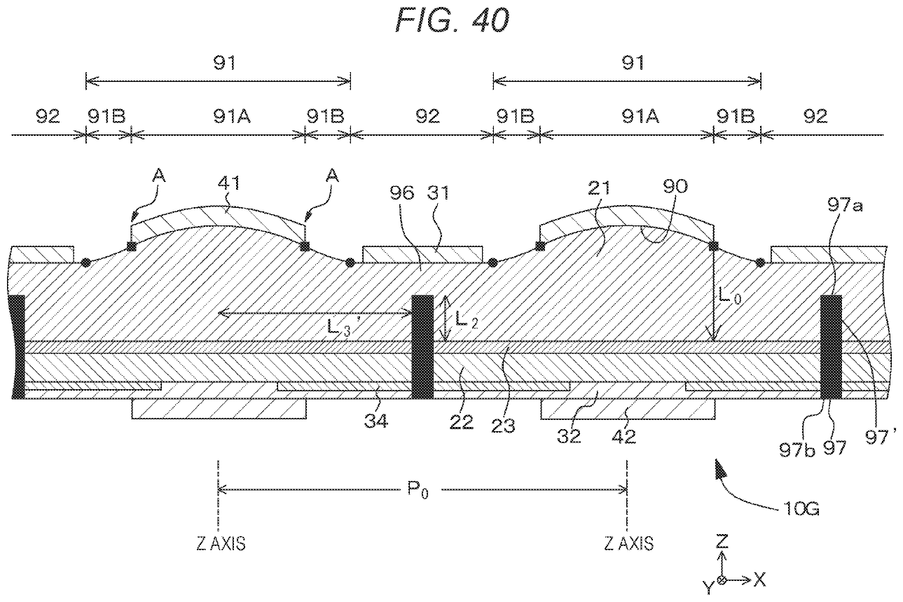

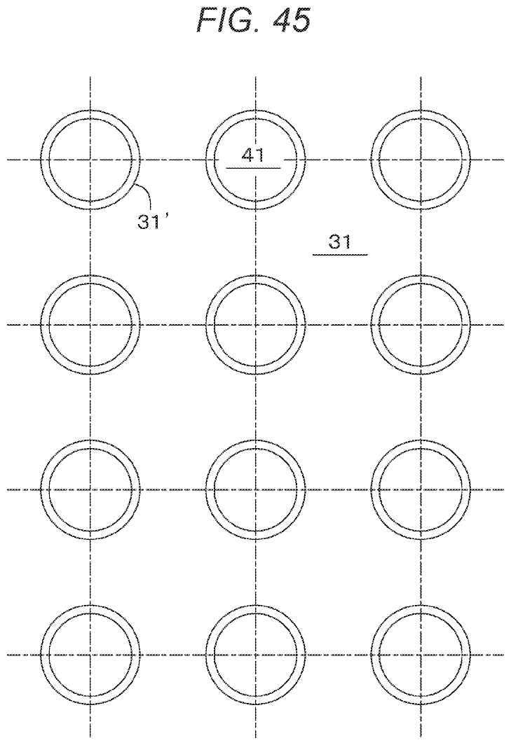

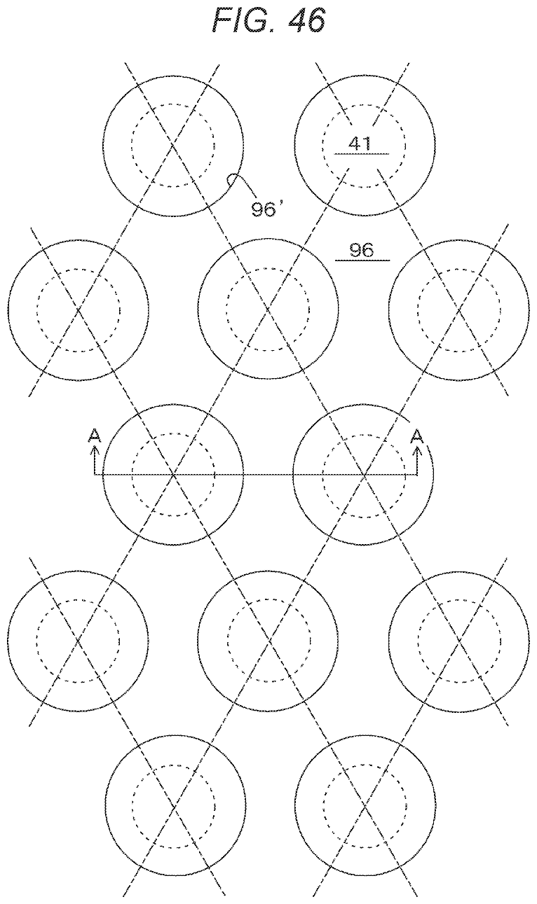

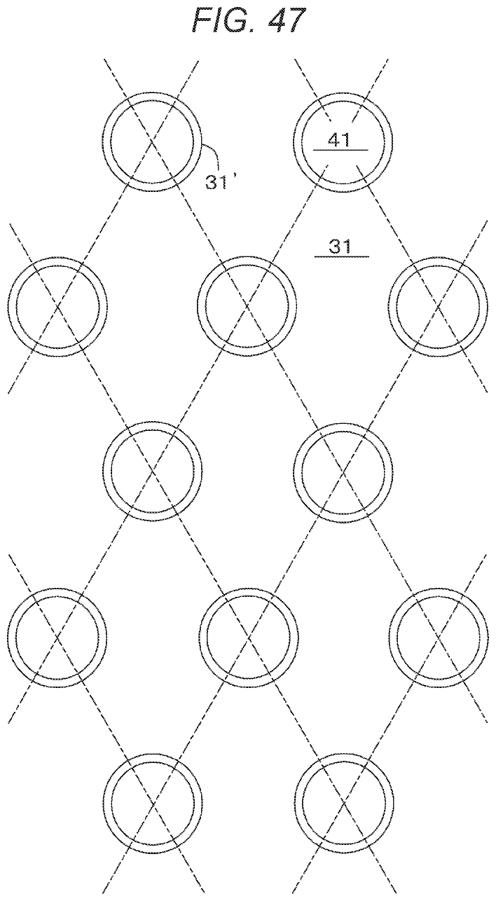

FIGS. 36, 37, 39, 41, 42, and 43 are schematic partial cross-sectional views of a light emitting element 10G of Embodiment 21, FIG. 38 is a schematic partial cross-sectional view of a light emitting element array including Modified Example-1 of the light emitting element 10G of Embodiment 21, and FIG. 40 is a schematic partial cross-sectional view of a light emitting element array including Modified Example-2 of the light emitting element 10G of Embodiment 21. Furthermore, FIGS. 44, 46, 48, 49, 50, and 51 are schematic plan views illustrating disposition of the first light reflecting layer and the partition wall in the light emitting element array including Modified Example-1 of the light emitting element 10G of Embodiment 21, and FIGS. 45 and 47 are schematic plan views illustrating disposition of the first light reflecting layer and the first electrode in the light emitting element array including Modified Example-1 of the light emitting element 10G of Embodiment 21. Note that FIGS. 44, 45, 48, and 50 illustrate a case where the light emitting element is positioned at a vertex (intersection portion) of a square lattice, and FIGS. 46, 47, 49, and 51 illustrate a case where the light emitting element is positioned at a vertex (intersection portion) of a regular triangle lattice. Furthermore, in FIGS. 38 and 40, an end portion of a facing surface of the first light reflecting layer that faces the first surface of the first compound semiconductor layer is indicated by “A”.

Specifically, in the light emitting element 10G of Embodiment 21, as illustrated in FIG. 36 which is a schematic partial cross-sectional view, a partition wall 96 extending in the stacking direction of the stacked structure 20 is formed so as to surround the first light reflecting layer 41.

Specifically, an orthogonal projection image of the top portion of the protrusion 91 is included in an orthogonal projection image of a side surface of the partition wall 96 that faces the first light reflecting layer 41 (which may hereinafter be simply referred to as a “side surface 96′ of the partition wall 96”). Alternatively, the orthogonal projection image of the side surface 96′ of the partition wall 96 may be included in an orthogonal projection image of a portion of the first light reflecting layer 41 that does not contribute to light reflection (a non-effective region of the first light reflecting layer 41). The side surface 96′ of the partition wall 96 may be a continuous surface or a discontinuous surface partially cut out. Note that, in the present specification, the “orthogonal projection image” means an orthogonal projection image obtained in a case where orthogonal projection is performed on the stacked structure 20.

The partition wall 96 extends from the first surface side of the first compound semiconductor layer 21 to the middle of the first compound semiconductor layer 21 in the thickness direction in the first compound semiconductor layer 21. That is, an upper end portion 96b of the partition wall 96 is positioned at the middle of the first compound semiconductor layer 21 in the thickness direction. A lower end portion 96a of the partition wall 96 is exposed at a first surface of the light emitting element 10G. Here, the “first surface of the light emitting element” refers to an exposed surface of the light emitting element 10G on a side where the first light reflecting layer 41 is provided, and a “second surface of the light emitting element” refers to an exposed surface of the light emitting element 10G on a side where a second light reflecting layer 42 is provided.

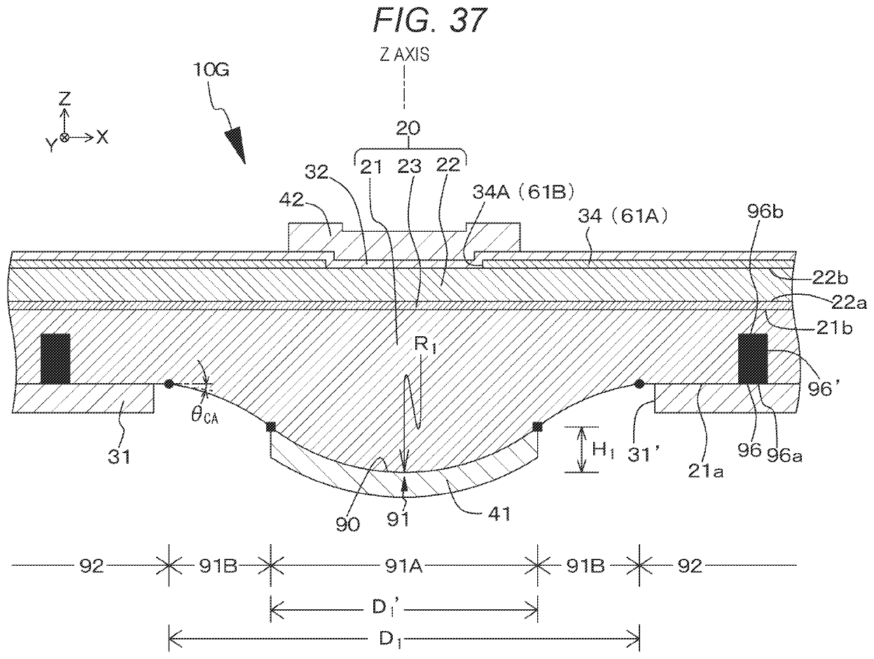

Alternatively, as illustrated in FIG. 37 which is a schematic partial cross-sectional view of Modified Example-1 of the light emitting element 10G of Embodiment 21, and in FIG. 38 which is a schematic partial cross-sectional view of a light emitting element array including a plurality of Modified Examples-1 of the light emitting element 10G, the partition wall 96 is not exposed at the first surface of the light emitting element 10G, and the lower end portion 96a of the partition wall 96 is covered by the first electrode 31.

Then, in the light emitting element array including the light emitting element 10G of Embodiment 21 or Modified Example-1 of the light emitting element 10G of Embodiment 21, a relationship between L₀, L₁, and L₃ is as follows.

It is desirable to satisfy the following Formula (1), preferably, Formula (1′), satisfy the following Formula (2), preferably, Formula (2′), satisfy the following Formulas (1) and (2), or satisfy the following Formulas (1′) and (2′).

0.01×L₀≤L₀−L₁ (1)

0.05×L₀≤L₀−L₁ (1′)

0.01×L₃≤L₁ (2)

0.05×L₃≤L₁ (2′)

where

L₀: a distance from the end portion of the facing surface of the first light reflecting layer that faces the first surface of the first compound semiconductor layer to the active layer,

L₁: a distance from the active layer to an end portion (the upper end portion of the partition wall and an end portion facing the active layer) of the partition wall extending to the middle of the first compound semiconductor layer in the thickness direction in the first compound semiconductor layer, and

L₃: a distance from an axial line of the first light reflecting layer included in the light emitting element to an orthogonal projection image of the partition wall on the stacked structure (more specifically, an orthogonal projection image of the upper end portion of the partition wall). Note that an upper limit value of (L₀-L₁) is less than L₀, but in a case where a short circuit does not occur between the active layer and a first electrode due to the partition wall, the upper limit value of (L₀-L₁) may be equal to or more than L₀.

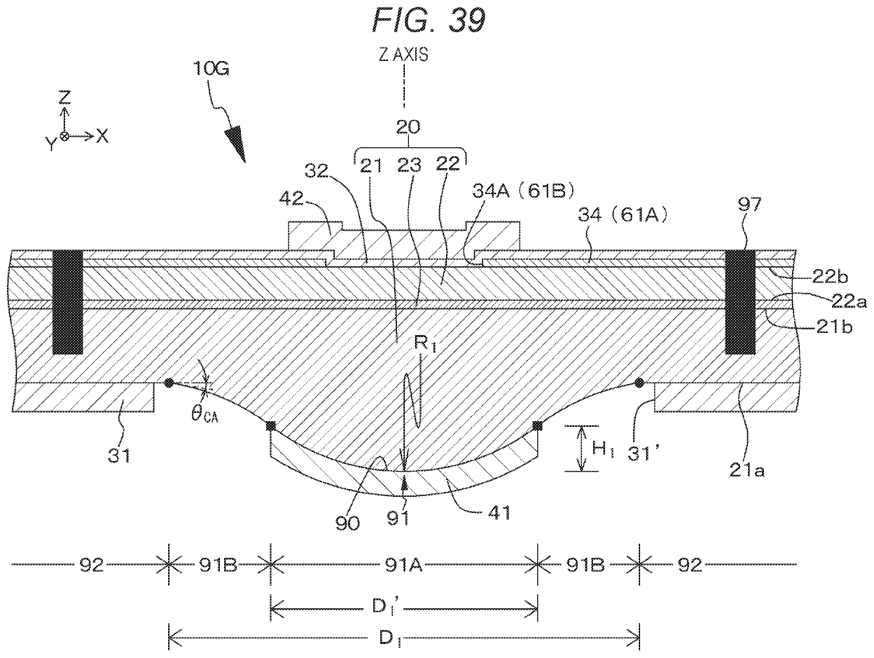

Alternatively, as illustrated in FIG. 39 which is a schematic partial cross-sectional view of Modified Example-2 of the light emitting element 10G of Embodiment 21, and in FIG. 40 which is a schematic partial cross-sectional view of a light emitting element array including a plurality of Modified Examples-2 of the light emitting element 10G, a partition wall 97 extends from the second surface side of the second compound semiconductor layer 22 in the second compound semiconductor layer 22 and the active layer 23, and further extends to the middle of the first compound semiconductor layer 21 in the thickness direction in the first compound semiconductor layer 21. That is, a lower end portion 97a of the partition wall 97 may be positioned at the middle of the first compound semiconductor layer 21 in the thickness direction. An upper end portion 97b of the partition wall 97 is exposed at the second surface of the light emitting element 10G.

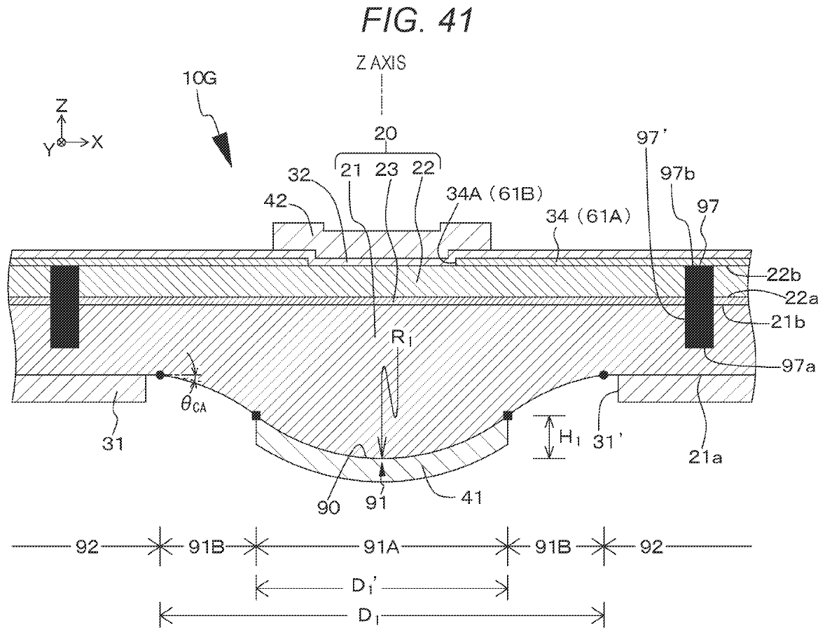

Alternatively, as illustrated in FIG. 41 which is a schematic partial cross-sectional view of Modified Example-3 of the light emitting element 10G of Embodiment 21, the upper end portion 97b of the partition wall 97 is not exposed at the second surface of the light emitting element 10G. Specifically, the upper end portion 97b of the partition wall 97 is covered by the insulating layer (current constriction layer) 34 and the second electrode 32.

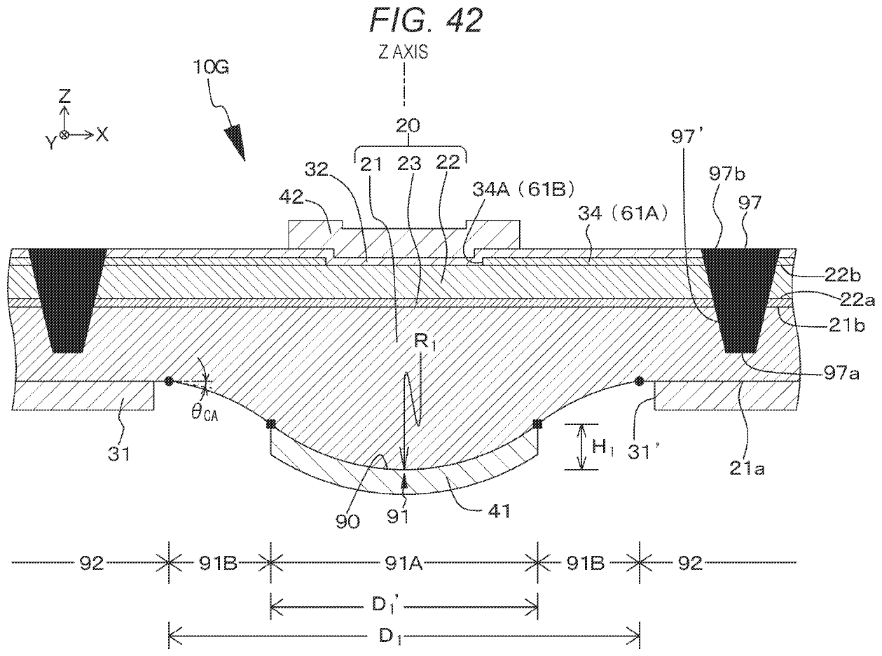

Alternatively, as illustrated in FIG. 42 which is a schematic partial cross-sectional view of Modified Example-4 of the light emitting element 10G of Embodiment 21, a side surface 97′ of the partition wall 97 is narrowed along a direction from the first surface side of the first compound semiconductor layer 21 toward the second surface side of the second compound semiconductor layer 22. That is, a shape of the side surface 97′ of the partition wall 97 in a case where the light emitting element 10G is cut along a virtual plane (XZ plane) including the stacking direction of the stacked structure 20 is a trapezoid. Specifically, the shape of the side surface 97′ of the partition wall 97 in a case where the light emitting element 10G is cut along the virtual plane (XZ plane) including the stacking direction of the stacked structure 20 is an isosceles trapezoid in which a second compound semiconductor layer side is a shorter side and a first compound semiconductor layer 21 side is a longer side. Further, accordingly, stray light can be returned to the light emitting element itself more efficiently.

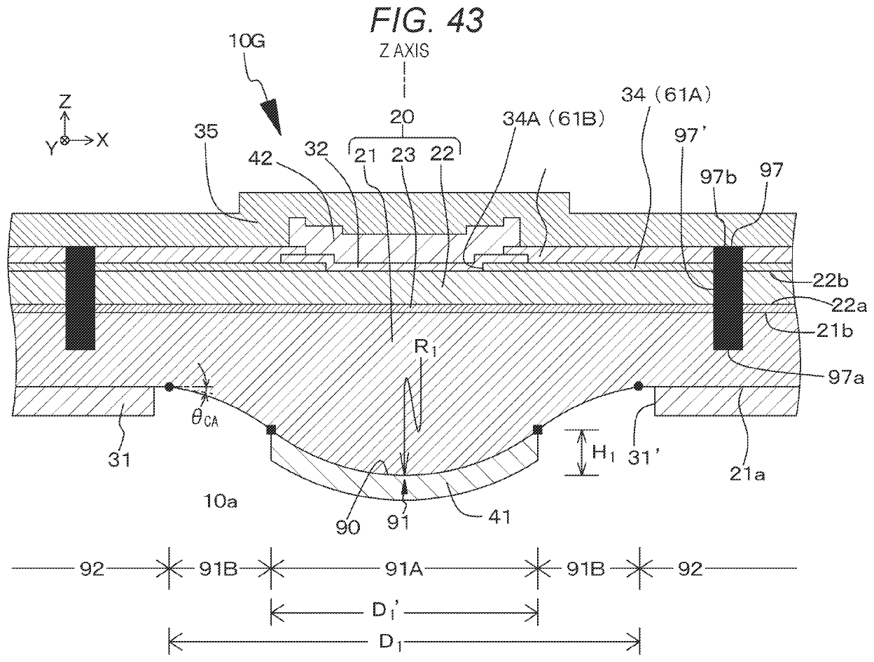

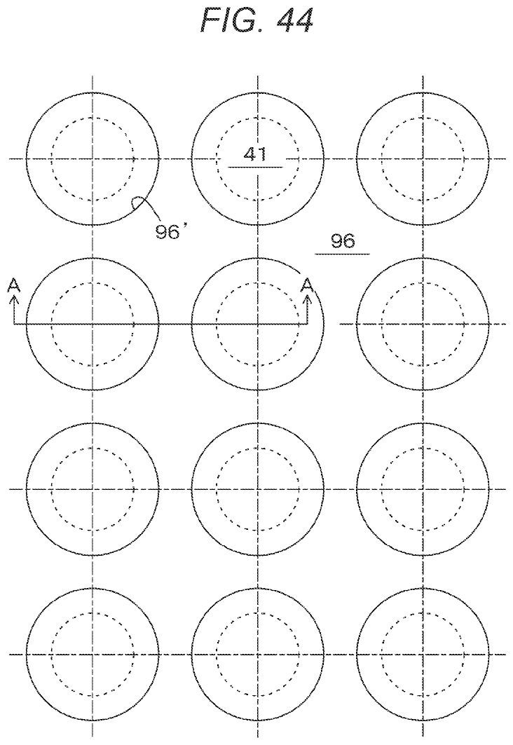

Alternatively, as illustrated in FIG. 43 which is a schematic partial cross-sectional view of Modified Example-5 of the light emitting element 10G of Embodiment 21, the partition wall 97 is formed using a solder material, and a portion of the partition wall 97 is exposed at an outer surface of the light emitting element 10G. A kind of bump can be constituted by the portion of the partition wall 97 exposed at the outer surface of the light emitting element 10G. Specific examples of the material of such a partition wall 97 can include a material of the bump described above, and more specific examples thereof can include a Au—Sn eutectic solder. The portion of the partition wall 97 is formed on the outer surface of the light emitting element 10G, and connection to an external circuit or the like can be made via the portion of the partition wall 97 exposed at the second surface of the light emitting element 10G.

Then, in the light emitting element array including Modified Example-2, Modified Example-3, Modified Example-4, and Modified Example-5 of the light emitting element 10G of Embodiment 21, a relationship between L₀, L₂, and L₃′ is as follows.

It is desirable to satisfy the following Formula (3), preferably, Formula (3′), satisfy the following Formula (4), preferably, Formula (4′), satisfy the following Formulas (3) and (4), or satisfy the following Formulas (3′) and (4′).

0.01×L₀≤L₂ (3)

0.05×L₀≤L₂ (3′)

0.01×L₃′≤L₂ (4)

0.05×L₃′≤L₂ (4′)

where

L₀: the distance from the end portion of the facing surface of the first light reflecting layer that faces the first surface of the first compound semiconductor layer to the active layer,

L₂: a distance from the active layer to an end portion (the lower end portion of the partition wall and an end portion facing the first electrode) of the partition wall extending to the middle of the first compound semiconductor layer in the thickness direction in the first compound semiconductor layer, and

L₃′: a distance from the axial line of the first light reflecting layer included in the light emitting element to an orthogonal projection image of the partition wall on the stacked structure (more specifically, an orthogonal projection image of the lower end portion of the partition wall). Note that an upper limit value of L₂ is less than L₀, but in a case where a short circuit does not occur between the active layer and the first electrode due to the partition wall, the upper limit value of L₂ may be equal to or more than L₀.

An example of these specific values is shown in Tables 8 and 9 below.

TABLE 8

P₀: 40 μm
L₀: 30 μm
L₁: 28 μm
L₃: 18 μm

TABLE 9

P₀: 20 μm
L₀: 17 μm
L₂: 12 μm
L₃′: 9 μm

A shape of each of the side surfaces 96′ and 97′ of the partition walls 96 and 97 in a case where the light emitting element 10G is cut along a virtual plane (for example, the XZ plane in the illustrated example,) including the stacking direction of the stacked structure 20 is a line segment. In addition, the shape of each of the side surfaces 96′ and 97′ of the partition walls 96 and 97 in a case where the light emitting element 10G is cut along a virtual plane (XY plane) orthogonal to the stacking direction of the stacked structure 20 is a circle. However, the present disclosure is not limited thereto.

In a case where the light emitting elements 10G are arranged in an array, the partition wall 96 is provided so as to surround the first light reflecting layer 41 included in each light emitting element 10G, but a region outside the side surface 96′ of the partition wall 96 may be occupied by the partition wall 96. That is, a space between the light emitting elements 10G may be occupied by the material of the partition wall 96. As illustrated in FIGS. 44 and 46, the partition wall 96 is provided so as to surround the first light reflecting layer 41 included in each light emitting element 10G, and the region outside the side surface 96′ of the partition wall 96 is occupied by the partition wall 96. That is, the space between the light emitting elements 10G is occupied by the material of the partition wall 96.

As illustrated in FIG. 45 or 47, in a case where the partition wall 96 is formed using a material having no conductivity, the first electrode 31 is provided on the first surface 21a of the first compound semiconductor layer 21. Furthermore, in a case where the partition wall 96 is formed using a material having conductivity, or in a case where the partition wall 96 is formed using a material having no conductivity, the first electrode 31 may be provided on an exposed surface (lower end surface 96a) of the partition wall 96. Specifically, the lower end portion (an end portion facing the first electrode 31) 96a of the partition wall 96 is in contact with the first electrode 31 formed on the first surface (the first surface 21a of the first compound semiconductor layer 21) of the light emitting element 10G. In a case where the partition wall 96 is formed using a material having conductivity, the partition wall 96 may also serve as the first electrode 31. In a case where the partition wall 96 is formed using a material having a high thermal conductivity, heat generated in the stacked structure 20 can be released (dissipated) to the outside through the partition wall 96. Specifically, the heat generated in the stacked structure 20 can be effectively released (dissipated) to the outside through the partition wall 96 and the first electrode 31 or the first pad electrode.

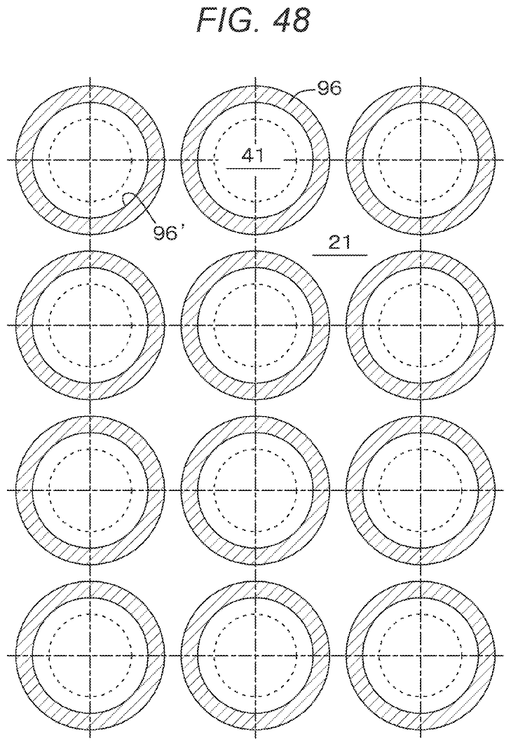

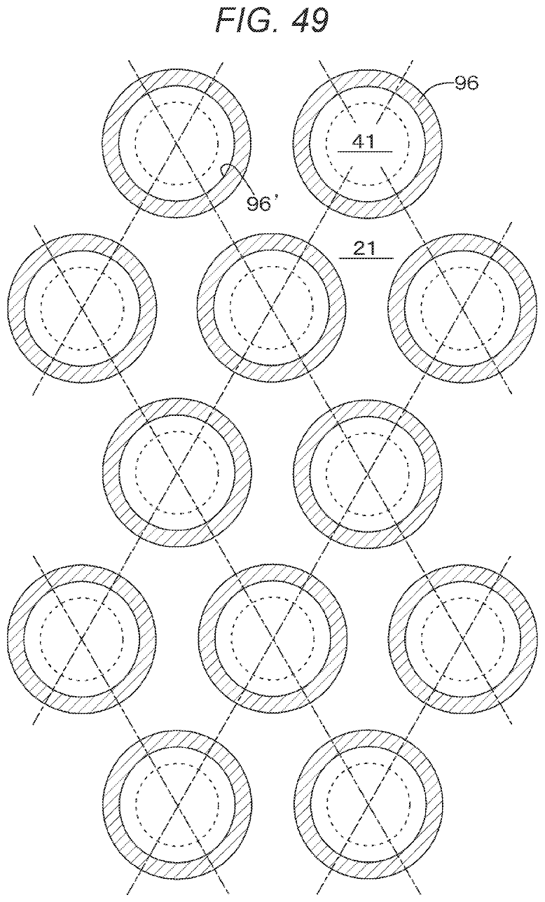

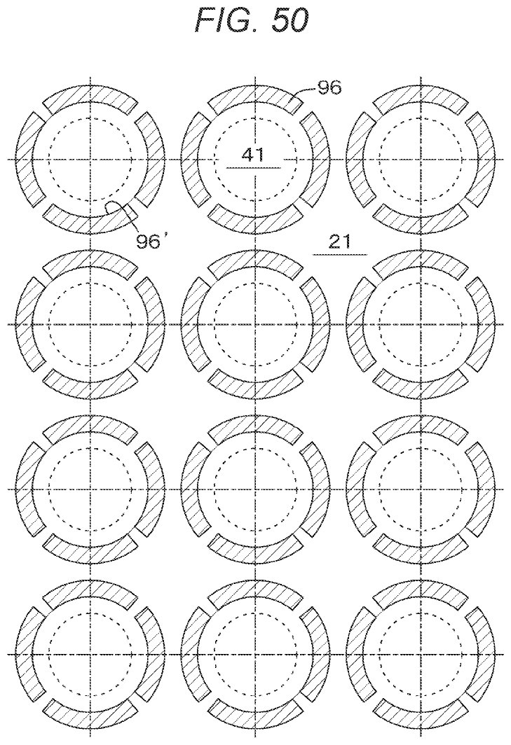

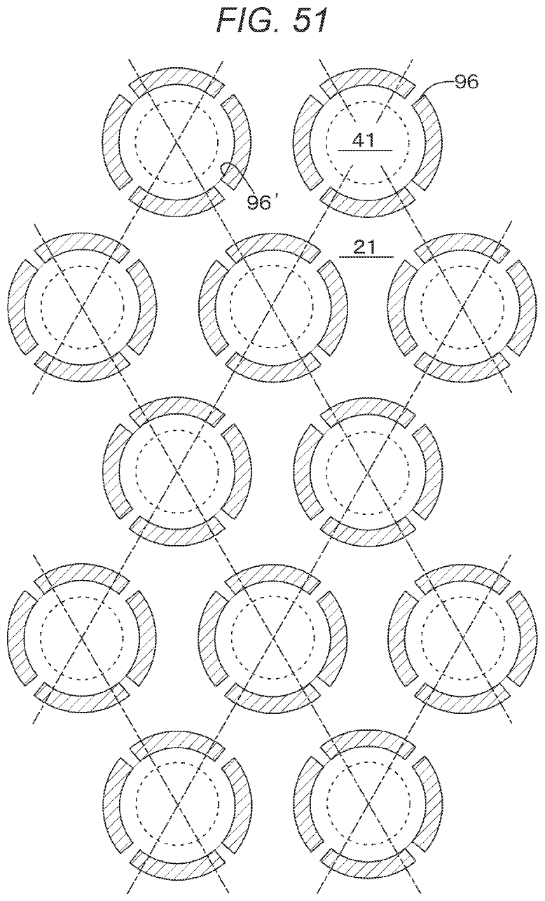

Alternatively, the region outside the side surface 96′ of the partition wall 96 is occupied by a material (for example, the stacked structure 20) other than the material of the partition wall 96. In this case, the partition wall 96 is formed in, for example, a continuous groove shape or a discontinuous groove shape. That is, the space between the light emitting elements 10G may be occupied by a material (for example, the stacked structure 20) other than the material of the partition wall 96. Then, for example, the partition wall 96 may be formed in a continuous groove shape (see FIGS. 48 and 49), or may be formed in a discontinuous groove shape (see FIGS. 50 and 51). Note that, in FIGS. 48, 49, 50, and 51, a portion corresponding to the partition wall 96 is hatched to clearly show the partition wall 96.

The partition walls 96 and 97 can be formed using a material that does not transmit light generated in the active layer, and thus, generation of stray light and occurrence of optical crosstalk can be prevented. Specifically, examples of such a material can include a material capable of blocking light, such as titanium (Ti), chromium (Cr), tungsten (W), tantalum (Ta), aluminum (Al), or MoSi₂, and for example, formation can be performed by a vapor deposition method including an electron beam vapor deposition method, a hot filament vapor deposition method, and a vacuum vapor deposition method, a sputtering method, a chemical vapor deposition (CVD) method, an ion plating method, or the like. Alternatively, a black resin film (specifically, for example, a black polyimide-based resin, an epoxy-based resin, or a silicone-based resin) mixed with a black colorant and having an optical density of 1 or more can be used.

Alternatively, the partition walls 96 and 97 can be formed using a material that reflects light generated in the active layer, and thus, generation of stray light and occurrence of optical crosstalk can be prevented, and stray light can be efficiently returned to the light emitting element itself, which can contribute to improvement of light emission efficiency of the light emitting element. Specifically, the partition walls 96 and 97 each include a thin film filter using interference of a thin film. The thin film filter has a similar configuration and structure although a stacking direction (alternate arrangement direction) is different from that of, for example, the light reflecting layer. Specifically, a concave portion is formed at a portion of the stacked structure 20, and the concave portion is sequentially filled with a similar material to that of the light reflecting layer on the basis of, for example, a sputtering method, such that it is possible to obtain the thin film filter in which dielectric layers are alternately arranged in a case where the partition walls 96 and 97 are cut along a virtual plane (XY plane) orthogonal to the stacking direction of the stacked structure 20. Alternatively, as such a material, a metal material, an alloy material, or a metal oxide material can be exemplified, and more specifically, copper (Cu) or an alloy thereof, gold (Au) or an alloy thereof, tin (Sn) or an alloy thereof, silver (Ag) or a silver alloy (for example, Ag—Pd—Cu or Ag—Sm—Cu), platinum (Pt) or an alloy thereof, palladium (Pd) or an alloy thereof, titanium (Ti) or an alloy thereof, aluminum (Al) or an aluminum alloy (for example, Al—Nd or Al—Cu), an Al/Ti stacked structure, an Al—Cu/Ti stacked structure, chromium (Cr) or an alloy thereof, indium tin oxide (ITO), or the like can be exemplified, and formation can be performed by, for example, a vapor deposition method including an electron beam vapor deposition method, a hot filament vapor deposition method, and a vacuum vapor deposition method, a sputtering method, a CVD method, an ion plating method, a plating method (electroplating method or electroless plating method), a lift-off method, a laser ablation method, a sol-gel method, a plating method, or the like.

Alternatively, 1×10⁻¹≤TC₁/TC₀≤1×10², where a thermal conductivity of a material of the first compound semiconductor layer 21 is TC₁, and a thermal conductivity of the material of the partition walls 96 and 97 is TC₀. Specifically, examples of such a material of the partition walls 96 and 97 can include a metal such as silver (Ag), copper (Cu), gold (Au), tin (Sn), aluminum (Al), ruthenium (Ru), rhodium (Rh), or platinum (Pt), alloys thereof, or mixtures of these metals, ITO, and the like, and for example, formation can be performed by a vapor deposition method including an electron beam vapor deposition method, a hot filament vapor deposition method, and a vacuum vapor deposition method, a sputtering method, a CVD method, an ion plating method, a plating method (electroplating method or electroless plating method), a lift-off method, a laser ablation method, a sol-gel method, a plating method, or the like. Then, as the partition walls 96 and 97 are formed using a material having a high thermal conductivity as described above, heat generated in the stacked structure 20 can be released (dissipated) to the outside through the partition walls 96 and 97. Note that, in this case, a partition wall extension portion may be formed on the outer surface (the first surface or the second surface) of the light emitting element 10G so that heat generated in the stacked structure 20 can be released (dissipated) to the outside via the partition walls 96 and 97 and the partition wall extension portion, or the partition walls 96 and 97 may be connected to the first electrode 31, the second electrode 32, or the pad electrode so that heat generated in the stacked structure 20 can be released (dissipated) to the outside via the partition walls 96 and 97 and the first electrode 31, the second electrode 32, or the pad electrode.

Alternatively, |CTE₀−CTE₁|≤1×10⁻⁴/K, where a linear expansivity of the material of the first compound semiconductor layer 21 is CTE₁, and a linear expansivity of the material of the partition walls 96 and 97 is CTE₀. Specifically, examples of such a material of the partition walls 96 and 97 can include a polyimide-based resin, a silicone-based resin, an epoxy-based resin, a carbon-based material, SOG, polycrystalline GaN, and monocrystalline GaN. By defining the linear expansivity in this manner, a thermal expansion coefficient (linear expansion coefficient) of the entire light emitting element can be optimized, and thermal expansion of the light emitting element 10G can be controlled (suppressed). Specifically, for example, a net thermal expansion coefficient of the stacked structure 20 can be increased, and can be adjusted to match a thermal expansion coefficient of a substrate material or the like on which the light emitting element 10G is mounted, such that it is possible to prevent damage of the light emitting element 10G and to suppress a decrease in reliability of the light emitting element 10G due to generation of stress. The partition walls 96 and 97 formed using a polyimide-based resin can be formed on the basis of, for example, a spin coating method and a curing method.

Alternatively, in a case where the partition walls 96 and 97 are formed using an insulating material, occurrence of electrical crosstalk can be suppressed. That is, it is possible to prevent an unnecessary current from flowing between adjacent light emitting elements 10G.

Examples of the shape of each of the side surfaces 96′ and 97′ of the partition walls 96 and 97 in a case where the light emitting element 10G is cut along the virtual plane (XZ plane) including the stacking direction of the stacked structure 20 can include a line segment, an arc, a part of a parabola, and a part of an arbitrary curve. In addition, examples of a shape of each of the side surfaces 96′ and 97′ of the partition walls 96 and 97 in a case where the light emitting element 10G is cut along the virtual plane (XY plane) orthogonal to the stacking direction of the stacked structure 20 can include a circle, an ellipse, an oval, a quadrangle including a square or a rectangle, and a regular polygon (including a rounded regular polygon).

Then, more specifically, in Embodiment 21, the partition walls 96 and 97 are formed using a material that does not transmit light generated in the active layer 23, or 1×10⁻¹≤TC₁/TC₀≤1×10², where the thermal conductivity of the material of the first compound semiconductor layer 21 is TC₁, and the thermal conductivity of the material of the partition walls 96 and 97 is TC₀. Specifically, the material of the first compound semiconductor layer 21 includes GaN, and the partition walls 96 and 97 are formed using copper (Cu). Note that

TC₀: 50 watts/(m·K) to 100 watts/(m·K), and

TC₁: 400 watts/(m·K). For example, in a case where the partition walls 96 and 97 each including a copper layer is formed by a plating method, it is sufficient if an underlying layer including a Au layer or the like having a thickness of about 0.1 μm is formed in advance as a seed layer by a sputtering method or the like, and the copper layer is formed thereon by a plating method. As the partition walls 96 and 97 are formed using a material having a high thermal conductivity as described above, heat generated in the stacked structure 20 can be effectively released (dissipated) to the outside through the partition walls 96 and 97.

Alternatively, the partition walls 96 and 97 are formed using a material that reflects light generated in the active layer 23, for example, silver (Ag).

Alternatively, |CTE₀-CTE₁|≤1×10⁻⁴/K, where the linear expansivity of the material (GaN) of the first compound semiconductor layer 21 is CTE₁, and the linear expansivity of the material (polyimide-based resin) of the partition walls 96 and 97 is CTE₀. Specifically,

CTE₀: 5.5×10⁻⁶/K, and

CTE₁: 25×10⁻⁶/K. Then, as these materials are combined, a net thermal expansion coefficient (linear expansion coefficient) of the light emitting element 10G can be increased and can be adjusted to match a thermal expansion coefficient of a substrate material or the like on which the light emitting element 10G is mounted, such that it is possible to suppress damage of the light emitting element 10G and to suppress a decrease in reliability of the light emitting element 10G due to generation of stress.

### Embodiment 22

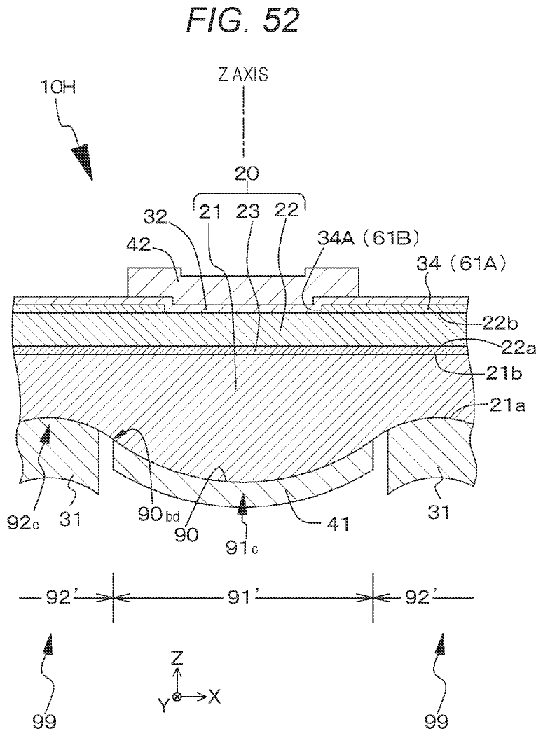

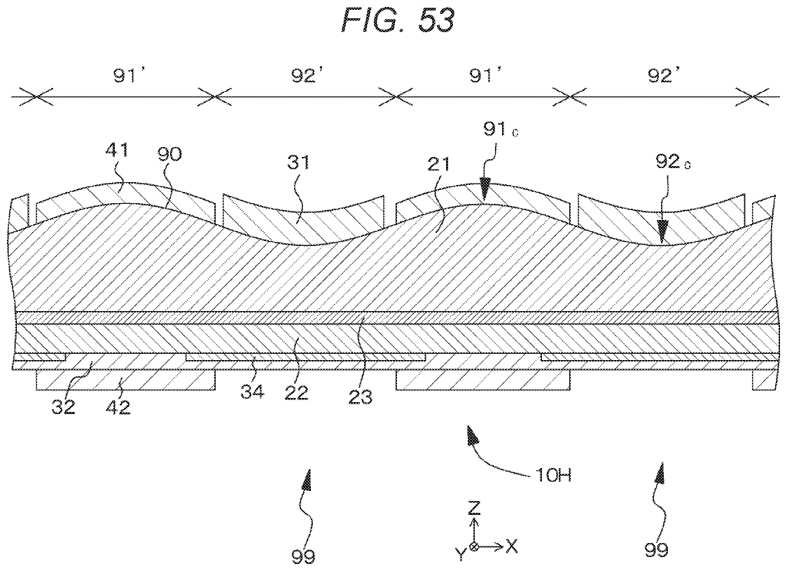

Embodiment 22 is a modification of Embodiments 1 to 4. FIG. 52 is a schematic partial end view of a light emitting element 10H of Embodiment 22, and FIG. 53 is a schematic partial end view of a light emitting element array of Embodiment 22. The light emitting element of Embodiment 22 relates to a light emitting element of an 8-A-th configuration as described later.

In the light emitting element array of Embodiment 22, the first light reflecting layer 41 is formed on the base surface 90 positioned on the first surface side of the first compound semiconductor layer 21, the base surface 90 extends in the peripheral region or extends in the peripheral region surrounded by a plurality of light emitting elements 10H, and the base surface 90 is uneven and differentiable.

Here, in a case where the base surface 90 is represented by z=f(x,y), a differential value for the base surface 90 can be obtained by the following:

∂z/∂x=[∂f(x,y)/∂x]_{y}, and

∂z/∂y=[∂f(x,y)/∂y]ₓ.

In the light emitting element of Embodiment 22, although the first light reflecting layer 41 is formed at a first portion 91′ of the base surface 90, in some cases, the extension portion of the first light reflecting layer 41 is formed at a second portion 92′ of the base surface 90 occupying the peripheral region, or the extension portion of the first light reflecting layer 41 is not formed at the second portion 92′.

In the light emitting element of Embodiment 22, the base surface 90 is preferably smooth. In addition, the first portion 91′ of the base surface 90 on which the first light reflecting layer 41 is formed can have an upward convex shape with respect to the second surface of the first compound semiconductor layer 21. The light emitting element of Embodiment 22 having such a configuration is referred to as a “light emitting element of an eighth configuration”.

Here, in the light emitting element of the eighth configuration, a boundary between the first portion 91′ and the second portion 92′ can be defined as:

(1) an outer peripheral portion of the first light reflecting layer 41 in a case where the first light reflecting layer 41 does not extend in the peripheral region, and

(2) a portion where an inflection point is present in the base surface 90 from the first portion 91′ to the second portion 92′ in a case where the first light reflecting layer 41 extends in the peripheral region.

The light emitting element of the eighth configuration can have a configuration in which the second portion 92′ of the base surface 90 occupying the peripheral region has a downward convex shape with respect to the second surface of the first compound semiconductor layer. The light emitting element of Embodiment 22 having such a configuration is referred to as a “light emitting element of an 8-A-th configuration”. Then, in the light emitting element of the 8-A-th configuration, a central portion of the first portion 91′ of the base surface 90 can be positioned at a vertex (intersection portion) of a square lattice, or the central portion of the first portion 91′ of the base surface 90 can be positioned at a vertex (intersection portion) of a regular triangular lattice. In the former case, a central portion of the second portion 92′ of the base surface 90 can be positioned at a vertex of the square lattice, and in the latter case, the central portion of the second portion 92′ of the base surface 90 can be positioned at a vertex of the regular triangular lattice.

In the light emitting element of the 8-A-th configuration, shapes of [the first portion 91′/second portion 92′ from the peripheral portion to the central portion] include:

(A) [upward convex shape/downward convex shape];

(B) [upward convex shape/continuing from downward convex shape to line segment];

(C) [upward convex shape/continuing from upward convex shape to downward convex shape];

(D) [upward convex shape/continuing from upward convex shape to downward convex shape and line segment];

(E) [upward convex shape/continuing from line segment to downward convex shape]; and

(F) [upward convex shape/continuing from line segment to downward convex shape and line segment]. Note that, in the light emitting element, the base surface 90 may end at the central portion of the second portion 92′.

Alternatively, the light emitting element of the eighth configuration can have a configuration in which the second portion 92′ of the base surface 90 occupying the peripheral region has a downward convex shape and an upward convex shape extending from the downward convex shape toward a central portion of the peripheral region with respect to the second surface 21b of the first compound semiconductor layer 21. The light emitting element of Embodiment 22 having such a configuration is referred to as a “light emitting element of an 8-B-th configuration”. Further, the light emitting element of the 8-B-th configuration can have a configuration in which LL₂>LL₁, where a distance from the second surface 21b of the first compound semiconductor layer 21 to the central portion of the first portion 91′ of the base surface 90 is LL₁, and a distance from the second surface of the first compound semiconductor layer 21 to the central portion of the second portion 92′ of the base surface 90 is LL₂, and R₁>R₂, where a radius of curvature of the central portion of the first portion 91′ of the base surface 90 (that is, the radius of curvature of the first light reflecting layer 41) is R₁, and a radius of curvature of the central portion of the second portion 92′ of the base surface 90 is R₂. Note that, although a value of LL₂/LL₁ is not limited, 1<LL₂/LL₁≤100 can be satisfied, and although a value of R₁/R₂ is not limited, 1<R₁/R₂≤100 can be satisfied.

In the light emitting element of the 8-B-th configuration having the above-described preferable configuration, the central portion of the first portion 91′ of the base surface 90 can be positioned at a vertex (intersection portion) of a square lattice, and in this case, the central portion of the second portion 92′ of the base surface 90 can be positioned at a vertex of the square lattice. Alternatively, the central portion of the first portion 91′ of the base surface 90 can be positioned at a vertex of a regular triangular lattice, and in this case, the central portion of the second portion 92′ of the base surface 90 can be positioned at a vertex of the regular triangular lattice.

In the light emitting element of the 8-B-th configuration, shapes of [the first portion 91′/second portion 92′ from the peripheral portion to the central portion] include:

(A) [upward convex shape/continuing from downward convex shape to upward convex shape];

(B) [upward convex shape/continuing from upward convex shape to downward convex shape and upward convex shape]; and

(C) [upward convex shape/[continuing from line segment to downward convex shape and upward convex shape].

Alternatively, the light emitting element of the eighth configuration can have a configuration in which the second portion 92′ of the base surface 90 occupying the peripheral region has an annular convex shape surrounding the first portion 91′ of the base surface 90 and a downward convex shape extending from the annular convex shape toward the first portion 91′ of the base surface 90 with respect to the second surface of the first compound semiconductor layer 21. The light emitting element of Embodiment 2 having such a configuration is referred to as a “light emitting element of an 8-C-th configuration”.

Further, the light emitting element of the 8-C-th configuration can have a configuration in which LL₂′>LL₁, where the distance from the second surface 21b of the first compound semiconductor layer 21 to the central portion of the first portion 91′ of the base surface 90 is LL₁, and a distance from the second surface of the first compound semiconductor layer 21 to a top portion of the annular convex shape of the second portion 92′ of the base surface 90 is LL₂′, and R₁>R₂′, where the radius of curvature of the central portion of the first portion 91′ of the base surface 90 (that is, the radius of curvature of the first light reflecting layer 41) is R₁, and a radius of curvature of the top portion of the annular convex shape of the second portion 92′ of the base surface 90 is R₂′. Note that, although a value of LL₂′/LL₁ is not limited, 1<LL₂′/LL₁≤100 can be satisfied, and although a value of R₁/R₂′ is not limited, 1<R₁/R₂′≤100 can be satisfied.

In the light emitting element of the 8-C-th configuration, shapes of [the first portion 91′/second portion 92′ from the peripheral portion to the central portion] include:

(A) [upward convex shape/continuing from downward convex shape to upward convex shape and downward convex shape];

(B) [upward convex shape/continuing from downward convex shape to upward convex shape, downward convex shape, and line segment];

(C) [upward convex shape/continuing from upward convex shape to downward convex shape, upward convex shape, and downward convex shape];

(D) [upward convex shape/continuing from upward convex shape to downward convex shape, upward convex shape, and line segment];

(E) [upward convex shape/continuing from line segment to downward convex shape, upward convex shape, and downward convex shape]; and

(F) [upward convex shape/continuing from line segment to downward convex shape, upward convex shape, downward convex shape, and line segment]. Note that, in the light emitting element, the base surface 90 may end at the central portion of the second portion 92′.

In the light emitting element of Embodiment 22 having the above-described preferable form and configuration, a figure drawn by the first portion 91′ of the base surface 90 in a case where the base surface 90 is cut along a virtual plane including the stacking direction of the stacked structure can be a part of a circle, a part of a parabola, a part of a sine curve, a part of an ellipse, or a part of a catenary curve. In some cases, the figure is not strictly a part of a circle, is not strictly a part of a parabola, is not strictly a part of a sine curve, is not strictly a part of an ellipse, or is not strictly a part of a catenary curve. That is, a case where the figure is substantially a part of a circle, a case where the figure is substantially a part of a parabola, a case where the figure is substantially a part of a sine curve, a case where the figure is substantially a part of an ellipse, and a case where the figure is substantially a part of a catenary curve are also included in a case where “the figure is a part of a circle, is a part of a parabola, is a part of a sine curve, is substantially a part of an ellipse, or is substantially a part of a catenary curve”. A part of these curves may be replaced by a line segment.

More specifically, in the light emitting element 10H of Embodiment 22, the base surface 90 extends in a peripheral region 99, and the base surface 90 has an uneven shape and is differentiable in the light emitting elements 10A, 10B, and 10C described in Embodiments 1 to 4. That is, in the light emitting element 10H of Embodiment 22, the base surface 90 is analytically smooth. Note that the first light reflecting layer 41 is formed on the base surface 90 positioned on the first surface side of the first compound semiconductor layer 21, and the second light reflecting layer 42 is formed on the second surface side of the second compound semiconductor layer 22 and has a flat shape, similarly to the light emitting elements 10A, 10B, and 10C described in Embodiments 1 to 4.

In addition, the light emitting element array of Embodiment 22 includes a plurality of light emitting elements arranged, and each light emitting element is implemented by the light emitting element 10H of Embodiment 22 described above. Note that the base surface 90 extends in the peripheral region 99.

Then, the first portion 91′ of the base surface 90 on which the first light reflecting layer 41 is formed has an upward convex shape with respect to the second surface 21b of the first compound semiconductor layer 21, and the second portion 92′ of the base surface 90 occupying the peripheral region 99 has a downward convex shape with respect to the second surface 21b of the first compound semiconductor layer 21. A central portion 91_{c} of the first portion 91′ of the base surface 90 is positioned at a vertex (intersection portion) of a square lattice, or the central portion 91_{c} of the first portion 91′ of the base surface 90 is positioned at a vertex (intersection portion) of a regular triangle lattice.

Although the first light reflecting layer 41 is formed at the first portion 91′ of the base surface 90, in some cases, an extension portion of the first light reflecting layer 41 is formed at the second portion 92′ of the base surface 90 occupying the peripheral region 99, or the extension portion of the first light reflecting layer 41 is not formed at the second portion 92′. In Embodiment 22, the extension portion of the first light reflecting layer 41 is not formed at the second portion 92′ of the base surface 90 occupying the peripheral region 99.

Here, in the light emitting element 10H of Embodiment 22, a boundary 90_{bd} between the first portion 91′ and the second portion 92′ can be defined as:

(1) an outer peripheral portion of the first light reflecting layer 41 in a case where the first light reflecting layer 41 does not extend in the peripheral region 99, and

(2) a portion where an inflection point is present in the base surface 90 from the first portion 91′ to the second portion 92′ in a case where the first light reflecting layer 41 extends in the peripheral region 99. Here, the light emitting element 10H of Embodiment 22 specifically corresponds to (1) described in the light emitting element of the 8-A-th configuration.

Furthermore, in the light emitting element 10H of Embodiment 22, shapes of [the first portion 91′/second portion 92′ from the peripheral portion to the central portion] specifically corresponds to (A) described in the light emitting element of the 8-A-th configuration described above.

In the light emitting element 10H of Embodiment 22, the first surface 21a of the first compound semiconductor layer 21 constitutes the base surface 90. A figure drawn by the first portion 91′ of the base surface 90 in a case where the base surface 90 is cut along a virtual plane (for example, the XZ plane in the illustrated example) including the stacking direction of the stacked structure 20 is differentiable, and more specifically, can be a part of a circle, a part of a parabola, a sine curve, a part of an ellipse, or a part of a catenary curve, or a combination of these curves, or a part of these curves may be replaced with a line segment. A figure drawn by the second portion 92′ is also differentiable, and more specifically, can be a part of a circle, a part of a parabola, a part of a sine curve, a part of an ellipse, a part of a catenary curve, or a combination of these curves, or a part of these curves may be replaced with a line segment. Furthermore, the boundary between the first portion 91′ and the second portion 92′ of the base surface 90 is also differentiable.

As described above, in the light emitting element of Embodiment 22, since the base surface 90 has an uneven shape and is differentiable, in a case where a strong external force is applied to the light emitting element for some reason, it is possible to reliably avoid a problem that stress concentrates on the rising portion of the convex portion, and there is no possibility that the first compound semiconductor layer 21 or the like is damaged. In particular, the light emitting element array is connected to and bonded to an external circuit or the like using the bump, and it is necessary to apply a large load (for example, about 50 MPa) to the light emitting element array at the time of bonding. In the light emitting element array of Embodiment 22, even in a case where such a large load is applied, there is no possibility that the light emitting element array is damaged. In addition, since the base surface 90 has an uneven shape, generation of stray light is further suppressed, and occurrence of optical crosstalk between the light emitting elements can be more reliably prevented.

The configuration and structure of the light emitting element described in Embodiment 22 can also be applied to the light emitting elements described in Embodiments 6 to 21.

### Embodiment 23

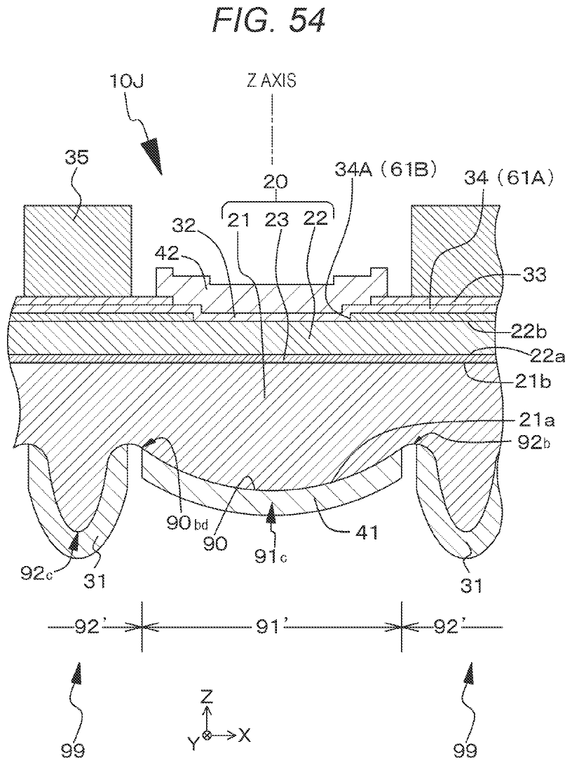

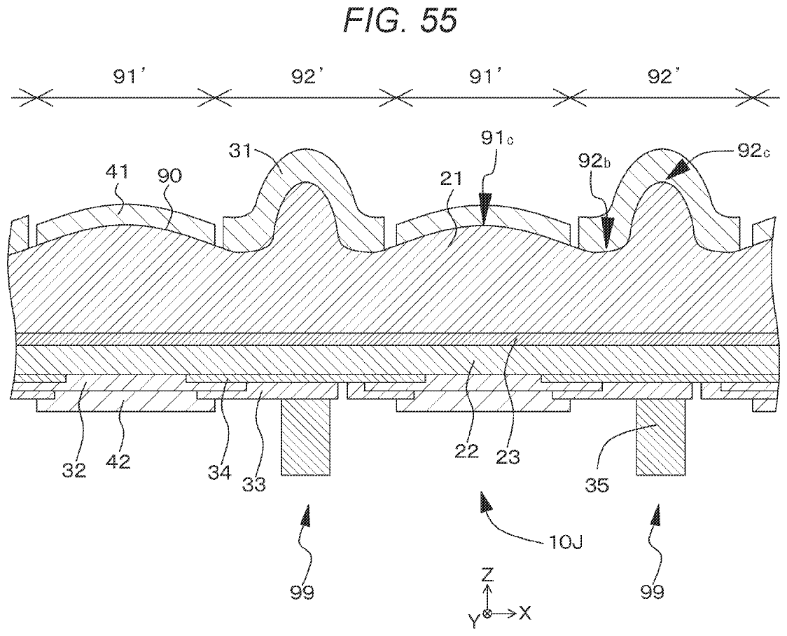

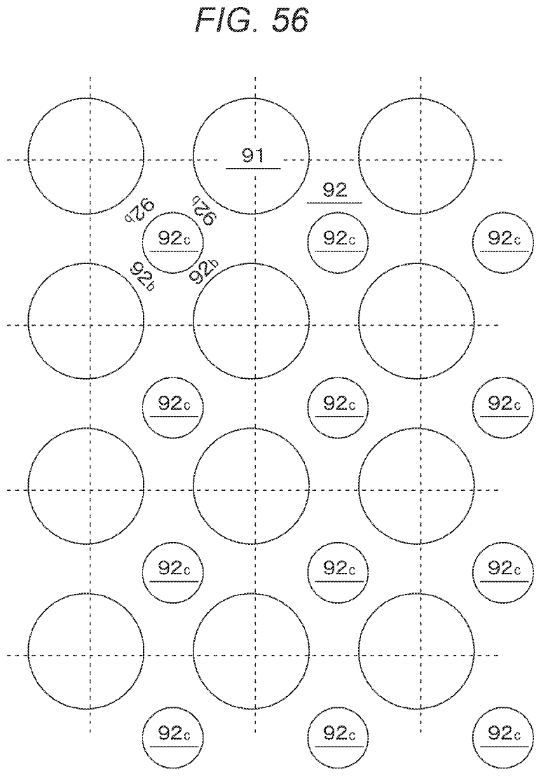

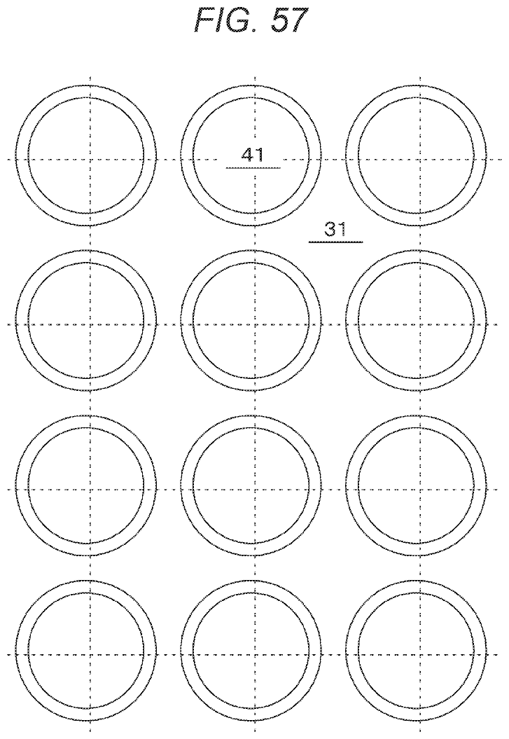

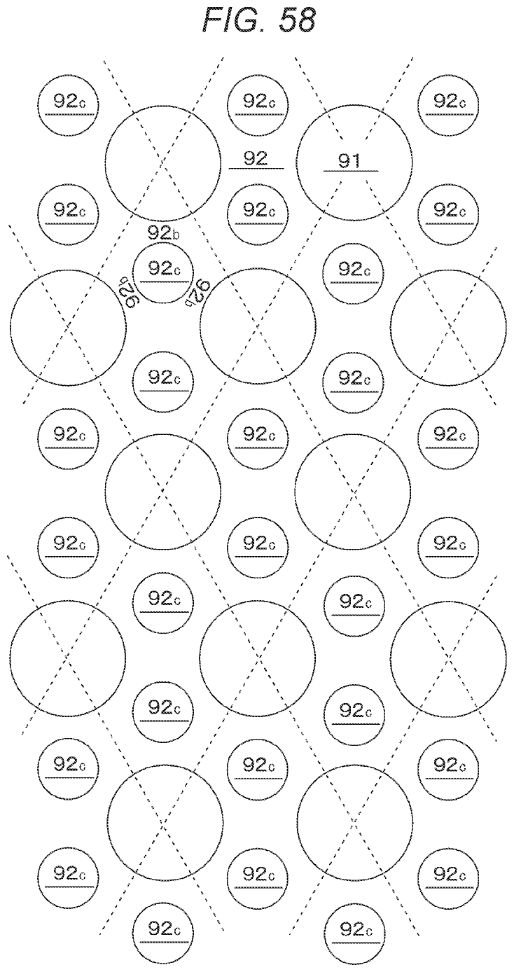

Embodiment 23 is a modification of Embodiment 22, and relates to the light emitting element of the 8-B-th configuration. FIG. 54 is a schematic partial end view of a light emitting element 10J of Embodiment 23, and FIG. 55 is a schematic partial end view of a light emitting element array of Embodiment 23. Furthermore, FIGS. 56 and 58 are schematic plan views illustrating disposition of the first portion 91′ and the second portion 92′ of the base surface 90 in the light emitting element array of Embodiment 23, and FIGS. 57 and 59 are schematic plan views illustrating disposition of the first light reflecting layer 41 and the first electrode in the light emitting element array of Embodiment 23.

In the light emitting element 10J of Embodiment 23, the second portion 92′ of the base surface 90 occupying the peripheral region 99 has a downward convex shape and an upward convex shape extending from the downward convex shape toward a central portion of the peripheral region 99 with respect to the second surface 21b of the first compound semiconductor layer 21. Then, LL₂>LL₁, where a distance from the second surface 21b of the first compound semiconductor layer 21 to the central portion 91_{c} of the first portion 91′ of the base surface 90 is LL₁, and a distance from the second surface 21b of the first compound semiconductor layer 21 to a central portion 92_{c} of the second portion 92′ of the base surface 90 is LL₂. Furthermore, R₁>R₂, where a radius of curvature (that is, a radius of curvature of the first light reflecting layer 41) of the central portion 91_{c} of the first portion 91′ of the base surface 90 is R₁, and a radius of curvature of the central portion 92_{c} of the second portion 92′ of the base surface 90 is R₂. Note that, although a value of LL₂/LL₁ is not limited, 1<LL₂/LL₁≤100 can be satisfied, and although a value of R₁/R₂ is not limited, 1<R₁/R₂≤100 can be satisfied. Specifically, for example, LL₂/LL1=1.05 and R₁/R₂=10.

In the light emitting element 10J of Embodiment 23, the central portion 91_{c} of the first portion 91′ of the base surface 90 is positioned at a vertex (intersection portion) of a square lattice (see FIG. 56), and in this case, the central portion 92_{c} (illustrated as a circle in FIG. 56) of the second portion 92′ of the base surface 90 is positioned at a vertex of the square lattice. Alternatively, the central portion 91_{c} of the first portion 91′ of the base surface 90 is positioned at a vertex (intersection portion) of a regular triangle lattice (see FIG. 58), and in this case, the central portion 92_{c} (illustrated as a circle in FIG. 58) of the second portion 92′ of the base surface 90 is positioned at a vertex of the regular triangle lattice. Further, the second portion 92′ of the base surface 90 occupying the peripheral region 99 has a downward convex shape toward the central portion of the peripheral region 99, and this region is denoted by Reference Sign 92b in FIGS. 56 and 58.

In the light emitting element 10J of Embodiment 23, shapes of [the first portion 91′/second portion 92′ from the peripheral portion to the central portion] specifically corresponds to (A) described in the light emitting element of the 8-B-th configuration described above.

In the light emitting element 10J of Embodiment 23, the bump 35 is arranged at a portion on the second surface side of the second compound semiconductor layer 22 facing a convex portion in the second portion 92′ of the base surface 90.

As illustrated in FIG. 54, the second electrode 32 is common to the light emitting elements 10J included in the light emitting element array, or is individually formed as illustrated in FIG. 55, and is connected to an external circuit or the like via the bump 35. The first electrode 31 is common to the light emitting elements 10J included in the light emitting element array, and is connected to an external circuit or the like via the first pad electrode (not illustrated). The bump 35 is formed at a portion on the second surface side of the second compound semiconductor layer 22 facing the convex portion 92_{c} in the second portion 92′ of the base surface 90. In the light emitting element 10J illustrated in FIGS. 54, 55A, and 55B, light may be emitted to the outside via the first light reflecting layer 41, or light may be emitted to the outside via the second light reflecting layer 42. Examples of a shape of the bump 35 can include a cylindrical shape, an annular shape, and a hemispherical shape.

In addition, it is desirable that the radius R₂ of curvature of the central portion 92_{c} of the second portion 92′ of the base surface 90 is 1×10⁻⁶ m or more, preferably, 3×10⁻⁶ m or more, and more preferably, 5×10⁻⁶ m or more, and specifically, the radius of curvature R₂=3 μm.

### Embodiment 24

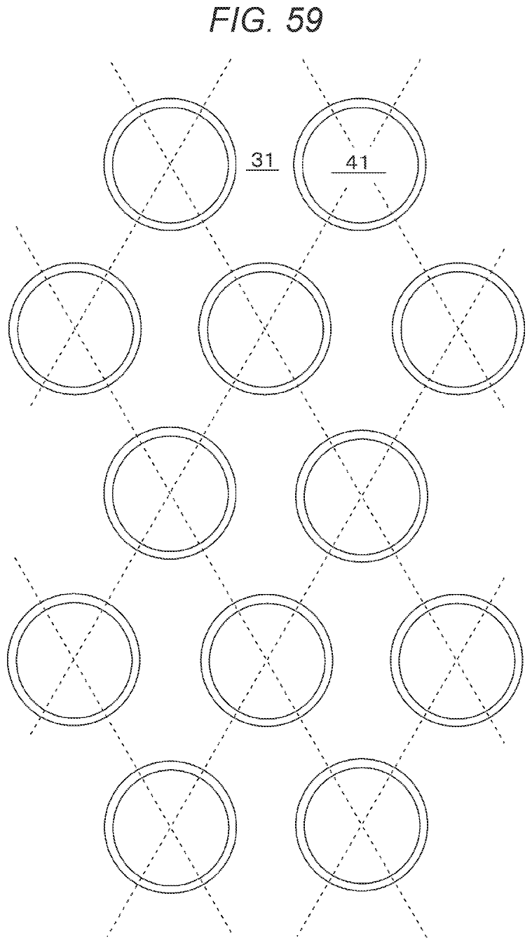

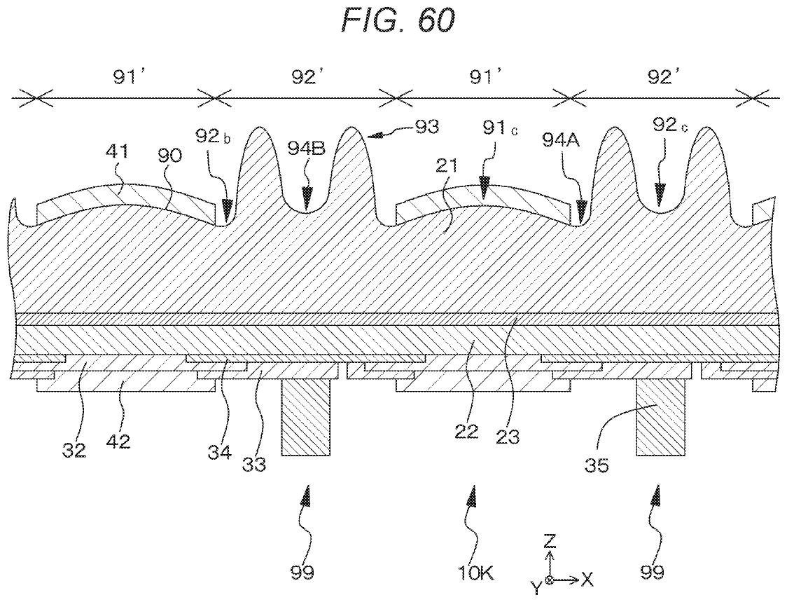

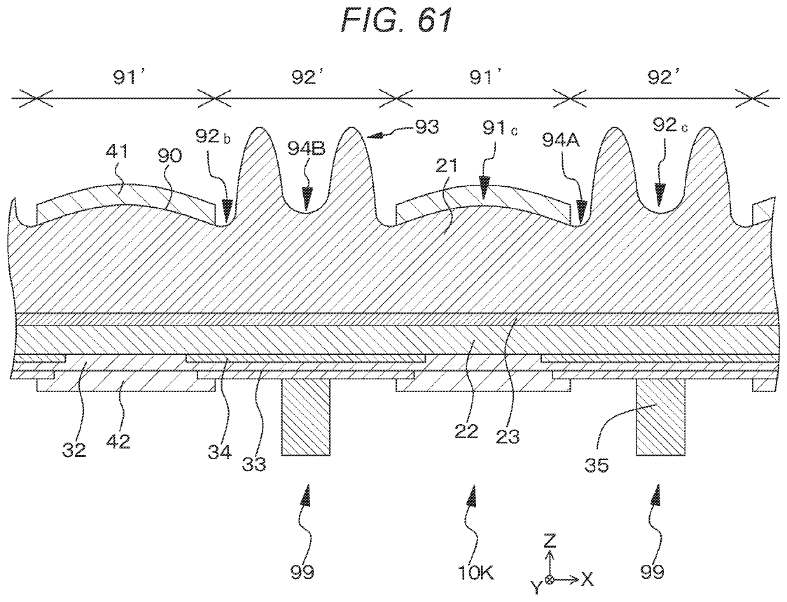

Embodiment 24 is also a modification of Embodiment 22 or Embodiment 23, and relates to the light emitting element of the 8-C-th configuration. FIGS. 60 and 61 are schematic partial end views of the light emitting element array of Embodiment 24, and FIG. 62 is a schematic plan view illustrating disposition of the first portion 91′ and the second portion 92′ of the base surface 90 in the light emitting element array of Embodiment 24. Note that, in the example illustrated in FIG. 60, the second electrode 32 is individually formed in each light emitting element, and in the example illustrated in FIG. 61, the second electrode 32 is formed common to the respective light emitting elements. Furthermore, in FIGS. 60 and 61, illustration of the first electrode is omitted.

In a light emitting element 10K of Embodiment 24, the second portion 92′ of the base surface 90 occupying the peripheral region 99 has an annular convex shape 93 surrounding the first portion 91′ of the base surface 90 and a downward convex shape 94A extending from the annular convex shape 93 toward the first portion 91′ of the base surface 90 with respect to the second surface 21b of the first compound semiconductor layer 21. A region surrounded by the annular convex shape 93 in the second portion 92′ of the base surface 90 occupying the peripheral region 99 is denoted by Reference Sign 94B.

In the light emitting element 10K of Embodiment 24, LL₂′>LL₁, where a distance from the second surface 21b of the first compound semiconductor layer 21 to the central portion 91_{c} of the first portion 91′ of the base surface 90 is LL₁, and a distance from the second surface 21b of the first compound semiconductor layer 21 to a top portion of the annular convex shape 93 of the second portion 92′ of the base surface 90 is LL₂′. Furthermore, R₁>R₂′, where a radius of curvature (that is, a radius of curvature of the first light reflecting layer 41) of the central portion 91_{c} of the first portion 91′ of the base surface 90 is R₁, and a radius of curvature of the top portion of the annular convex shape 93 of the second portion 92′ of the base surface 90 is R₂′. Note that although a value of LL₂′/LL₁ is not limited, 1<LL₂′/LL₁≤100 can be satisfied, and specifically, for example, LL₂′/LL₁=1.1. In addition, although a value of R₁/R₂′ is not limited, 1<R₁/R₂′≤100 can be satisfied, and specifically, for example, R₁/R₂′=50.

In the light emitting element 10K of Embodiment 24, shapes of [the first portion 91′/second portion 92′ from the peripheral portion to the central portion] specifically corresponds to (A) described in the light emitting element of the 8-C-th configuration described above.

Furthermore, in the light emitting element 10K of Embodiment 24, the bump 35 is arranged at a portion on the second surface side of the second compound semiconductor layer 22 facing the annular convex portion 93 in the second portion 92′ of the base surface 90. A shape of the bump 35 is preferably an annular shape facing the annular convex shape 93. A cylindrical shape, an annular shape, and a hemispherical shape can be exemplified. The bump 35 is formed at a portion on the second surface side of the second compound semiconductor layer 22 facing the convex portion 92_{c} in the second portion 92′ of the base surface 90.

As illustrated in FIG. 60, the second electrode 32 is individually formed in the light emitting element 10K included in the light emitting element array, and is connected to an external circuit or the like via the bump 35. The first electrode 31 is common to the light emitting elements 10K included in the light emitting element array, and is connected to an external circuit or the like via the first pad electrode (not illustrated). Alternatively, as illustrated in FIG. 61, the second electrode 32 is common to the light emitting elements 10K included in the light emitting element array, and is connected to an external circuit or the like via the bump 35. The first electrode 31 is common to the light emitting elements 10K included in the light emitting element array, and is connected to an external circuit or the like via the first pad electrode (not illustrated). In the light emitting element 10K illustrated in FIGS. 60 and 61, light may be emitted to the outside via the first light reflecting layer 41, or light may be emitted to the outside via the second light reflecting layer 42.

Although the present disclosure has been described above on the basis of preferred embodiments, the present disclosure is not limited to these embodiments. The configurations and structures of the light emitting elements described in the embodiments are examples, and can be appropriately changed, and the method for manufacturing the light emitting element can also be appropriately changed. In some cases, by appropriately selecting the bonding layer and the support substrate, a surface emitting laser element that emits light from the second surface of the second compound semiconductor layer via the second light reflecting layer can be obtained. In some cases, a through hole reaching the first compound semiconductor layer can be formed in a region of the second compound semiconductor layer and the active layer that do not affect light emission, and the first electrode insulated from the second compound semiconductor layer and the active layer can be formed in the through hole. The first light reflecting layer may extend to the second region of the base surface. That is, the first light reflecting layer on the base surface may be formed using a so-called solid film. Then, in this case, it is sufficient if a through hole is formed in the first light reflecting layer extending to the second region of the base surface, and the first electrode connected to the first compound semiconductor layer is formed in the through hole.

Note that the present disclosure can also have the following configuration.

[A01]<<Method for manufacturing light emitting element . . . first aspect>>

A method for manufacturing a light emitting element which includes a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked, a first light reflecting layer, and a second light reflecting layer formed on a second surface side of the second compound semiconductor layer and having a flat shape, and in which a base surface positioned on a first surface side of the first compound semiconductor layer has a protrusion protruding in a direction away from the active layer, and a cross-sectional shape of the protrusion in a case where the base surface is cut along a virtual plane including a stacking direction of the stacked structure includes a smooth curve,

the method including:

forming the second light reflecting layer on the second surface side of the second compound semiconductor layer after forming the stacked structure;

forming a first sacrificial layer on the base surface on which the protrusion is to be formed;

forming a second sacrificial layer on the entire surface and then performing etching back from the base surface inward by using the second sacrificial layer and the first sacrificial layer as etching masks; and

forming the first light reflecting layer on at least the protrusion.

[A02] The method according to [A01], in which in the forming of the second sacrificial layer on the entire surface, formation of the second sacrificial layer is performed a plurality of times.
[A03]<<Method for manufacturing light emitting element . . . Second Aspect>>

A method for manufacturing a light emitting element which includes a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked, a first light reflecting layer, and a second light reflecting layer formed on a second surface side of the second compound semiconductor layer and having a flat shape, and in which a base surface positioned on a first surface side of the first compound semiconductor layer has a protrusion protruding in a direction away from the active layer, and a cross-sectional shape of the protrusion in a case where the base surface is cut along a virtual plane including a stacking direction of the stacked structure includes a smooth curve,

the method including:

forming the second light reflecting layer on the second surface side of the second compound semiconductor layer after forming the stacked structure;

forming a first layer on a portion of the base surface on which the protrusion is to be formed;

forming a second layer covering the first layer to form the protrusion constituted by the first layer and the second layer covering the first layer on the base surface; and

forming the first light reflecting layer on at least the protrusion.

[A04] The method according to [A03], in which in the forming of the second layer on the entire surface, formation of the second layer is performed a plurality of times.

### [B01]<<Light Emitting Element . . . First Aspect>>

A light emitting element including:

a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked;

a first light reflecting layer; and

a second light reflecting layer formed on a second surface side of the second compound semiconductor layer and having a flat shape,

in which a base surface positioned on a first surface side of the first compound semiconductor layer has a protrusion protruding in a direction away from the active layer,

a cross-sectional shape of the protrusion in a case where the base surface is cut along a virtual plane including a stacking direction of the stacked structure includes a smooth curve,

the first light reflecting layer is formed on at least the protrusion, and

2×10⁻⁶ m≤D₁≤2.5×10⁻⁵ m,

1×10⁻⁸ m≤H₁≤5×10⁻⁷ m,

1×10⁻⁴ m≤R₁, and

Ra_{Pj}≤1.0 nm, where a diameter of the protrusion is D₁, a height of the protrusion is H₁, a radius of curvature of a top portion of the protrusion is R₁, a surface roughness of the protrusion is Ra_{Pj}, and a resonator length of the light emitting element is L_{OR}
[B02]<<Light emitting element . . . Second aspect>>

A light emitting element including:

a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked;

a first light reflecting layer; and

a second light reflecting layer formed on a second surface side of the second compound semiconductor layer and having a flat shape,

in which a base surface positioned on a first surface side of the first compound semiconductor layer has a protrusion protruding in a direction away from the active layer,

a cross-sectional shape of the protrusion in a case where the base surface is cut along a virtual plane including a stacking direction of the stacked structure includes a smooth curve,

the first light reflecting layer is formed on at least the protrusion, and

2×10⁻³ m≤D₁

1×10⁻³ m≤R₁, and

Ra_{Pj}≤1.0 nm, where a diameter of the protrusion is D₁, a height of the protrusion is H₁, a radius of curvature of a top portion of the protrusion is R₁, a surface roughness of the protrusion is Ra_{Pj}, and a resonator length of the light emitting element is L_{OR}
[B03]<<Light emitting element . . . Third aspect>>

A light emitting element including:

a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked;

a first light reflecting layer; and

a second light reflecting layer formed on a second surface side of the second compound semiconductor layer and having a flat shape,

in which a base surface positioned on a first surface side of the first compound semiconductor layer has a protrusion protruding in a direction away from the active layer,

the protrusion is constituted by a first layer and a second layer covering the first layer,

a cross-sectional shape of the protrusion in a case where the base surface is cut along a virtual plane including a stacking direction of the stacked structure includes a smooth curve, and

the first light reflecting layer is formed on at least the protrusion.

[B04] The light emitting element according to any one of [B01] to [B03], in which a wavelength conversion material layer is provided in a region of the light emitting element where light is emitted.
[B05] The light emitting element according to [B04], in which white light is emitted via the wavelength conversion material layer.
[B06] The light emitting element according to any one of [B01] to [B05], in which the stacked structure is formed using at least one material selected from the group consisting of a GaN-based compound semiconductor, an InP-based compound semiconductor, and a GaAs-based compound semiconductor.
[B07] The light emitting element according to any one of [B01] to [B06], in which a value of a thermal conductivity of the stacked structure is higher than a value of a thermal conductivity of the first light reflecting layer.
[C01]<<First configuration>>

The light emitting element according to any one of [B01] to [B07], in which the first surface of the first compound semiconductor layer constitutes the base surface.

[C02]<<Light emitting element of second configuration>>

The light emitting element according to any one of [B01] to [B07], in which a compound semiconductor substrate is disposed between the first surface of the first compound semiconductor layer and the first light reflecting layer, and the base surface is constituted by a surface of the compound semiconductor substrate.

[C03]<<Light emitting element of third configuration>>

The light emitting element according to any one of [B01] to [B07], in which a base material is disposed between the first surface of the first compound semiconductor layer and the first light reflecting layer, or a compound semiconductor substrate and the base material are disposed between the first surface of the first compound semiconductor layer and the first light reflecting layer, and the base surface is constituted by a surface of the base material.

[C04] The light emitting element according to [C03], in which a material of the base material is at least one kind of material selected from the group consisting of a transparent dielectric material such as TiO₂, Ta₂O₅, or SiO₂, a silicone-based resin, and an epoxy-based resin.
[D01]<<Light emitting element array of fourth configuration>>

The light emitting element according to any one of [B01] to [C04], in which a current injection region and a current non-injection region surrounding the current injection region are provided in the second compound semiconductor layer, and

the shortest distance D_{CI} from an area center point of the current injection region to a boundary between the current injection region and the current non-injection region satisfies the following formula:

D_{CI}≥ω₀/2

provided that

ω₀²≡(λ₀/π){L_{OR}(R₁−L_{OR})}^{1/2}

where

λ₀: a desired wavelength of light mainly emitted from the light emitting element (oscillation wavelength)

L_{OR}: the resonator length

R₁: a radius of curvature of a top portion (central portion) of a first region of the base surface (that is, the radius of curvature of the first light reflecting layer).

[D02] The light emitting element according to [D01], further including:

a mode loss acting portion provided on the second surface of the second compound semiconductor layer and constituting a mode loss acting region acting on an increase or decrease in oscillation mode loss;

a second electrode formed on the second surface of the second compound semiconductor layer and on the mode loss acting portion; and

a first electrode electrically connected to the first compound semiconductor layer,

in which the second light reflecting layer is formed on the second electrode,

the current injection region, a current non-injection/inner region surrounding the current injection region, and a current non-injection/outer region surrounding the current non-injection/inner region are formed in the stacked structure, and

an orthogonal projection image of the mode loss acting region and an orthogonal projection image of the current non-injection/outer region overlap each other.

[D03] The light emitting element according to [D01] or [D02], in which a radius r₁ of the first region satisfies ω₀≤r₁≤20·ω₀.
[D04] The light emitting element according to any one of [D01] to [D03], in which D_{CI}≥ω₀.
[E01]<<Light emitting element array of fifth configuration>>

The light emitting element according to any one of [B01] to [C04], further including:

a mode loss acting portion provided on the second surface of the second compound semiconductor layer and constituting a mode loss acting region acting on an increase or decrease in oscillation mode loss;

a second electrode formed on the second surface of the second compound semiconductor layer and on the mode loss acting portion; and

a first electrode electrically connected to the first compound semiconductor layer,

in which the second light reflecting layer is formed on the second electrode,

a current injection region, a current non-injection/inner region surrounding the current injection region, and a current non-injection/outer region surrounding the current non-injection/inner region are formed in the stacked structure, and

an orthogonal projection image of the mode loss acting region and an orthogonal projection image of the current non-injection/outer region overlap each other.

[E02] The light emitting element according to [E01], in which the current non-injection/outer region is positioned below the mode loss acting region.
[E03] The light emitting element according to [E01] or [E02], in which 0.01≤S₁/(S₁+S₂)≤0.7, where an area of an orthogonal projection image of the current injection region is Si and an area of an orthogonal projection image of the current non-injection/inner region is S₂.
[E04] The light emitting element according to any one of [E01] to [E03], in which the current non-injection/inner region and the current non-injection/outer region are formed by ion implantation into the stacked structure.
[E05] The light emitting element according to [E04], in which an ion type is at least one type of ion selected from the group consisting of boron, proton, phosphorus, arsenic, carbon, nitrogen, fluorine, oxygen, germanium, and silicon.
[E06]<<Light emitting element array of 5-B-th configuration>>

The light emitting element according to any one of [E01] to [E05], in which the current non-injection/inner region and the current non-injection/outer region are formed by plasma irradiation on the second surface of the second compound semiconductor layer, asking treatment on the second surface of the second compound semiconductor layer, or reactive ion etching treatment on the second surface of the second compound semiconductor layer.

[E07]<<Light emitting element array of 5-C-th configuration>>

The light emitting element according to any one of [E01] to [E06], in which the second light reflecting layer has a region that reflects or scatters light from the first light reflecting layer toward the outside of a resonator structure including the first light reflecting layer and the second light reflecting layer.

[E08] The light emitting element according to any one of [E01] to [E07], in which OL₀>OL₂, where an optical distance from the active layer to the second surface of the second compound semiconductor layer in the current injection region is OL₂, and an optical distance from the active layer to a top surface of the mode loss acting portion in the mode loss acting region is OL₀.
[E09] The light emitting element according to any one of [E01] to [E08], in which generated light having a higher-order mode is scattered toward the outside of the resonator structure including the first light reflecting layer and the second light reflecting layer and lost by the mode loss acting region, such that the oscillation mode loss increases.
[E10] The light emitting element according to any one of [E01] to [E09], in which the mode loss acting portion is formed using a dielectric material, a metal material, or an alloy material.
[E11] The light emitting element according to [E10], in which the mode loss acting portion is formed using the dielectric material, and

an optical thickness of the mode loss acting portion is a value deviating from an integral multiple of ¼ of a wavelength of light generated in the light emitting element array.

[E12] The light emitting element according to [E10], in which the mode loss acting portion is formed using the dielectric material, and

an optical thickness of the mode loss acting portion is an integral multiple of ¼ of a wavelength of light generated in the light emitting element array.

[E13]<<Light emitting element array of 5-D-th configuration>>

The light emitting element according to any one of [E01] to [E03], in which a convex portion is formed on the second surface side of the second compound semiconductor layer, and

the mode loss acting portion is formed on a region of the second surface of the second compound semiconductor layer surrounding the convex portion.

[E14] The light emitting element according to [E13], in which OL₀<OL₂, where an optical distance from the active layer to the second surface of the second compound semiconductor layer in the current injection region is OL₂, and an optical distance from the active layer to a top surface of the mode loss acting portion in the mode loss acting region is OL₀.
[E15] The light emitting element according to [E13] or [E14], in which generated light having a higher-order mode is confined in the current injection region and the current non-injection/inner region by the mode loss acting region, such that the oscillation mode loss decreases.
[E16] The light emitting element according to any one of [E13] to [E15], in which the mode loss acting portion is formed using a dielectric material, a metal material, or an alloy material.
[E17] The light emitting element according to any one of [E01] to [E16], in which the second electrode is formed using a transparent conductive material.
[F01]<<Light emitting element array of sixth configuration>>

The light emitting element according to any one of [B01] to [C04], further including:

a second electrode formed on the second surface of the second compound semiconductor layer;

the second light reflecting layer formed on the second electrode;

a mode loss acting portion provided on the first surface of the first compound semiconductor layer and constituting a mode loss acting region acting on an increase or decrease in oscillation mode loss; and

a first electrode electrically connected to the first compound semiconductor layer,

in which the first light reflecting layer is formed on the first surface of the first compound semiconductor layer and on the mode loss acting portion,

a current injection region, a current non-injection/inner region surrounding the current injection region, and a current non-injection/outer region surrounding the current non-injection/inner region are formed in the stacked structure, and

an orthogonal projection image of the mode loss acting region and an orthogonal projection image of the current non-injection/outer region overlap each other.

[F02] The light emitting element according to [F01], in which 0.01≤S₁′/(S₁′+S₂′)≤0.7, where an area of an orthogonal projection image of the current injection region is S₁′ and an area of an orthogonal projection image of the current non-injection/inner region is S₂′.
[F03]<<Light emitting element array of 6-A-th configuration>>

The light emitting element according to [F01] or [F02], in which the current non-injection/inner region and the current non-injection/outer region are formed by ion implantation into the stacked structure.

[F04] The light emitting element according to [F03], in which an ion type is at least one type of ion selected from the group consisting of boron, proton, phosphorus, arsenic, carbon, nitrogen, fluorine, oxygen, germanium, and silicon.
[F05]<<Light emitting element array of 6-B-th configuration>>

The light emitting element according to any one of [F01] to [F04], in which the current non-injection/inner region and the current non-injection/outer region are formed by plasma irradiation on the second surface of the second compound semiconductor layer, asking treatment on the second surface of the second compound semiconductor layer, or reactive ion etching treatment on the second surface of the second compound semiconductor layer.

[F06]<<Light emitting element array of 6-C-th configuration>>

The light emitting element according to any one of [F01] to [F05], in which the second light reflecting layer has a region that reflects or scatters light from the first light reflecting layer toward the outside of a resonator structure including the first light reflecting layer and the second light reflecting layer.

[F07] The light emitting element according to any one of [F01] to [F06], in which OL₀′>OL₁′, where an optical distance from the active layer to the first surface of the first compound semiconductor layer in the current injection region is OL₁′, and an optical distance from the active layer to a top surface of the mode loss acting portion in the mode loss acting region is OL₀′.
[F08] The light emitting element according to any one of [F01] to [F07], in which generated light having a higher-order mode is scattered toward the outside of the resonator structure including the first light reflecting layer and the second light reflecting layer and lost by the mode loss acting region, such that the oscillation mode loss increases.
[F09] The light emitting element according to any one of [F01] to [F08], in which the mode loss acting portion is formed using a dielectric material, a metal material, or an alloy material.
[F10] The light emitting element according to [F09], in which the mode loss acting portion is formed using the dielectric material, and

an optical thickness of the mode loss acting portion is a value deviating from an integral multiple of ¼ of a wavelength of light generated in the light emitting element array.

[F11] The light emitting element according to [F09], in which the mode loss acting portion is formed using the dielectric material, and

an optical thickness of the mode loss acting portion is an integral multiple of ¼ of a wavelength of light generated in the light emitting element array.

[F12]<<Light emitting element array of 6-D-th configuration>>

The light emitting element according to [F01] or [F02], in which a convex portion is formed on the first surface side of the first compound semiconductor layer, and

the mode loss acting portion is formed on a region of the first surface of the first compound semiconductor layer surrounding the convex portion.

[F13] The light emitting element according to [F12], in which OL₀′<OL₁′, where an optical distance from the active layer to the first surface of the first compound semiconductor layer in the current injection region is OL₁′, and an optical distance from the active layer to a top surface of the mode loss acting portion in the mode loss acting region is OL₀′.
[F14] The light emitting element according to [F01] or [F02], in which a convex portion is formed on the first surface side of the first compound semiconductor layer, and

the mode loss acting portion is formed on a region of the first surface of the first compound semiconductor layer surrounding the convex portion.

[F15] The light emitting element according to any one of [F12] to [F14], in which generated light having a higher-order mode is confined in the current injection region and the current non-injection/inner region by the mode loss acting region, such that the oscillation mode loss decreases.
[F16] The light emitting element according to any one of [F12] to [F15], in which the mode loss acting portion is formed using a dielectric material, a metal material, or an alloy material.
[F17] The light emitting element according to any one of [F01] to [F16], in which the second electrode is formed using a transparent conductive material.
[G01]<<Light emitting element array of seventh configuration>>

The light emitting element according to any one of [B01] to [F17], in which at least two light absorbing material layers are formed in the stacked structure including the second electrode in parallel with a virtual plane occupied by the active layer.

[G02] The light emitting element according to [G01], in which at least four light absorbing material layers are formed.
[G03] The light emitting element according to [G01] or [G02], in which 0.9×{(m·λ₀)/(2·n_{eq}}≤L_{Abs}≤1.1×{(m·λ₀)/(2·n_{eq})}, where the oscillation wavelength is λ₀, an equivalent refractive index of the whole of two light absorbing material layers and a portion of the stacked structure positioned between the light absorbing material layers is n_{eq}, and a distance between the light absorbing material layers is L_{Abs}, m being 1 or an arbitrary integer of 2 or more including 1.
[G04] The light emitting element according to any one of [G01] to [G03], in which a thickness of the light absorbing material layer is λ₀/(4·n_{eq}) or less.
[G05] The light emitting element according to any one of [G01] to [G04], in which the light absorbing material layer is positioned at a minimum amplitude portion generated in a standing wave of light formed inside the stacked structure.
[G06] The light emitting element according to any one of [G01] to [G05], in which the active layer is positioned at a maximum amplitude portion generated in a standing wave of light formed inside the stacked structure.
[G07] The light emitting element according to any one of [G01] to [G06], in which the light absorbing material layer has a light absorption coefficient that is twice or more the light absorption coefficient of a compound semiconductor constituting the stacked structure.
[G08] The light emitting element according to any one of [G01] to [G07], in which the light absorbing material layer is formed using at least one material selected from the group consisting of a compound semiconductor material having a narrower band gap than the compound semiconductor constituting the stacked structure, a compound semiconductor material doped with impurities, a transparent conductive material, and a light reflecting layer constituting material having a light absorption characteristic.
[H01] The light emitting element according to any one of [B01] to [G07], in which a partition wall extending in the stacking direction of the stacked structure is formed so as to surround the first light reflecting layer.
[H02] The light emitting element according to [H01], in which the partition wall extends from the first surface side of the first compound semiconductor layer to the middle of the first compound semiconductor layer in a thickness direction in the first compound semiconductor layer.
[H03] The light emitting element according to [H01], in which the partition wall extends from the second surface side of the second compound semiconductor layer in the second compound semiconductor layer and the active layer, and further extends to the middle of the first compound semiconductor layer in a thickness direction in the first compound semiconductor layer.
[H04] The light emitting element according to any one of [H01] to [H03], in which the partition wall is formed using a material that does not transmit light generated in the active layer.
[H05] The light emitting element according to any one of [H01] to [H03], in which the partition wall is formed using a material that reflects light generated in the active layer.
[H06] The light emitting element according to any one of [H01] to [H03], in which 1×10⁻¹≤TC₁/TC₀≤1×10², where a thermal conductivity of a material of the first compound semiconductor layer is TC₁, and a thermal conductivity of a material of the partition wall is TC₀.
[H07] The light emitting element according to any one of [H01] to [H03], in which |CTE₀−CTE₁|≤1×10⁻⁴/K, where a linear expansivity of a material of the first compound semiconductor layer is CTE₁, and a linear expansivity of a material of the partition wall is CTE₀.
[H08] The light emitting element according to any one of [H01] to [H03], in which the partition wall is formed using a solder material, and a portion of the partition wall is exposed at an outer surface of the light emitting element.
[H09] The light emitting element according to any one of [H01] to [H08], in which a side surface of the partition wall is narrowed in a direction from the first surface side of the first compound semiconductor layer toward the second surface side of the second compound semiconductor layer.
[H10] The light emitting element according to any one of [H01] to [H09], in which the first light reflecting layer is formed on the base surface positioned on the first surface side of the first compound semiconductor layer,

the base surface extends in a peripheral region, and

the base surface is uneven and differentiable.

[J01] The light emitting element according to any one of [B01] to [H10], in which the base surface positioned on the first surface side of the first compound semiconductor layer has a first region including the protrusion protruding in a direction away from the active layer, and a second region surrounding the first region and having a flat surface,

the first region includes a 1-A-th region including the top portion of the protrusion and a 1-B-th region surrounding the 1-A-th region,

the first light reflecting layer is formed on at least the 1-A-th region,

a first curve formed by the 1-A-th region in a cross-sectional shape of the base surface in a case where the base surface is cut along a virtual plane including the stacking direction of the stacked structure includes an upward convex smooth curve,

a supplementary angle θ_{CA} of an angle formed by a second curve formed by the 1-B-th region and a straight line formed by the second region in the cross-sectional shape of the base surface at an intersection of the second curve and the straight line has a value exceeding 0 degrees, and

the second curve includes at least one kind of figure selected from the group consisting of a downward convex curve, a line segment, and a combination of arbitrary curves.

[J02] The light emitting element according to [J01], in which the supplementary angle θ_{CA} is 1 degree or more and 6 degrees or less.
[J03] The light emitting element according to any one of [B01] to [H10], in which the base surface positioned on the first surface side of the first compound semiconductor layer has a first region including the protrusion protruding in a direction away from the active layer, and a second region surrounding the first region and having a flat surface,

the first light reflecting layer is formed on at least a top portion of the first region, and

a supplementary angle θ_{CA} of an angle formed by a curve formed by the first region and a straight line formed by the second region in a cross-sectional shape of the base surface in a case where the base surface is cut along a virtual plane including the stacking direction of the stacked structure at an intersection of the curve and the straight line is 1 degree or more and 6 degrees or less.

[K01] The light emitting element according to any one of [B01] to [H10], in which the first light reflecting layer is formed on the base surface positioned on the first surface side of the first compound semiconductor layer,

the base surface extends in the peripheral region, and

the base surface is uneven and differentiable.

[L01]<<Light emitting element array>>

A light emitting element array including a plurality of light emitting elements,

in which each light emitting element includes:

a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked;

a first light reflecting layer; and

a second light reflecting layer formed on a second surface side of the second compound semiconductor layer and having a flat shape,

a base surface positioned on a first surface side of the first compound semiconductor layer has a protrusion protruding in a direction away from the active layer,

a cross-sectional shape of the protrusion in a case where the base surface is cut along a virtual plane including a stacking direction of the stacked structure includes a smooth curve,

the first light reflecting layer is formed on at least the protrusion,

2×10⁻⁶ m≤D₁≤2.5×10⁻⁵ m,

1×10⁻⁸ m≤H₁≤5×10⁻⁷ m,

1×10⁻⁴ m≤R₁, and

Ra_{Pj} 1.0 nm, where a diameter of the protrusion is D₁, a height of the protrusion is H₁, a radius of curvature of a top portion of the protrusion is R₁, a surface roughness of the protrusion is Ra_{Pj}, and a resonator length of the light emitting element is L_{OR}, and

a formation pitch P₀ of the light emitting elements is 3×10⁻⁵m or less.

[L02] The light emitting element array according to [L01], in which in each light emitting element, a partition wall extending in the stacking direction of the stacked structure is formed so as to surround the first light reflecting layer.
[L03] The light emitting element array according to [L02], in which in each light emitting element, the partition wall extends from the first surface side of the first compound semiconductor layer to the middle of the first compound semiconductor layer in a thickness direction in the first compound semiconductor layer.
[L04] The light emitting element array according to [BOX], in which a relationship between L₀, Li, and L₃ satisfies the following Formula (1), preferably, Formula (1′), satisfies the following Formula (2), preferably, Formula (2′), satisfies the following Formulas (1) and (2), or satisfies the following Formulas (1′) and (2′):

0.01×L₀≤L₀−L₁ (1)

0.05×L₀≤L₀−L₁ (1′)

0.01×L₃≤L₁ (2)

0.05×L₃≤L₁ (2′)

where

L₀: a distance from an end portion of a facing surface of the first light reflecting layer that faces the first surface of the first compound semiconductor layer to the active layer,

L₁: a distance from the active layer to an end portion (an upper end portion of the partition wall and an end portion facing the active layer) of the partition wall extending to the middle of the first compound semiconductor layer in the thickness direction in the first compound semiconductor layer, and

L₃: a distance from an axial line of the first light reflecting layer included in the light emitting element to an orthogonal projection image of the partition wall on the stacked structure (more specifically, an orthogonal projection image of the upper end portion of the partition wall).

[L05] The light emitting element array according to [L02], in which in each light emitting element, the partition wall extends from the second surface side of the second compound semiconductor layer in the second compound semiconductor layer and the active layer, and further extends to the middle of the first compound semiconductor layer in the thickness direction in the first compound semiconductor layer.
[L06] The light emitting element array according to [L05], in which a relationship between L₀, L₂, and L₃′ satisfies the following Formula (3), preferably, Formula (3′), satisfies the following Formula (4), preferably, Formula (4′), satisfies the following Formulas (3) and (4), or satisfies the following Formulas (3′) and (4′):

0.01×L₀≤L₂ (3)

0.05×L₀≤L₂ (3′)

0.01×L₃′≤L₂ (4)

0.05×L₃′≤L₂ (4′)

where

L₀: a distance from an end portion of a facing surface of the first light reflecting layer that faces the first surface of the first compound semiconductor layer to the active layer,

L₂: a distance from the active layer to an end portion (a lower end portion of the partition wall and an end portion facing a first electrode) of the partition wall extending to the middle of the first compound semiconductor layer in the thickness direction in the first compound semiconductor layer, and

L₃′: a distance from an axial line of the first light reflecting layer included in the light emitting element to an orthogonal projection image of the partition wall on the stacked structure (more specifically, an orthogonal projection image of the lower end portion of the partition wall).

[M01] The light emitting element array according to any one of [L01] to [L06], in which the first light reflecting layer is formed on the base surface positioned on the first surface side of the first compound semiconductor layer,

the base surface extends in a peripheral region surrounded by the plurality of light emitting elements, and

the base surface is uneven and differentiable.

[M02] The light emitting element array according to [M01], in which the base surface is smooth.
[M03]<<Light emitting element of eighth configuration>>

The light emitting element array according to [M01] or [M02], in which a first portion of the base surface on which the first light reflecting layer is formed has an upward convex shape with respect to the second surface of the first compound semiconductor layer.

[M04]<<Light emitting element of 8-A-th configuration>>

The light emitting element array according to [M03], in which a second portion of the base surface occupying the peripheral region has a downward convex shape with respect to the second surface of the first compound semiconductor layer.

[M05] The light emitting element array according to [M04], in which a central portion of the first portion of the base surface is positioned at a vertex (intersection portion) of a square lattice.
[M06] The light emitting element array according to [M04], in which a central portion of the first portion of the base surface is positioned at a vertex (intersection portion) of a regular triangle lattice.
[M07]<<Light emitting element of 8-B-th configuration>>

The light emitting element array according to [M03], in which a second portion of the base surface occupying the peripheral region has a downward convex shape and an upward convex shape extending from the downward convex shape toward a central portion of the peripheral region with respect to the second surface of the first compound semiconductor layer.

[M08] The light emitting element array according to [M07], in which LL₂>LL₁, where a distance from the second surface of the first compound semiconductor layer to a central portion of the first portion of the base surface is LL₁, and a distance from the second surface of the first compound semiconductor layer to a central portion of the second portion of the base surface is LL₂.
[M09] The light emitting element array according to [M07] or [M08], in which R₁>R₂, where a radius of curvature (that is, a radius of curvature of the first light reflecting layer) of the central portion of the first portion of the base surface is R₁, and a radius of curvature of the central portion of the second portion of the base surface is R₂.
[M10] The light emitting element array according to any one of [M07] to [M09], in which the central portion of the first portion of the base surface is positioned at a vertex (intersection portion) of a square lattice.
[M11] The light emitting element array according to [M10], in which the central portion of the second portion of the base surface is positioned at a vertex (intersection portion) of the square lattice.
[M12] The light emitting element array according to any one of [M07] to [M09], in which the central portion of the first portion of the base surface is positioned at a vertex (intersection portion) of a regular triangle lattice.
[M13] The light emitting element array according to [M12], in which the central portion of the second portion of the base surface is positioned at a vertex (intersection portion) of the regular triangle lattice.
[M14]<<Light emitting element of 8-C-th configuration>>

The light emitting element array according to [M03], in which a second portion of the base surface occupying the peripheral region has an annular convex shape surrounding the first portion of the base surface and a downward convex shape extending from the annular convex shape toward the first portion of the base surface with respect to the second surface of the first compound semiconductor layer.

[M15] The light emitting element array according to [M14], in which LL₂′>LL₁, where a distance from the second surface of the first compound semiconductor layer to a central portion of the first portion of the base surface is LL₁, and a distance from the second surface of the first compound semiconductor layer to a top portion of the annular convex shape of the second portion of the base surface is LL₂′.
[M16] The light emitting element array according to [M14] or [M15], in which R₁>R₂′, where a radius of curvature (that is, a radius of curvature of the first light reflecting layer) of the central portion of the first portion of the base surface is R₁, and a radius of curvature of the top portion of the annular convex shape of the second portion of the base surface is R₂′.

### REFERENCE SIGNS LIST

10A, 10B, 10C, 10D, 10E, 10F, 10G, 10H, 10J, 10K Light emitting element (surface emitting element and surface emitting laser element)
11 Compound semiconductor substrate (light emitting element array manufacturing substrate)
11a First surface of compound semiconductor substrate (light emitting element array manufacturing substrate) facing first compound semiconductor layer
11b Second surface of compound semiconductor substrate (light emitting element array manufacturing substrate) facing first compound semiconductor layer
20 Stacked structure
21 First compound semiconductor layer
21a First surface of first compound semiconductor layer
21b Second surface of first compound semiconductor layer
22 Second compound semiconductor layer
22a First surface of second compound semiconductor layer
22b Second surface of second compound semiconductor layer
23 Active layer (light emitting layer)
31 First electrode
31′ Opening provided in first electrode
32 Second electrode
33 Second pad electrode
34 Insulating layer (current constriction layer)
34A Opening provided in insulating layer (current constriction layer)
35 Bump
41 First light reflecting layer
42 Second light reflecting layer
42A Forward tapered inclined portion formed in second light reflecting layer
48 Bonding layer
49 Support substrate
51, 61 Current injection region
61A Current injection region
61B Current non-injection region
52, 62 Current non-injection/inner region
53, 63 Current non-injection/outer region
54, 64 Mode loss acting portion (mode loss acting layer)
54A, 54B, 64A Opening formed in mode loss acting portion
55, 65 Mode loss acting region
71 First layer
72 Second layer
73 Wavelength conversion material layer (color conversion material layer)
74 Light absorbing material layer
81 First sacrificial layer
82 Second sacrificial layer
90 Base surface
91 Protrusion
91A 1-A-th region of protrusion
91B 1-B-th region of protrusion
92 Second region
91′ First portion
92′ Second portion
91_{c} Central portion of first portion of base surface
90_{bd} Boundary between first portion and second portion
93 Base material
94 Uneven portion for forming base surface
95 Planarization film
96, 97 Partition wall
96′, 97′ Side surface of partition wall
96a, 97a Lower end portion of partition wall
96b, 97b Upper end portion of partition wall

1. A method for manufacturing a light emitting element which includes a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked, a first light reflecting layer, and a second light reflecting layer formed on a second surface side of the second compound semiconductor layer and having a flat shape, and in which a base surface positioned on a first surface side of the first compound semiconductor layer has a protrusion protruding in a direction away from the active layer, and a cross-sectional shape of the protrusion in a case where the base surface is cut along a virtual plane including a stacking direction of the stacked structure includes a smooth curve,
the method comprising:
forming the second light reflecting layer on the second surface side of the second compound semiconductor layer after forming the stacked structure;
forming a first sacrificial layer on the base surface on which the protrusion is to be formed;
forming a second sacrificial layer on the entire surface and then performing etching back from the base surface inward by using the second sacrificial layer and the first sacrificial layer as etching masks; and
forming the first light reflecting layer on at least the protrusion.

2. The method according to claim 1, wherein in the forming of the second sacrificial layer on the entire surface, formation of the second sacrificial layer is performed a plurality of times.

3. A method for manufacturing a light emitting element which includes a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked, a first light reflecting layer, and a second light reflecting layer formed on a second surface side of the second compound semiconductor layer and having a flat shape, and in which a base surface positioned on a first surface side of the first compound semiconductor layer has a protrusion protruding in a direction away from the active layer, and a cross-sectional shape of the protrusion in a case where the base surface is cut along a virtual plane including a stacking direction of the stacked structure includes a smooth curve,
the method comprising:
forming the second light reflecting layer on the second surface side of the second compound semiconductor layer after forming the stacked structure;
forming a first layer on a portion of the base surface on which the protrusion is to be formed;
forming a second layer covering the first layer to form the protrusion constituted by the first layer and the second layer covering the first layer on the base surface; and
forming the first light reflecting layer on at least the protrusion.

4. The method for manufacturing a light emitting element according to claim 3, wherein in the forming of the second layer on the entire surface, formation of the second layer is performed a plurality of times.

5. A light emitting element comprising:
a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked;
a first light reflecting layer; and
a second light reflecting layer formed on a second surface side of the second compound semiconductor layer and having a flat shape,
wherein a base surface positioned on a first surface side of the first compound semiconductor layer has a protrusion protruding in a direction away from the active layer,
a cross-sectional shape of the protrusion in a case where the base surface is cut along a virtual plane including a stacking direction of the stacked structure includes a smooth curve,
the first light reflecting layer is formed on at least the protrusion, and
2×10−6 m≤D1≤2.5×10−5 m,
1×10−8 m≤H1≤5×10−7 m,
1×10−4 m≤R1, and
RaPj≤1.0 nm, where a diameter of the protrusion is D1, a height of the protrusion is H1, a radius of curvature of a top portion of the protrusion is R1, and a surface roughness of the protrusion is RaPj, and a resonator length of the light emitting element is L_{OR}.

6. A light emitting element comprising:
a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked;
a first light reflecting layer; and
a second light reflecting layer formed on a second surface side of the second compound semiconductor layer and having a flat shape,
wherein a base surface positioned on a first surface side of the first compound semiconductor layer has a protrusion protruding in a direction away from the active layer,
a cross-sectional shape of the protrusion in a case where the base surface is cut along a virtual plane including a stacking direction of the stacked structure includes a smooth curve,
the first light reflecting layer is formed on at least the protrusion, and
2×10−3 m≤D1,
1×10−3 m≤R1, and
RaPj≤1.0 nm, where a diameter of the protrusion is D1, a height of the protrusion is H1, a radius of curvature of a top portion of the protrusion is R1, and a surface roughness of the protrusion is RaPj, and a resonator length of the light emitting element is L_{OR}.

7. A light emitting element comprising:
a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked;
a first light reflecting layer; and
a second light reflecting layer formed on a second surface side of the second compound semiconductor layer and having a flat shape,
wherein a base surface positioned on a first surface side of the first compound semiconductor layer has a protrusion protruding in a direction away from the active layer,
the protrusion is constituted by a first layer and a second layer covering the first layer,
a cross-sectional shape of the protrusion in a case where the base surface is cut along a virtual plane including a stacking direction of the stacked structure includes a smooth curve, and
the first light reflecting layer is formed on at least the protrusion.

8. The light emitting element according to claim 5, wherein a wavelength conversion material layer is provided in a region of the light emitting element where light is emitted.

9. The light emitting element according to claim 8, wherein white light is emitted via the wavelength conversion material layer.

10. A light emitting element array comprising:
a plurality of light emitting elements,
wherein each light emitting element includes:
a stacked structure in which a first compound semiconductor layer having a first surface and a second surface opposing the first surface, an active layer facing the second surface of the first compound semiconductor layer, and a second compound semiconductor layer having a first surface facing the active layer and a second surface opposing the first surface are stacked;
a first light reflecting layer; and
a second light reflecting layer formed on a second surface side of the second compound semiconductor layer and having a flat shape,
a base surface positioned on a first surface side of the first compound semiconductor layer has a protrusion protruding in a direction away from the active layer,
a cross-sectional shape of the protrusion in a case where the base surface is cut along a virtual plane including a stacking direction of the stacked structure includes a smooth curve,
the first light reflecting layer is formed on at least the protrusion, and
2×10−6 m≤D1≤2.5×10−5 m,
1×10−8 m≤H1≤5×10−7 m,
1×10−4 m≤R1, and
RaPj≤1.0 nm, where a diameter of the protrusion is D1, a height of the protrusion is H1, a radius of curvature of a top portion of the protrusion is R1, a surface roughness of the protrusion is RaPj, and a resonator length of the light emitting element is L_{OR} and
a formation pitch P0 of the light emitting elements is 3×10-5 m or less.
